(19) United States
(12) Patent Application Publication
(10) Pub. No.: US 2026/0105938 A1
(43) Pub. Date: Apr. 16, 2026

(54) MEMORY DEVICE AND METHOD OF FORMING THE SAME

(71) Applicant: TAIWAN SEMICONDUCTOR MANUFACTURING COMPANY, LTD., Hsinchu (TW)

(72) Inventors: Jui-Lin CHEN, Hsinchu (TW); Ping-Wei WANG, Hsinchu (TW); Lien-Jung HUNG, Hsinchu (TW)

(21) Appl. No.: 19/052,636

(22) Filed: Feb. 13, 2025

Related U.S. Application Data
(60) Provisional application No. 63/706,338, filed on Oct. 11, 2024.

(51) Int. Cl. G11C 5/06; H10B 10/00; H10D 30/00; H10D 30/01; H10D 30/43; H10D 62/10; H10D 64/23

(52) U.S. Cl. CPC G11C 5/063; H10B 10/125; H10D 30/014; H10D 30/019; H10D 30/43; H10D 30/501; H10D 62/121; H10D 64/251

(57) ABSTRACT

A device includes a first, second, third, and fourth transistor and a first and second conductor. The first transistor is coupled to a first node and includes a first gate. The second transistor is coupled to the first node, the second transistor includes a second gate. The third transistor is coupled to a second node, and includes a third gate separated from the first gate in a first direction. The fourth transistor is coupled to the second node, and includes a fourth gate. The first conductor is on a first metal layer above a front-side of a substrate, and is coupled to the first gate and the second node. The second conductor is on a second metal layer below a back-side of the substrate, and is coupled to the fourth gate and the first node.

### PRIORITY CLAIM

This application claims the benefit of U.S. Provisional Application No. 63/706,338, filed Oct. 11, 2024, which is incorporated herein by reference in its entirety.

### BACKGROUND

The semiconductor integrated circuit (IC) industry has produced a wide variety of digital devices to address issues in a number of different areas. Some of these digital devices, such as memory macros, are configured for the storage of data. As ICs have become smaller and more complex, the resistance of conductive lines within these digital devices is also changed affecting the operating voltages of these digital devices and overall IC performance.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a block diagram of a memory circuit, in accordance with some embodiments.

FIG. 2 is a circuit diagram of a corresponding memory cell usable in FIG. 1, in accordance with some embodiments.

FIGS. 3A-3D are corresponding diagrams of corresponding portions of a layout design of a corresponding integrated circuit, in accordance with some embodiments.

FIGS. 4A-4F are diagrams of an integrated circuit, in accordance with some embodiments.

FIGS. 5A-5F are diagrams of an integrated circuit, in accordance with some embodiments.

FIGS. 6A-6D are diagrams of an integrated circuit, in accordance with some embodiments.

FIGS. 7A-7D are diagrams of a layout design, in accordance with some embodiments.

FIGS. 8A-8D are diagrams of an integrated circuit, in accordance with some embodiments.

FIGS. 9A-9G are diagrams of an integrated circuit, in accordance with some embodiments.

FIG. 10A-10B are corresponding functional flow charts of a corresponding method of manufacturing an IC device, in accordance with some embodiments.

FIGS. 11A-11I are cross-sectional views of intermediate device structures obtained when fabricating the first butt-side contact on the front-side of the integrated circuit, and the second butt-side contact on the back-side of the integrated circuit, in accordance with some embodiments.

FIG. 12 is a flow chart of a method of manufacturing an integrated circuit, in accordance with some embodiments.

FIG. 13 is a flowchart of a method of generating a layout design of an integrated circuit, in accordance with some embodiments.

FIG. 14 is a schematic view of a system for designing an IC layout design and manufacturing an IC circuit, in accordance with some embodiments.

FIG. 15 is a block diagram of an IC manufacturing system, and an IC manufacturing flow associated therewith, in accordance with at least one embodiment of the present disclosure.

### DETAILED DESCRIPTION

The following disclosure provides different embodiments, or examples, for implementing features of the provided subject matter. Specific examples of components, materials, values, steps, arrangements, or the like, are described below to simplify the present disclosure. These are, of course, merely examples and are not limiting. Other components, materials, values, steps, arrangements, or the like, are contemplated. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In accordance with some embodiments, a memory cell includes a first transistor of a first type.

In some embodiments, the first transistor is coupled to a first storage node. In some embodiments, the first transistor includes a first gate on a first level.

In some embodiments, the memory cell further includes a second transistor of a second type different from the first type. In some embodiments the second transistor is coupled to the first storage node. In some embodiments, the second transistor includes a second gate on a second level below the first level.

In some embodiments, the memory cell further includes a third transistor of the first type. In some embodiments, the third transistor is coupled to a second storage node. In some embodiments, the third transistor includes a third gate on the first level. In some embodiments, the third gate is separated from the first gate in at least a first direction.

In some embodiments, the memory cell further includes a fourth transistor of the second type. In some embodiments the fourth transistor is coupled to the second storage node. In some embodiments, the fourth transistor includes a fourth gate on the second level.

In some embodiments, the memory cell further includes a first conductor extending in a second direction different from the first direction. In some embodiments, the first conductor is on a first metal layer above a front-side of a substrate. In some embodiments, the first conductor is being coupled to the first gate and the second storage node.

In some embodiments, the memory cell further includes a second conductor extending in the second direction. In some embodiments, the second conductor is on a second metal layer below a back-side of the substrate. In some embodiments, the second metal layer is different from the first metal layer. In some embodiments, the second conductor is coupled to the fourth gate and the first storage node.

In some embodiments, the first conductor is used as a first butt-side contact on the front-side of the memory cell, and the second conductor is used as a second butt-side contact on the back-side of the memory cell, thus improving routing resources of the memory cell and reducing the area of the memory cell compared to other approaches.

In some embodiments, by using the first conductor as the first butt-side contact on the front-side of the memory cell, and by using the second conductor as the second butt-side contact on the back-side of the memory cell, at least one of the first conductor or the second conductor has a simpler design than other approaches that have a more complex L-shape and use at least one more extra masks.

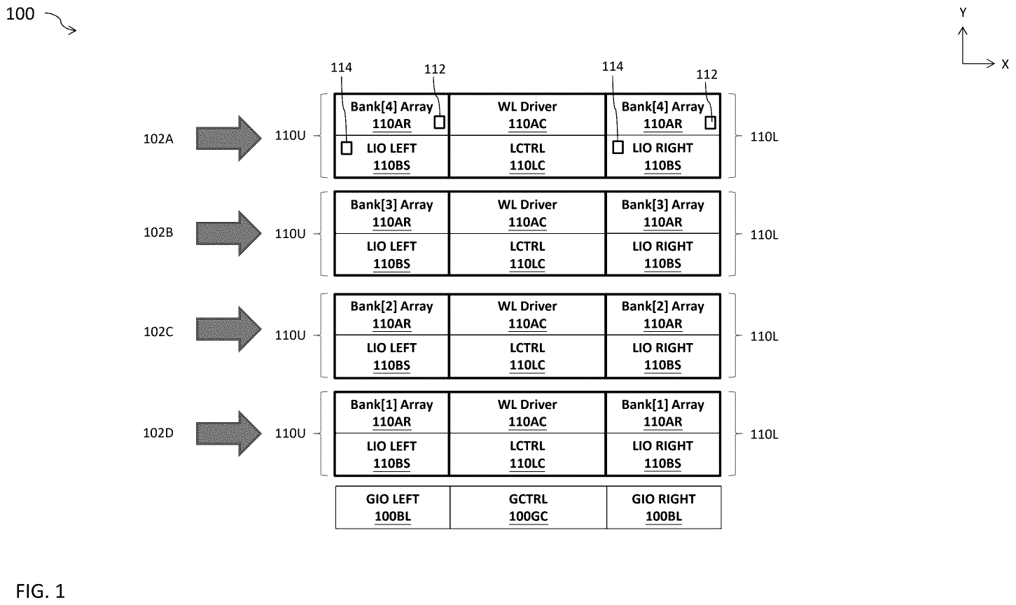

FIG. 1 is a block diagram of a memory circuit 100, in accordance with some embodiments.

FIG. 1 is simplified for the purpose of illustration. In some embodiments, memory circuit 100 includes various elements in addition to those depicted in FIG. 1 or is otherwise arranged to perform the operations discussed below.

Memory circuit 100 is an IC that includes memory partitions 102A-102D, a global control circuit 100GC and global input output (GIO) circuits 100BL.

Each memory partition 102A-102D includes memory banks 110U and 110L adjacent to a word line (WL) driver circuit 110AC and a local control circuit 110LC. Each memory bank 110U and 110L includes a memory cell array 110AR and a local input output (LIO) circuit 110BS.

A memory partition, e.g., a memory partition 102A-102D, is a portion of memory circuit 100 that includes a subset of memory devices (not shown in FIG. 1) and adjacent circuits configured to selectively access the subset of memory devices in program and read operations. In the FIG. 1 embodiment, memory circuit 100 includes a total of four partitions. In some embodiments, memory circuit 100 includes a total number of partitions greater or fewer than four.

GIO circuit 100BL is configured to control access to one or more electrical paths, e.g., bit lines, to each memory device of the corresponding memory bank 110U or 110L of each memory partition 102A-102D, e.g., by generating one or more bit line signals. In some embodiments, GIO circuit 100BL includes a global bit line driver circuit. In some embodiments, GIO circuit 100BL is coupled to each memory bank 110U and 110L by a corresponding global bit line (not shown).

Global control circuit 100GC is configured to control some or all of program and read operations on each memory partition 102A-102D, e.g., by generating and/or outputting one or more control and/or enable signals.

In some embodiments, global control circuit 100GC includes one or more analog circuits configured to interface with memory partitions 102A-102D, cause data to be programmed in one or more memory devices, and/or use data received from one or more memory devices in one or more circuit operations. In some embodiments, global control circuit 100GC includes one or more global address decoder or pre-decoder circuits configured to output one or more address signals to the WL driver circuit 110AC of each memory partition 102A-102D.

Each WL driver circuit 110AC is configured to generate word line signals on corresponding word lines WL. In some embodiments, each WL driver circuit 110AC is configured to output word line signals on corresponding word lines WL to the adjacent memory banks 110U and 110L of the corresponding memory partition 102A-102D.

Each local control circuit 110LC is an electronic circuit configured to receive one or more address signals. Each local control circuit 110LC is configured to generate signals corresponding to adjacent subsets of memory devices identified by the one or more address signals. In some embodiments, the adjacent subsets of memory devices correspond to columns of memory devices. In some embodiments, each local control circuit 110LC is configured to generate each signal as a complementary pair of signals. In some embodiments, each local control circuit 110LC is configured to output the signals to corresponding word line driver circuits within the adjacent WL driver circuit 110AC of the corresponding memory partition 102A-102D. In some embodiments, the local control circuit 110LC includes a bank decoder circuit.

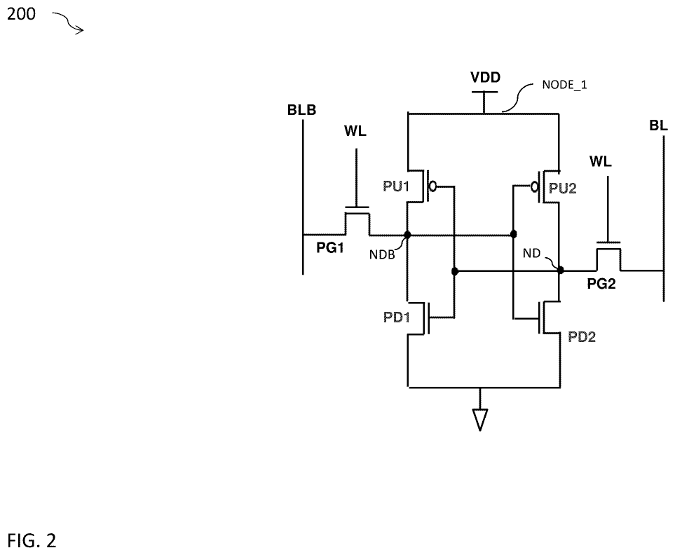

Each LIO circuit 110BS is configured to selectively access one or more bit lines (shown in FIG. 2) coupled to adjacent subsets of memory devices of the corresponding memory cell array 110AR responsive to GIO circuit 100BL, e.g., based on one or more BL control signals. In some embodiments, the adjacent subsets of memory devices correspond to rows of memory devices. In some embodiments, the LIO circuit 110BS includes a bit line selection circuit.

Each LIO circuit 110BS includes one or more circuits 114. For ease of illustration, circuit 114 is not shown in memory bank 110U and 110L of memory partitions 102B, 102C and 102D. In some embodiments, each circuit 114 includes at least a sense amplifier circuit. In some embodiments, during a read operation, the sense amplifier circuit is configured to read data from at least one memory cell 112 in a corresponding column of memory cells in the corresponding memory cell array 110AR, in accordance with some embodiments. In some embodiments, each circuit 114 in LIO circuit 110BS is coupled to a corresponding column of memory devices 112 in memory cell array 110AR.

Each memory bank 110U and 110L includes the corresponding memory cell array 110AR including memory cells or memory devices 112 configured to be accessed in program and read operations by the adjacent LIO circuit 110BS and the adjacent WL driver circuit 110AC.

Each memory cell array 110AR includes an array of memory devices 112 having N rows and M columns, where M and N are positive integers. The rows of cells in memory cell array 102 are arranged in a first direction X. The columns of cells in memory cell array 102 are arranged in a second direction Y. The second direction Y is different from the first direction X. In some embodiments, the second direction Y is perpendicular to the first direction X. In some embodiments, each memory cell array 110AR is divided into an upper region and a lower region (not shown). In some embodiments, each column of memory devices 112 in memory cell array 110AR is coupled to a corresponding circuit 114 in LIO circuit 110BS.

Memory device 112 is shown in memory bank 110U and 110L of memory partition 102A. For ease of illustration, memory device 112 is not shown in memory bank 110U and 110L of memory partitions 102B, 102C and 102D.

Memory device 112 is an electrical, electromechanical, electromagnetic, or other device configured to store bit data represented by logical states. At least one logical state of memory device 112 is capable of being programmed in a write operation and detected in a read operation. In some embodiments, a logical state corresponds to a voltage level of an electrical charge stored in a given memory device 112. In some embodiments, a logical state corresponds to a physical property, e.g., a voltage, a current, a resistance or a magnetic orientation, of a component of a given memory device 112.

In some embodiments, memory device 112 includes one or more single port (SP) static random access memory (SRAM) cells. In some embodiments, memory device 112 includes one or more dual port (DP) SRAM cells. In some embodiments, memory device 112 includes one or more multi-port (MP) SRAM cells. In some embodiments, memory device 112 includes the one or more SRAM cells include complementary FET (CFET) transistors. Different types of memory cells in memory device 112 are within the contemplated scope of the present disclosure. In some embodiments, memory device 112 includes one or more dynamic random access memory (DRAM) cells. In some embodiments, memory device 112 includes one or more one-time programmable (OTP) memory devices such as electronic fuse (eFuse) or anti-fuse devices, flash memory devices, random-access memory (RAM) devices, resistive RAM devices, ferroelectric RAM devices, magneto-resistive RAM devices, erasable programmable read only memory (EPROM) devices, electrically erasable programmable read only memory (EEPROM) devices, or the like. In some embodiments, memory device 112 is an OTP memory device including one or more OTP memory cells.

Other configurations of memory circuit 100 are within the scope of the present disclosure.

FIG. 2 is a circuit diagram of a corresponding memory cell 200 usable in FIG. 1, in accordance with some embodiments.

FIG. 2 is a circuit diagram of a memory cell 200 usable in FIG. 1, in accordance with some embodiments.

Memory cell 200 is usable as one or more memory cells MCB in at least one of memory cell array 110AR of FIG. 1 or memory device 112 of FIG. 1.

Memory cell 200 is a six transistor (ST) single port (SP) SRAM memory cell. In some embodiments, memory cell 200 employs a number of transistors other than six. Other types of memory are within the scope of various embodiments.

Memory cell 200 comprises P field effect transistors (PFET) PU1 and PU2, and NFET transistors PD1, PD2, PG1 and PG2. PFET transistors PU1 and PU2 and NFET transistors PD1 and PD2 form a cross latch or a pair of cross-coupled inverters. For example, PFET transistor PU1 and NFET transistor PD1 form a first inverter while PFET transistor PU2 and NFET transistor PD2 form a second inverter.

A source terminal of each of PFET transistors PU1 and PU2 is configured as a voltage supply node NODE_1. Each voltage supply node NODE_1 is coupled to a first voltage supply VDD.

Each of a drain terminal of PFET transistor PU1, a drain terminal of NFET transistor PD1, a gate terminal of PFET transistor PU2, a gate terminal of NFET transistor PD2 and a source terminal of NFET transistor PG1 are coupled together, and are configured as a storage node NDB.

Each of a drain terminal of PFET transistor PU2, a drain terminal of NFET transistor PD2, a gate terminal of PFET transistor PU1, a gate terminal of NFET transistor PD1 and a source terminal of NFET transistor PG2 are coupled together, and are configured as a storage node ND.

A source terminal of each of NFET transistors PD1 and PD2 is configured as a supply reference voltage node (not labelled) having a supply reference voltage VSS. The source terminal of each of NFET transistors PD1 and PD2 is also coupled to reference voltage supply VSS.

A word line WL is coupled with a gate terminal of each of NFET transistors PG1 and PG2. Word line WL is also called a write control line because NFET transistors PG1 and PG2 are configured to be controlled by a signal on word line WL in order to transfer data between bit line bar BLB/bit line BL and corresponding node NDB/ND.

In some embodiments, the signal of the word line WL is equal to a voltage supply VDD. In some embodiments, when the signal of the word line WL is equal to the voltage supply VDD, the NFET transistors PG1 and PG1 are turned on.

A drain terminal of NFET transistor PG1 is coupled to a bit line bar BLB. A drain terminal of NFET transistor PG2 is coupled to a bit line BL.

Bit line BL and bit line bar BLB are configured as both data input and output for memory cell 200. In some embodiments, in a write operation, applying a logical value to bit line BL and the opposite logical value to bit line bar BLB enables writing the logical values on the bit lines to memory cell 200.

Each of bit line BL and bit line bar BLB is called “a data line” because the data carried on bit line BL and bit line bar BLB are written to and read from corresponding nodes ND and NDB.

Other configurations of memory cell 200 are within the scope of the present disclosure.

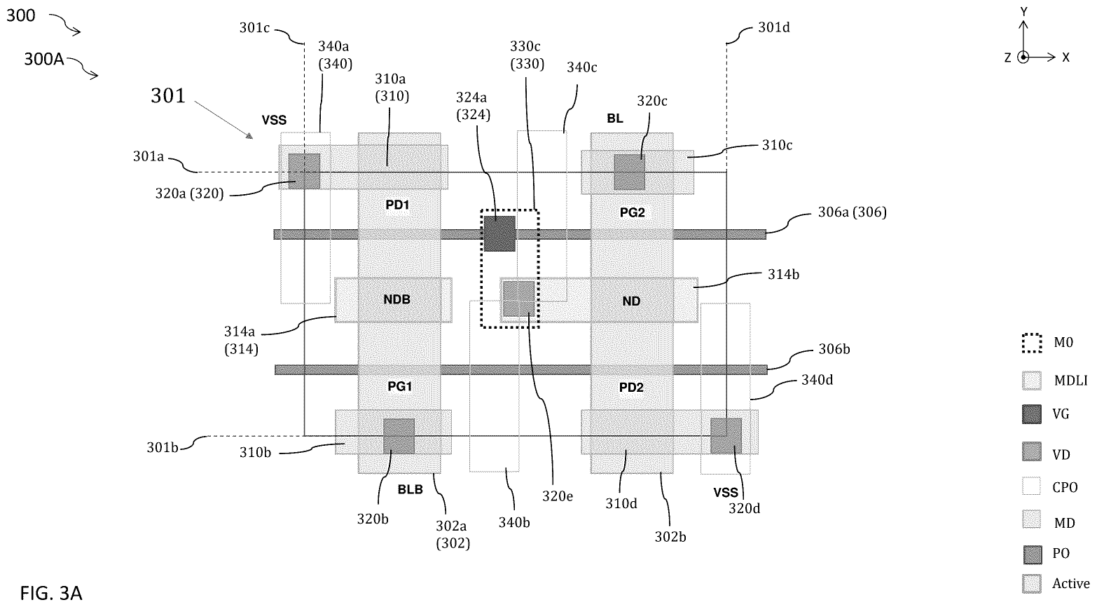

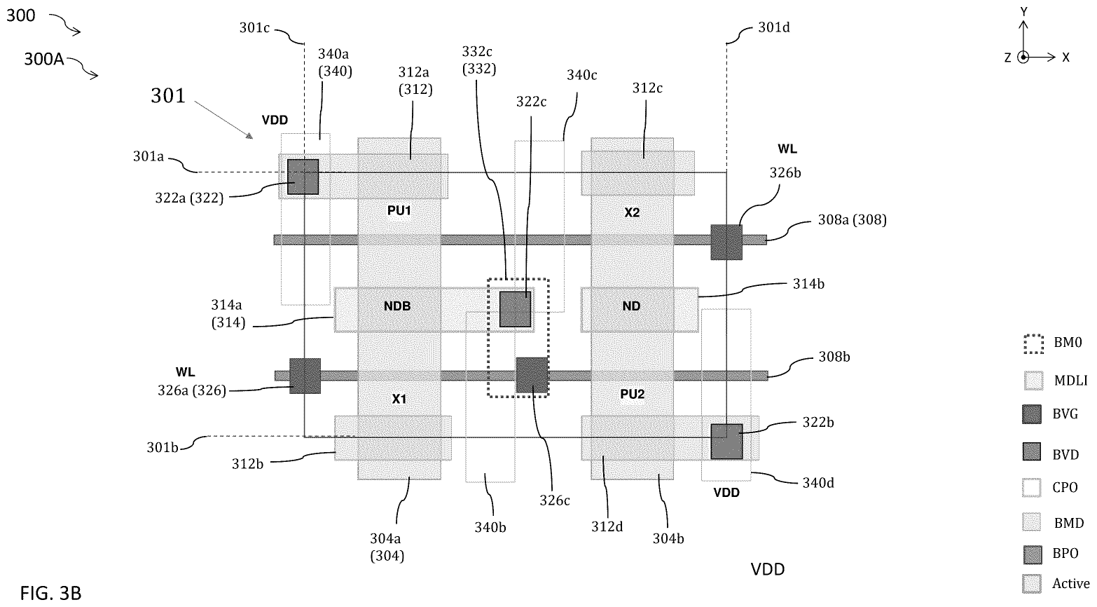

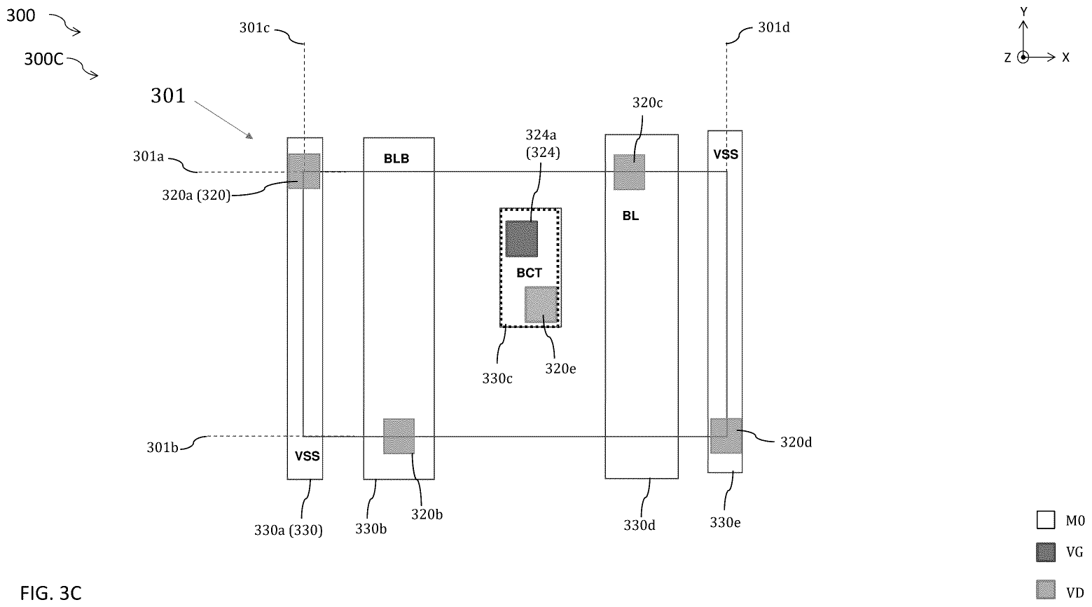

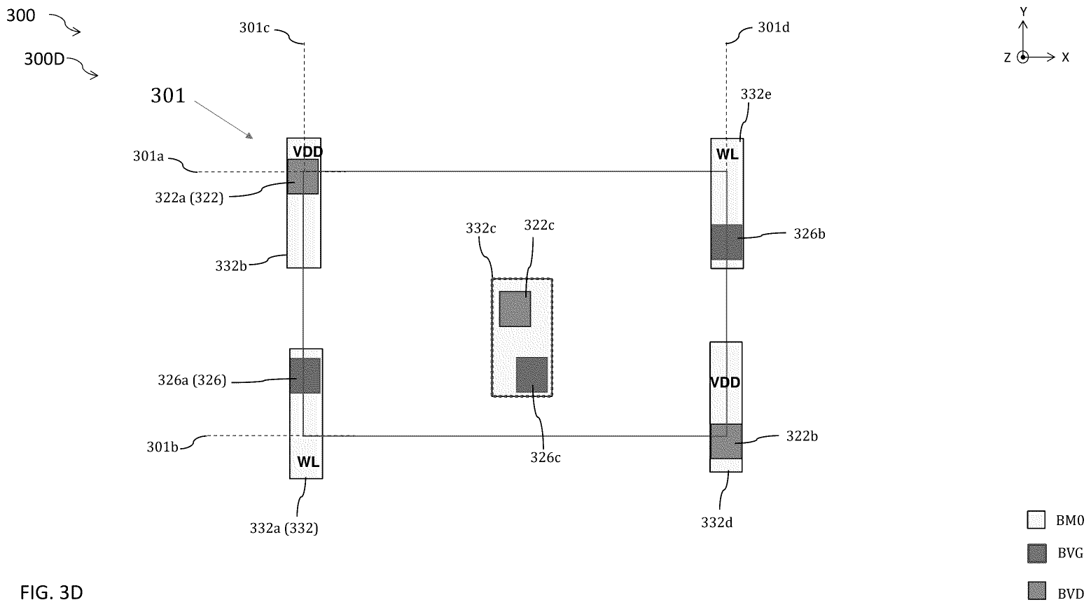

FIGS. 3A-3D are corresponding diagrams of corresponding portions 300A-300D of a layout design 300 of a corresponding integrated circuit, in accordance with some embodiments.

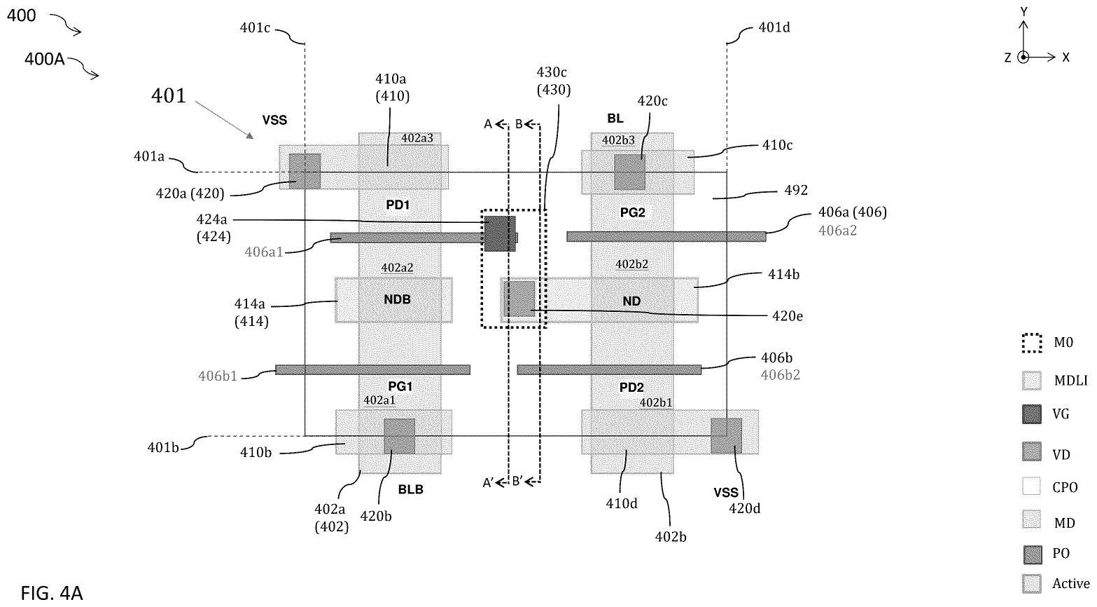

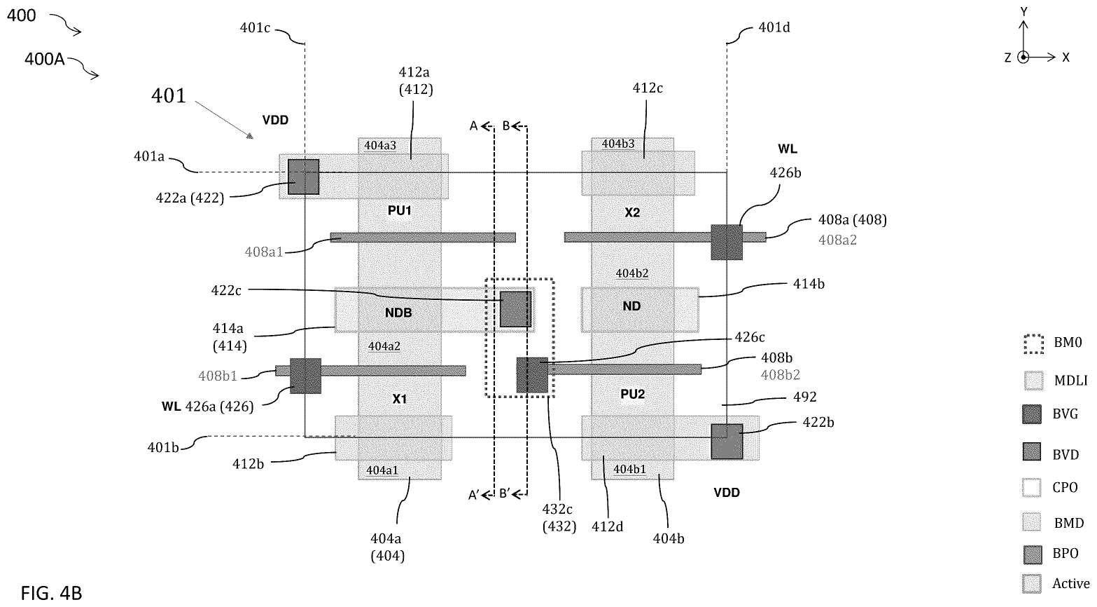

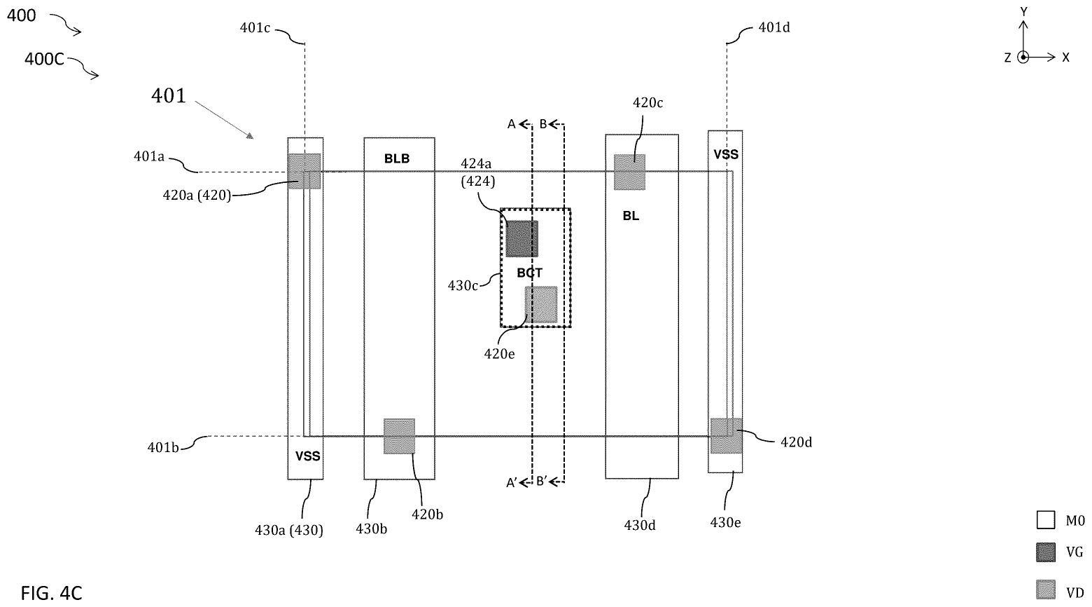

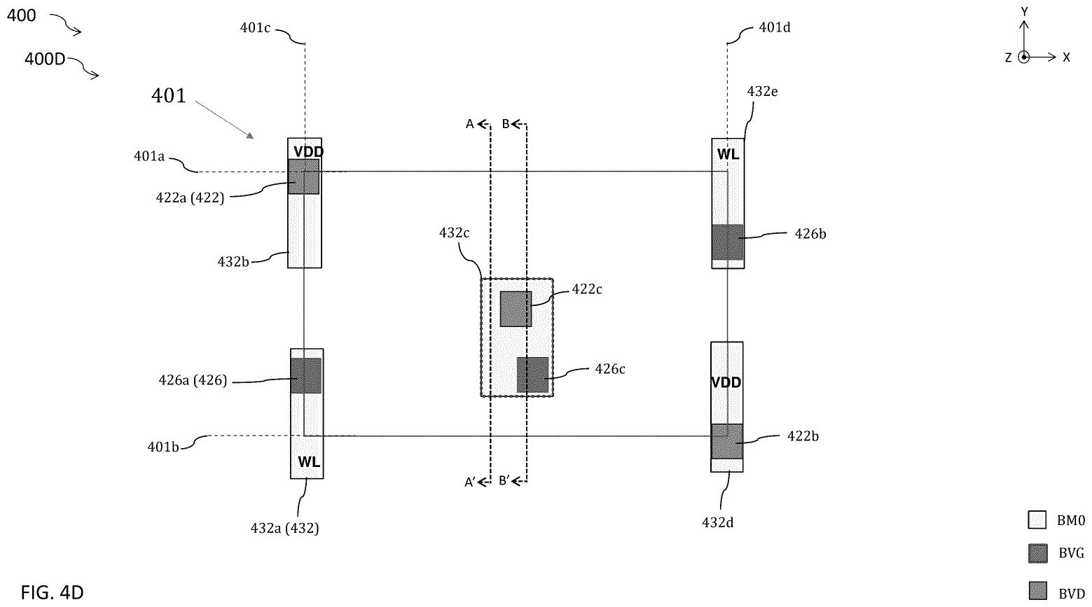

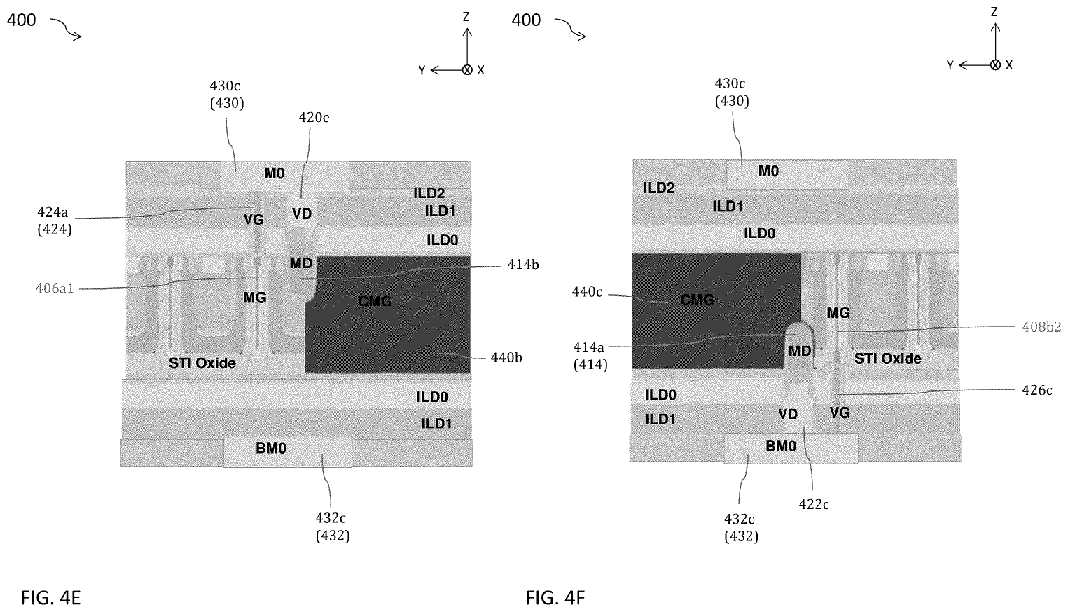

Layout design 300 is a layout of an integrated circuit 400 of FIGS. 4A-4F or memory cell 200. Layout design 300 is a layout of memory cell 200 of FIG. 2.

Portion 300A includes one or more features of layout design 300 of an active level or an oxide diffusion (OD) level, a gate (POLY or PO) level, a cut gate or cut POLY (CPOLY or CPO) level, a metal over diffusion (MD) level, a metal over diffusion local interconnect (MDLI) level, a via over gate (VG) level, a via over diffusion (VD) level and a metal 0 (M0) level.

Portion 300B includes one or more features of layout design 300 of the OD level, the POLY level, the CPO level, a backside metal over diffusion (BMD) level, the MDLI level, a backside via over gate (BVG) level, a backside via over diffusion (BVD) level and a back-side metal 0 (BM0) level.

Portion 300C includes one or more features of layout design 300 of the VG level, the VD level and the M0 level.

Portion 300D includes one or more features of layout design 300 of the BVG level, the BVD level and the BM0 level.

FIGS. 3A-3D are corresponding diagrams of corresponding portions 300A-300D of layout design 300, simplified for ease of illustration.

For ease of illustration, some of the labeled elements of one or more of FIGS. 1-9G and 11A-11I are not labelled in one or more of FIGS. 1-9G and 11A-11I. In some embodiments, layout design 300 includes additional elements not shown in FIGS. 3A-3D. Layout design 300 includes one or more features of the OD level, the POLY level, the CPO level, the MD level, the MDLI level, the VG level, the VD level, the M0 level, the BMD level, the BVG level, the BVD level and the BM0 level.

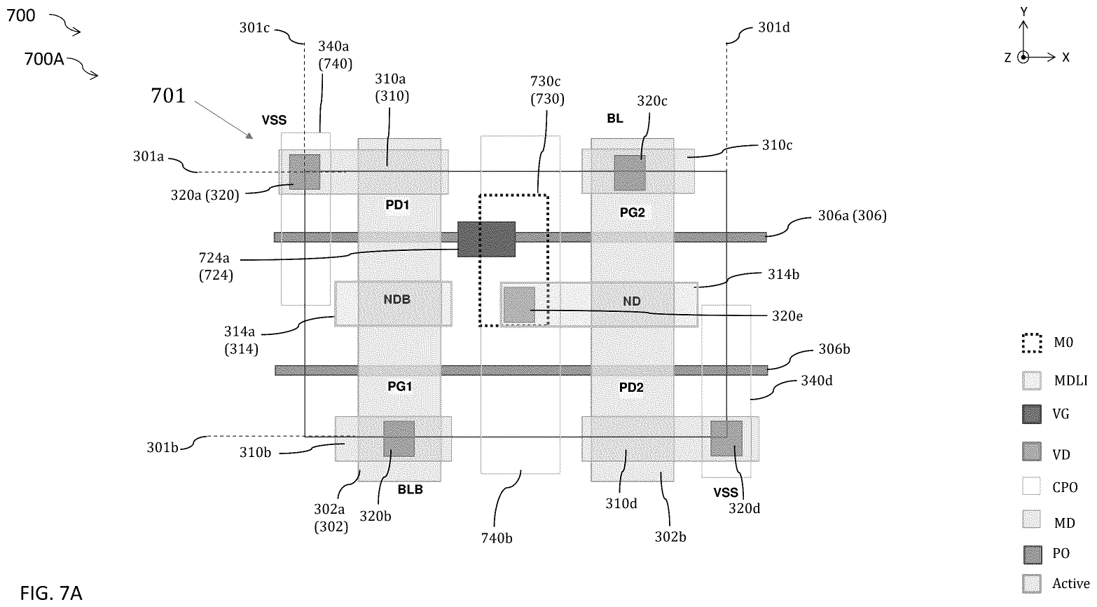

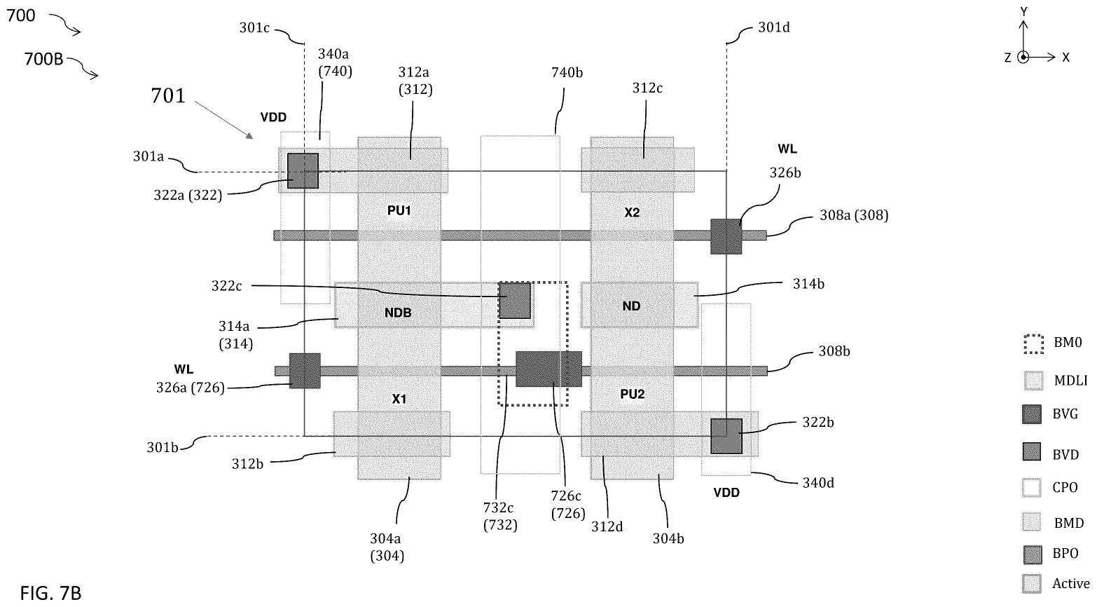

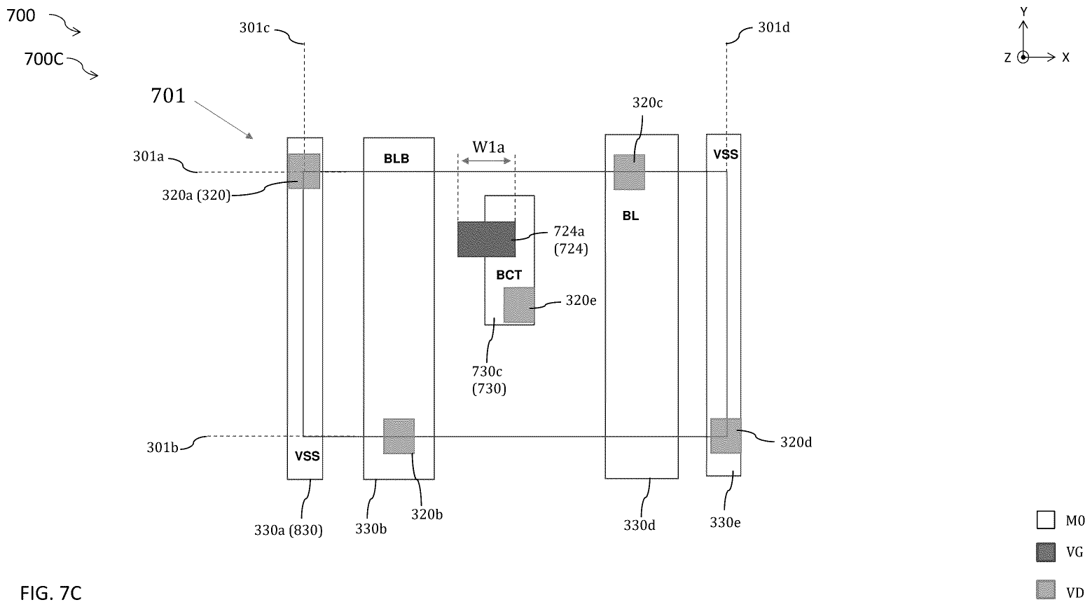

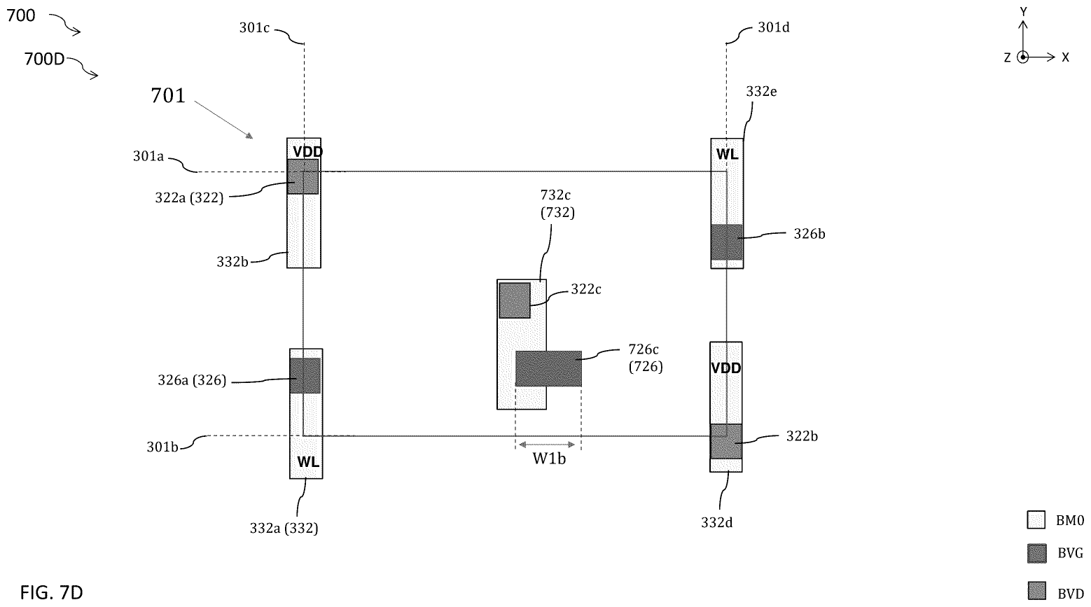

In some embodiments, at least layout design 300 or 700 of at least FIGS. 3A-3D or 7A-7D, or integrated circuit 400, 500, 600, 800, 900 or 1100 of at least FIGS. 4A-4F, 5A-5F, 6A-6D, 8A-8D, 9A-9G or 11A-11I includes additional elements not shown in one or more of FIGS. 3A-3D, 4A-4F, 5A-5F, 6A-6D, 7A-7D, 8A-8D, 9A-9G or 11A-11I.

Layout design 300 is usable to manufacture integrated circuit 400 of FIGS. 4A-4F.

Portion 300A is a layout of portion 400A of integrated circuit 400 of FIG. 4A, portion 300B is a layout of portion 400B of integrated circuit 400 of FIG. 4B, portion 300C is a layout of portion 400C of integrated circuit 400 of FIG. 4C, and portion 300D is a layout of portion 400D of integrated circuit 400 of FIG. 4D, and similar detailed description is omitted for brevity.

Layout design 300 includes a cell 301. The cell 301 has cell boundaries 301a and 301b that extend in a first direction X, and cell boundaries 301c and 301d that extend in a second direction Y. In some embodiments, at least one of the first direction X, the second direction Y or a third direction Z is different from another of the first direction X, the second direction Y or the third direction Z. In some embodiments, layout design 300 abuts other cell layout designs (not shown) along cell boundaries 301c and 301d. In some embodiments, layout design 300 abuts other cell layout designs (not shown) along cell boundaries 301a and 301b that extend in the first direction X. In some embodiments, layout design 300 is a single height standard cell. In some embodiments, cell 301 is useable to manufacture a cell 401.

In some embodiments, cell 301 is a standard cell, and layout design 300 corresponds to a layout of a standard cell defined by cell boundaries 301a, 301b, 301c and 301d. In some embodiments, a cell 301 is a predefined portion of layout design 300 including one or more transistors and electrical connections configured to perform one or more circuit functions. In some embodiments, cell 301 is bounded by cell boundaries 301a, 301b, 301c and 301d, and thus corresponds to a region of functional circuit components or devices that are part of a standard cell. In some embodiments, layout design 300 is a layout design of a memory cell, such as memory cell 200 of FIG. 2.

Layout design 300 includes one or more active region layout patterns 302a or 302b (collectively referred to as a “set of active region patterns 302”) or one or more active region layout patterns 304a or 304b (collectively referred to as a “set of active region patterns 304”) extending in the second direction Y.

Embodiments of the present disclosure use the term “layout pattern” which is hereinafter also referred to as “patterns” in the remainder of the present disclosure for brevity.

The set of active region patterns 302 is above the set of active region patterns 304.

Active region patterns 302a and 302b of the set of active region patterns 302 are separated from one another in the first direction X. Active region patterns 304a and 304b of the set of active region patterns 304 are separated from one another in the first direction X.

Active region patterns 302a and 304a are separated from one another in a third direction Z. Active region patterns 302b and 304b are separated from one another in the third direction Z.

The set of active region patterns 302 is usable to manufacture a corresponding set of active regions 402 of integrated circuit 100, 200, 400, 500, 600, 800, 900 or 1100. The set of active region patterns 304 is usable to manufacture a corresponding set of active regions 404 of integrated circuit 100, 200, 400, 500, 600, 800, 900 or 1100.

In some embodiments, at least one of the set of active regions 402 or 404 are located on the front-side 403a of integrated circuit 100, 200, 400, 500, 600, 800, 900 or 1100. In some embodiments, at least one of the set of active regions 402 or 404 corresponds to source and drain regions of one or more complementary FET (CFET) transistors. In some embodiments, at least one of the set of active regions 402 or 404 correspond to source and drain regions of one or more nanosheet transistors or nanowire transistors. Other transistor types are within the scope of the present disclosure. In some embodiments, at least one of the set of active regions 402 or 404 corresponds to source and drain regions of one or more finFET transistors.

In some embodiments, active region patterns 302a, 302b are usable to manufacture corresponding active regions 402a, 402b of the set of active regions 402 of integrated circuit 100, 200, 400, 500, 600, 800, 900 or 1100. In some embodiments, active region patterns 304a, 304b are usable to manufacture corresponding active regions 404a, 404b of the set of active regions 404 of integrated circuit 100, 200, 400, 500, 600, 800, 900 or 1100.

In some embodiments, the set of active region patterns 302 and 304 are referred to as an oxide diffusion (OD) region which defines the source or drain diffusion regions of at least integrated circuit 100, 200, 400, 500, 600, 800, 900 or 1100 or layout design 300.

In some embodiments, active region patterns 302a and 302b are usable to manufacture source and drain regions of NFET transistors of integrated circuits 100, 200, 400, 500, 600, 800, 900 or 1100, and active region patterns 304a and 304b are usable to manufacture source and drain regions of PFET transistors of integrated circuits 100, 200, 400, 500, 600, 800, 900 or 1100.

In some embodiments, active region patterns 302a and 302b are usable to manufacture source and drain regions of PFET transistors of integrated circuits 100, 200, 400, 500, 600, 800, 900 or 1100, and active region patterns 304a and 304b are usable to manufacture source and drain regions of NFET transistors of integrated circuits 100, 200, 400, 500, 600, 800, 900 or 1100.

In some embodiments, the set of active region patterns 302 or 304 is located on a first layout level. In some embodiments, the first layout level corresponds to an active level or an OD level of one or more of layout design 300 or integrated circuits 100, 200, 400, 500, 600, 800, 900 or 1100. some embodiments, the OD level is above at least the BM0.

Other configurations, arrangements on other layout levels or quantities of patterns in the set of active region patterns 302 or 304 are within the scope of the present disclosure.

Layout design 300 further includes one or more gate patterns 306a or 306b (collectively referred to as a “set of gate patterns 306”), one or more gate patterns 308a or 308b (collectively referred to as a “set of gate patterns 308”) extending in the first direction X.

The set of gate patterns 306 is above the set of gate patterns 308.

In some embodiments, gate patterns 306a and 308a are separated from one another in the third direction Z. In some embodiments, gate patterns 306b and 308b are separated from one another in the third direction Z.

The set of gate patterns 306 is usable to manufacture a corresponding set of gates 406 of integrated circuit 100, 200, 400, 500, 600, 800, 900 or 1100. The set of gate patterns 308 is usable to manufacture a corresponding set of gates 408 of integrated circuit 100, 200, 400, 500, 600, 800, 900 or 1100.

In some embodiments, gate patterns 306a or 306b are usable to manufacture corresponding gates 406a or 406b of the set of gates 406 of integrated circuit 100, 200, 400, 500, 600, 800, 900 or 1100. In some embodiments, gate patterns 308a or 308b are usable to manufacture corresponding gates 408a or 408b of the set of gates 408 of integrated circuit 100, 200, 400, 500, 600, 800, 900 or 1100.

In some embodiments, at least one of the set of gates 406 or 408 are located on the front-side 403a of integrated circuit 100, 200, 400, 500, 600, 800, 900 or 1100.

In some embodiments, each of the gate patterns in the set of gate patterns 306 and 308 is shown in FIGS. 3A-3D with labels “PD1, PU1, PD2, PU2, PG1, PG2, X1, X2” that identify corresponding transistors of FIG. 2 manufactured by the corresponding gate pattern in FIGS. 3A-3D, and are omitted for brevity.

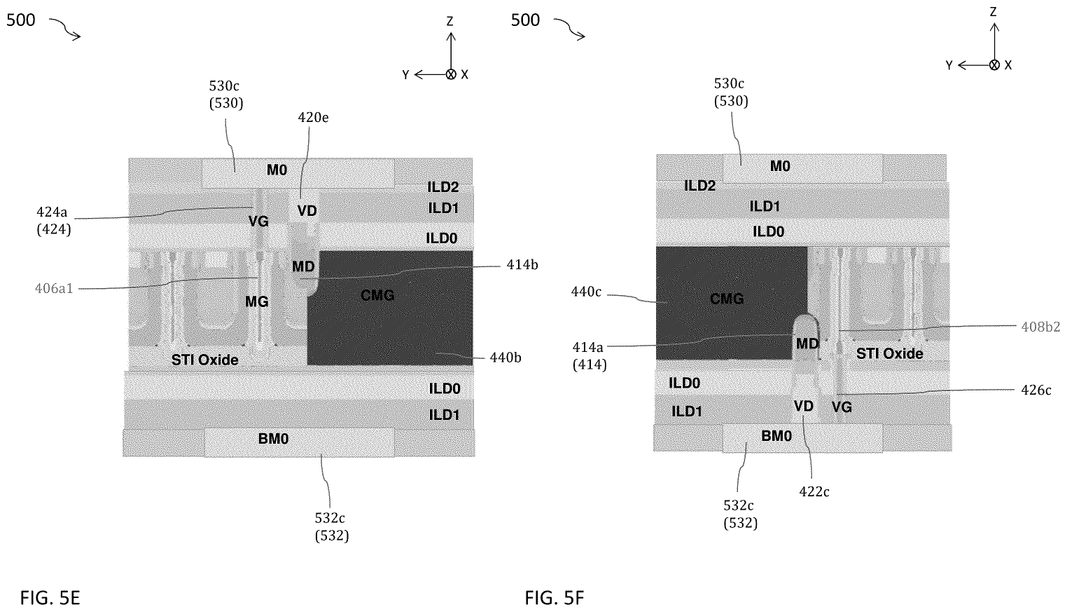

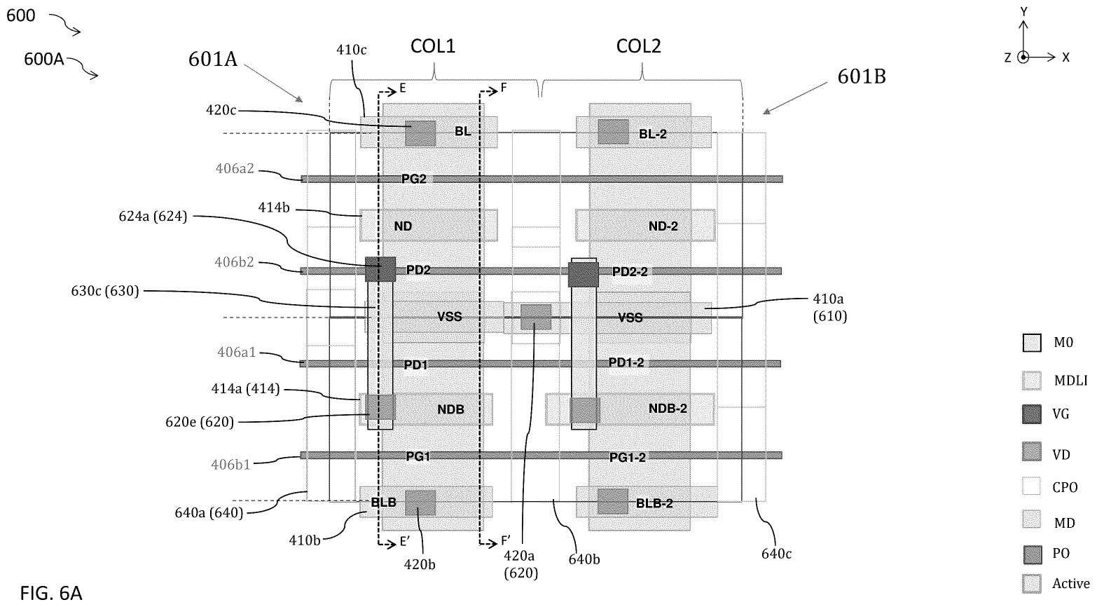

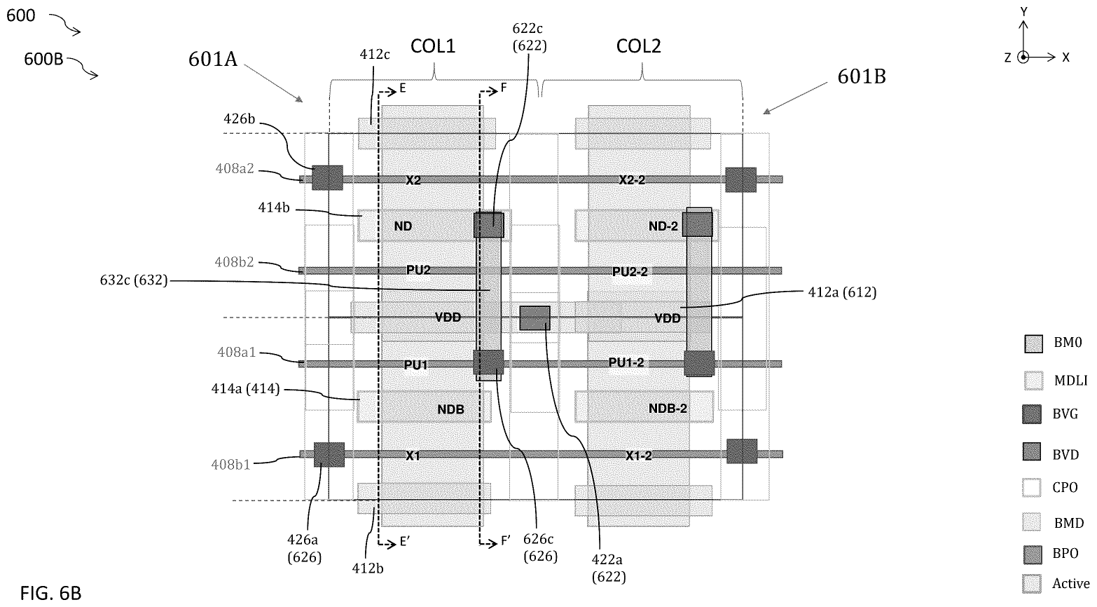

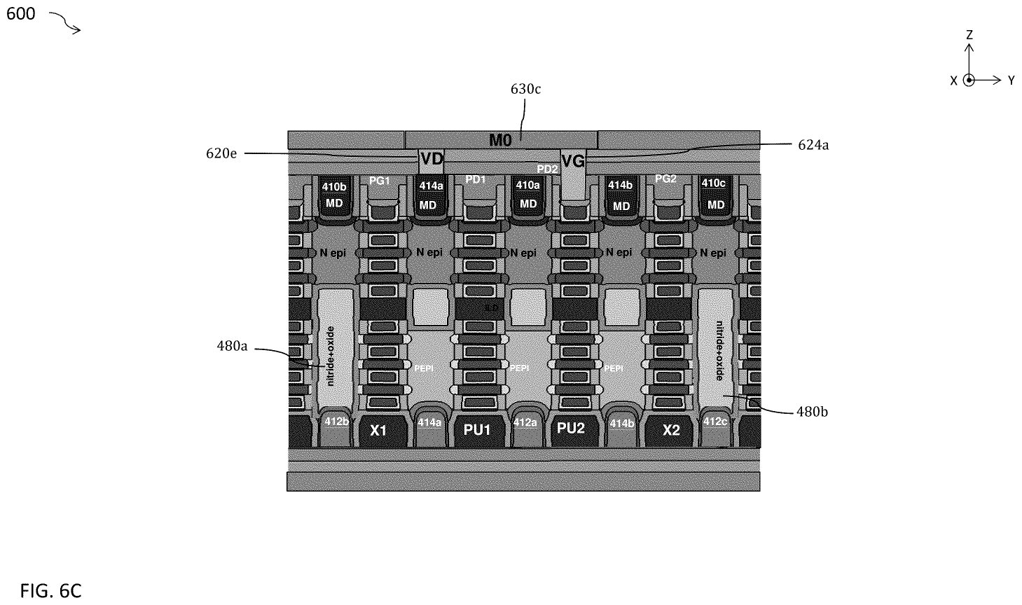

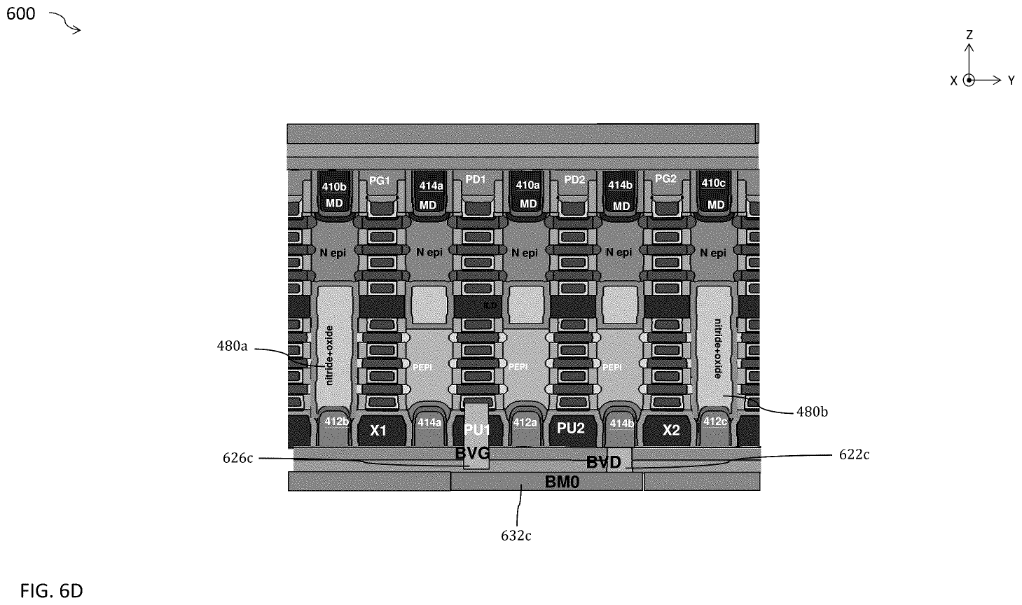

In some embodiments, at least one of label X1 or X2 is a corresponding dummy transistor on the back-side of layout design 300. In some embodiments, a dummy transistor is a non-functional transistor. In some embodiments, a dummy transistor is a transistor where the source and/or drain is replaced with a corresponding insulating region, such as insulating region 680a in FIG. 6C.

In some embodiments, the set of gate patterns 306 or 308 encapsulate the set of active region patterns 302 and 304. In some embodiments, at least a portion of the set of gate patterns 306 or 308 is above the set of active region patterns 302 and 304. In some embodiments, at least another portion of the set of gate patterns 306 or 308 is below the set of active region patterns 302 and 304.

The set of gate patterns 306 or 308 is positioned on a second layout level. In some embodiments, the second layout level is different from the first layout level. In some embodiments, the second layout level corresponds to the POLY level (also referred to as PO level or MG level) of one or more of layout design 300 or 700 or integrated circuits 100, 200, 400, 500, 600, 800, 900 or 1100. In some embodiments, the POLY level is above the BMD and the BM0 level.

Other configurations, arrangements on other layout levels or quantities of patterns in the set of gate patterns 306 or 308 are within the scope of the present disclosure.

Layout design 300 further includes one or more cut feature patterns 340a, 340b, 340c or 340d (collectively referred to as a “set of cut feature patterns 340”) extending in the second direction Y.

The set of cut feature patterns 340 is above the set of gate patterns 306 or 308.

At least one of cut feature pattern 340a, 340b, 340c or 340d is separated from another of cut feature pattern 340a, 340b, 340c or 340d in at least one of the first direction X or the second direction Y.

In some embodiments, the set of cut feature patterns 340 overlap at least a portion of a gate pattern of the set of gate patterns 306 or 308. In some embodiments, the set of cut feature patterns 340 overlaps other underlying patterns (not shown) of other layout levels (e.g., BM0, BMD, Active, MD, or the like) of layout design 300.

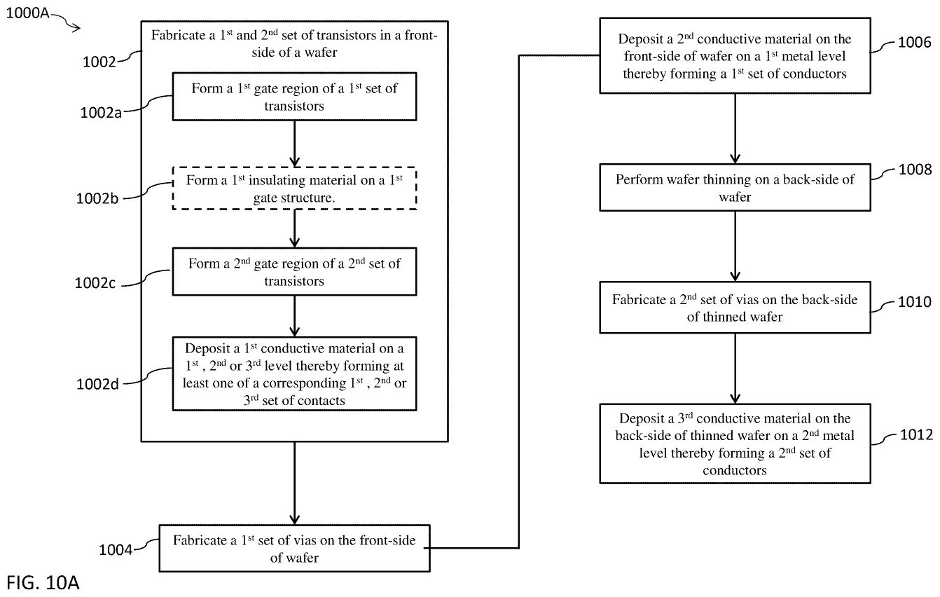

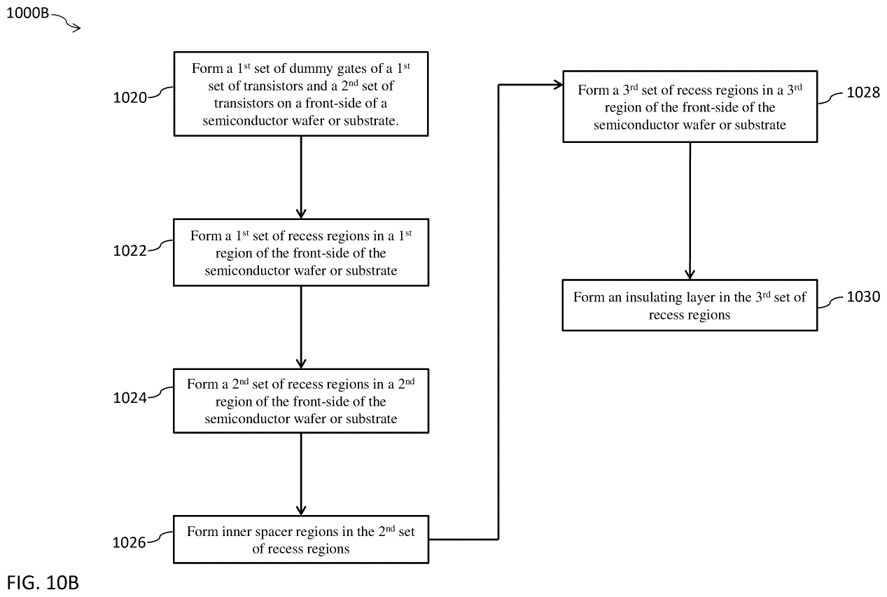

In some embodiments, cut feature patterns 340a, 340b, 340c or 340d identify corresponding locations of corresponding removed gate portions 440a, 440b, 440c or 440d of the set of removed gate portions 440 that are removed in operation 1004 of method 1000A-1000B (FIGS. 10A-10B).

In some embodiments, cut feature pattern 340b is usable to separate gate 406b2 and gate 406b1 from each other. In some embodiments, cut feature pattern 340b is usable to separate gate 408b2 and gate 408b1 from each other.

In some embodiments, cut feature pattern 340c is usable to separate gate 406a2 and gate 406a1 from each other. In some embodiments, cut feature pattern 340c is usable to separate gate 408a2 and gate 408a1 from each other.

In some embodiments, the set of cut feature patterns 340 is referred to as “a set of cut metal gate (CMG) patterns.” In some embodiments, cut feature patterns 340b and 340c are referred to as having a “zig-zag shape. ” In some embodiments, the cut feature pattern 340b is offset from the cut feature pattern 340c in the second direction Y thereby forming the “zig-zag shape.” In some embodiments, a side portion of cut feature pattern 340b is not aligned with a side portion of cut feature pattern 340c in the second direction Y. In some embodiments, a single side portion of cut feature pattern 340b is aligned with a single side portion of cut feature pattern 340c in the second direction Y.

Other configurations, arrangements on other layout levels or quantities of patterns in the set of cut feature patterns 340 are within the scope of the present disclosure. In some embodiments, at least one cut feature pattern of the set of cut feature patterns 340 is not included in layout design 300.

The set of cut feature patterns 340 is positioned on the second layout level.

Other configurations, arrangements on other layout levels or quantities of patterns in the set of cut feature patterns 340 are within the scope of the present disclosure.

Layout design 300 further includes one or more contact patterns 310a, 310b, 310c, 310d (collectively referred to as a “set of contact patterns 310”) extending in the first direction X.

Each of the contact patterns of the set of contact patterns 310 is separated from an adjacent contact pattern of the set of contact patterns 310 in at least the first direction X or the second direction Y.

The set of contact patterns 310 is usable to manufacture a corresponding set of contacts 410 of integrated circuit 100, 200, 400, 500, 600, 800, 900 or 1100.

In some embodiments, contact pattern 310a, 310b, 310c, 310d of the set of contact patterns 310 is usable to manufacture corresponding contact 410a, 410b, 410c, 410d of the set of contact patterns 410. In some embodiments, the set of contact patterns 310 is also referred to as a set of metal over diffusion (MD) patterns.

In some embodiments, at least one of contact pattern 310a, 310b, 310c, 310d of the set of contact patterns 310 is usable to manufacture source or drain terminals of the NFET of integrated circuit 100, 200, 400, 500, 600, 800, 900 or 1100.

In some embodiments, at least one of contact pattern 310a, 310b, 310c, 310d of the set of contact patterns 310 is usable to manufacture source or drain terminals of the PFET transistors of integrated circuit 100, 200, 400, 500, 600, 800, 900 or 1100.

In some embodiments, contact pattern 310a is usable to manufacture source/drain terminals of NFET transistor PD1, contact pattern 310b is usable to manufacture source/drain terminals of NFET transistor PG1, contact pattern 310c is usable to manufacture source/drain terminals of NFET transistor PG2, and contact pattern 310d is usable to manufacture source/drain terminals of NFET transistor PD2.

In some embodiments, the set of contact patterns 310 overlaps the set of active region patterns 302 or 304. The set of contact patterns 310 is located on a third layout level. In some embodiments, the third layout level corresponds to the contact level or an MD level of one or more of layout design 300 or integrated circuits 100, 200, 400, 500, 600, 800, 900 or 1100. In some embodiments, the third layout level is different from at least one of the first layout level or the second layout level. Other configurations, arrangements on other layout levels or quantities of patterns in the set of contact patterns 310 are within the scope of the present disclosure.

Layout design 300 further includes one or more contact patterns 312a, 312b, 312c, 312d (collectively referred to as a “set of contact patterns 312”) extending in the first direction X.

Each of the contact patterns of the set of contact patterns 312 is separated from an adjacent contact pattern of the set of contact patterns 312 in at least the first direction X or the second direction Y.

The set of contact patterns 310 and 312 are separated from one another in the third direction Z. In some embodiments, contact patterns 310a and 312a are separated from one another in the third direction Z. In some embodiments, contact patterns 310b and 312b are separated from one another in the third direction Z. In some embodiments, contact patterns 310c and 312c are separated from one another in the third direction Z. In some embodiments, contact patterns 310d and 312d are separated from one another in the third direction Z.

The set of contact patterns 312 is usable to manufacture a corresponding set of contacts 412 of integrated circuit 100, 200, 400, 500, 600, 800, 900 or 1100.

In some embodiments, contact pattern 312a, 312b, 312c, 312d of the set of contact patterns 312 is usable to manufacture corresponding contact 412a, 412b, 412c, 412d of the set of contacts 412. In some embodiments, the set of contacts 412 are on the front-side 403a of integrated circuit 400. In some embodiments, the set of contacts 412 are accessed by other layers (e.g., back-side layers) from a back-side 403b of integrated circuit 400. In some embodiments, the back-side 403b of integrated circuit 400 is opposite from the front-side of integrated circuit 400. In some embodiments, the set of contacts patterns 312 is also referred to as a set of back-side MD (BMD) patterns.

In some embodiments, contact pattern 312a is usable to manufacture source/drain terminals of PFET transistor PU1, contact pattern 312b is usable to manufacture source/drain terminals of PFET transistor X1, contact pattern 312c is usable to manufacture source/drain terminals of PFET transistor X2 and contact pattern 312d is usable to manufacture source/drain terminals of PFET transistor PU2.

In some embodiments, at least one of PFET transistor X1 or PFET transistor X2 is a corresponding dummy transistor.

In some embodiments, the set of contact patterns 312 are overlapped by the set of active region patterns 302 or 304. The set of contact patterns 312 is located on a fourth layout level. In some embodiments, the fourth layout level corresponds to the back-side contact level or a back-side MD (BMD) level of one or more of layout design 300 or integrated circuits 100, 200, 400, 500, 600, 800, 900 or 1100. In some embodiments, the fourth layout level is different from at least one of the first layout level, the second layout level or the third layout level.

In some embodiments, the BMD level is above the BM0 level. In some embodiments, the BMD level is below the back-side 403b of integrated circuit 400. In some embodiments, the BMD level is below the OD level, the POLY level, the MD level and the M0 level.

Other configurations, arrangements on other layout levels or quantities of patterns in the set of contact patterns 312 are within the scope of the present disclosure.

Layout design 300 further includes one or more contact patterns 314a, 314b (collectively referred to as a “set of contact patterns 314”) extending in the second direction Y.

Each of the contact patterns of the set of contact patterns 314 is separated from an adjacent contact pattern of the set of contact patterns 314 in at least the first direction X or the second direction Y.

In some embodiments, the set of contact patterns 314 is between the set of contact patterns 310 and 312. Contact pattern 314a is between contact patterns 310a and 310b. Contact pattern 314a is between contact patterns 312a and 312b. Contact pattern 314b is between contact patterns 310c and 310d. Contact pattern 314b is between contact patterns 312c and 312d.

In some embodiments, contact pattern 314a includes one or more separate discontinuous patterns. In some embodiments, contact pattern 314b includes one or more separate discontinuous patterns.

Contact patterns 314a and 314b are separated from one another in the first direction X.

The set of contact patterns 314 is usable to manufacture a corresponding set of contacts 414 of integrated circuit 100, 200, 400, 500, 600, 800, 900 or 1100.

In some embodiments, contact pattern 314a, 314b of the set of contact patterns 314 is usable to manufacture corresponding contact 414a, 414b of the set of contacts 414. In some embodiments, the set of contacts 414 are on a front-side 403a of integrated circuit 400. In some embodiments, the set of contacts patterns 314 is also referred to as a set of local interconnect (MDLI) patterns.

In some embodiments, at least one of contact pattern 314a, 314b of the set of contact patterns 314 is usable to manufacture interconnect structures usable to connect source or drain terminals of one of the NFET or PFET transistors of integrated circuit 100, 200, 400, 500, 600, 800, 900 or 1100.

In some embodiments, contact pattern 314a is usable to manufacture drain/source terminals of NFET transistor PD1, drain/source terminals of NFET PG1, drain/source terminals of PFET transistor PU1 and drain/source terminals of PFET X1.

In some embodiments, contact pattern 314a corresponds to node NDB of FIG. 2, and similar detailed description is omitted for brevity.

In some embodiments, contact pattern 314b is usable to manufacture drain/source terminals of NFET transistor PG2, drain/source terminals of NFET transistor PD2, drain/source terminals of PFET transistor X2 and drain/source terminals of PFET transistor PU2.

In some embodiments, contact pattern 314b corresponds to node ND of FIG. 2, and similar detailed description is omitted for brevity.

In some embodiments, at least a first portion of the set of contact patterns 314 are overlapped by one or more of the set of active region patterns 302 or 304. In some embodiments, at least a second portion of the set of contact patterns 314 is between the set of active region patterns 302 or 304. In some embodiments, at least a third portion of the set of contact patterns 314 is coplanar with the set of contact patterns 310 or the set of contact patterns 312.

The set of contact patterns 314 is located on a fifth layout level. In some embodiments, the fifth layout level corresponds to the MDLI level of one or more of layout design 300 or integrated circuits 100, 200, 400, 500, 600, 800, 900 or 1100. In some embodiments, the fifth layout level is different from at least one of the first layout level or the second layout level.

In some embodiments, the MDLI level includes the MD level and the BMD level. In some embodiments, the MDLI level is below the M0 level. In some embodiments, the MDLI level is above the BM0 level.

Other configurations, arrangements on other layout levels or quantities of patterns in the set of contact patterns 314 are within the scope of the present disclosure.

Layout design 300 further includes one or more conductive feature patterns 330a, 330b, 330c, 330d, 330e (collectively referred to as a “set of conductive feature patterns 330”) extending in the second direction Y.

Each conductive feature pattern in the set of conductive feature patterns 330 is separated from another conductive feature pattern in the set of conductive feature patterns 330 in the first direction X.

The set of conductive feature patterns 330 overlap at least one of the set of active region patterns 302 or 304, the set of gate patterns 306 or 308 or the set of contact patterns 310, 312 or 314.

The set of conductive feature patterns 330 is usable to manufacture a corresponding set of conductors 430 of integrated circuit 100, 200, 400, 500, 600, 800, 900 or 1100. Conductive feature patterns 330a, 330b, 330c, 330d, 330e are usable to manufacture corresponding conductors 430a, 430b, 430c, 430d, 430e of integrated circuit 100, 200, 400, 500, 600, 800, 900 or 1100. In some embodiments, at least one conductor of the set of conductors 430 is located on the front-side 403a of integrated circuit 100, 200, 400, 500, 600, 800, 900 or 1100.

In some embodiments, the set of conductive feature patterns 330 is located on a sixth layout level. In some embodiments, the sixth layout level is different from at least one of the first layout level, the second layout level, the third layout level, the fourth layout level or the fifth layout level. In some embodiments, the sixth layout level corresponds to the M0 level of one or more of layout design 300 or integrated circuits 100, 200, 400, 500, 600, 800, 900 or 1100. In some embodiments, the M0 level is above the OD level, the POLY level, the MD level, the BMD level, the MDLI level and the BM0 level.

In some embodiments, the set of conductive feature patterns 330 correspond to 5 M0 routing tracks. Other numbers of M0 routing tracks are within the scope of the present disclosure.

Other configurations, arrangements on other layout levels or quantities of patterns in the set of conductive feature patterns 330 are within the scope of the present disclosure.

Layout design 300 further includes one or more conductive feature patterns 332a, 332b, 332c, 332d, 332e (collectively referred to as a “set of conductive feature patterns 332”) extending in the first direction X.

Each conductive feature pattern in the set of conductive feature patterns 332 is separated from another conductive feature pattern in the set of conductive feature patterns 332 at least one of the first direction X or the second direction Y.

The set of conductive feature patterns 332 is overlapped by at least one of the set of active region patterns 302 or 304, the set of gate patterns 306 or 308, the set of contact patterns 310, 312 or 314 or the set of conductive feature patterns 330.

The set of conductive feature patterns 330 and 332 are separated from one another in the third direction Z. In some embodiments, conductive feature pattern 330a is separated from at least one of conductive feature pattern 332a or 332b in the third direction Z. In some embodiments, conductive feature patterns 330c and 332c are separated from one another in the third direction Z. In some embodiments, conductive feature pattern 330e is separated from at least one of conductive feature pattern 332d or 332e in the third direction Z.

The set of conductive feature patterns 332 is usable to manufacture a corresponding set of conductors 432 of integrated circuit 100, 200, 400, 500, 600, 800, 900 or 1100. Conductive feature patterns 332a, 332b, 332c, 332d, 332e are usable to manufacture corresponding conductors 432a, 432b, 432c, 432d, 432e of integrated circuit 100, 200, 400, 500, 600, 800, 900 or 1100. In some embodiments, at least one conductor of the set of conductors 432 is located on the back-side 403b of integrated circuit 100, 200, 400, 500, 600, 800, 900 or 1100.

In some embodiments, the set of conductive feature patterns 332 is located on a seventh layout level. In some embodiments, the seventh layout level is different from at least one of the first layout level, the second layout level, the third layout level, the fourth layout level, the fifth layout level or the sixth layout level. In some embodiments, the seventh layout level corresponds to the BM0 level of one or more of layout design 300 or integrated circuits 100, 200, 400, 500, 600, 800, 900 or 1100. some embodiments, the BM0 level is below the OD level, the POLY level, the MD level, the BMD level, the MDLI level and the BM0 level.

In some embodiments, the set of conductive feature patterns 332 correspond to 3 BM0 routing tracks. Other numbers of BM0 routing tracks are within the scope of the present disclosure.

In some embodiments, conductive feature pattern 330c is usable as a first butt-side contact pattern on the front-side of the layout design 300, and conductive feature pattern 332c is usable as a second butt-side contact pattern on the back-side of the layout design 300, thus improving routing resources and reducing are compared to other approaches.

Other configurations, arrangements on other layout levels or quantities of patterns in the set of conductive feature patterns 332 are within the scope of the present disclosure.

Layout design 300 further includes one or more via patterns 320a, 320b, 320c, 320d, 320e (collectively referred to as a “set of via patterns 320”).

The set of via patterns 320 is usable to manufacture a corresponding set of vias 420 of integrated circuit 100, 200, 400, 500, 600, 800, 900 or 1100. In some embodiments, via patterns 320a, 320b, 320c, 320d, 320e of the set of via patterns 320 are usable to manufacture corresponding vias 420a, 420b, 420c, 420d, 420e of the set of vias 420 of integrated circuit 100, 200, 400, 500, 600, 800, 900 or 1100.

In some embodiments, the set of via patterns 320 is between the set of contact patterns 310 and the set of conductive feature patterns 330.

Via pattern 320a is between contact pattern 310a and conductive feature pattern 330a.

Via pattern 320b is between contact pattern 310b and conductive feature pattern 330b.

Via pattern 320c is between contact pattern 310c and conductive feature pattern 330d.

Via pattern 320d is between contact pattern 310d and conductive feature pattern 330e.

Via pattern 320e is between contact pattern 314b and conductive feature pattern 330c.

The set of via patterns 320 is positioned at a via over diffusion (VD) level of one or more of layout design 300 or integrated circuits 100, 200, 400, 500, 600, 800, 900 or 1100. In some embodiments, the VD level is above the OD level, the POLY level, the MD level, the BMD level, the MDLI level and the BM0 level. In some embodiments, the VD level is below the M0 level. In some embodiments, the VD level is between the MD level and the M0 level. In some embodiments, the VD level is between the third layout level and the sixth layout level. Other layout levels are within the scope of the present disclosure.

Other configurations, arrangements on other layout levels or quantities of patterns in at least set of via patterns 320 are within the scope of the present disclosure.

Layout design 300 further includes one or more via patterns 322a, 322b, 322c (collectively referred to as a “set of via patterns 322”).

The set of via patterns 322 is usable to manufacture a corresponding set of vias 422 of integrated circuit 100, 200, 400, 500, 600, 800, 900 or 1100. In some embodiments, via patterns 322a, 322b, 322c of the set of via patterns 322 are usable to manufacture corresponding vias 422a, 422b, 422c of the set of vias 422 of integrated circuit 100, 200, 400, 500, 600, 800, 900 or 1100.

In some embodiments, the set of via patterns 322 is between the set of contact patterns 312 and the set of conductive feature patterns 332.

Via pattern 322a is between contact pattern 312a and conductive feature pattern 332b.

Via pattern 322b is between contact pattern 312d and conductive feature pattern 332d.

Via pattern 322c is between contact pattern 314a and conductive feature pattern 332c.

The set of via patterns 322 is positioned at a back-side via over diffusion (BVD) level of one or more of layout design 300 or integrated circuits 100, 200, 400, 500, 600, 800, 900 or 1100. In some embodiments, the BVD level is below the OD level, the POLY level, the MD level, the BMD level and the M0 level. In some embodiments, the BVD level is above the BM0 level. In some embodiments, the BVD level is between the BMD level and the BM0 level. In some embodiments, the BVD level is between the fourth layout level and the seventh layout level. Other layout levels are within the scope of the present disclosure.

Other configurations, arrangements on other layout levels or quantities of patterns in at least set of via patterns 322 are within the scope of the present disclosure.

Layout design 300 further includes one or more via patterns 324a (collectively referred to as a “set of via patterns 324”).

The set of via patterns 324 is usable to manufacture a corresponding set of vias 424 of integrated circuit 100, 200, 400, 500, 600, 800, 900 or 1100. In some embodiments, via patterns 324a of the set of via patterns 324 are usable to manufacture corresponding vias 424a of the set of vias 424 of integrated circuit 100, 200, 400, 500, 600, 800, 900 or 1100.

In some embodiments, the set of via patterns 324 is between the set of gate patterns 306 and the set of conductive feature patterns 330. Via pattern 324a is between gate pattern 306a and conductive feature pattern 330c.

The set of via patterns 324 is positioned at a via over gate (VG) level of one or more of layout design 300 or integrated circuits 100, 200, 400, 500, 600, 800, 900 or 1100. In some embodiments, the VG level is above the OD level, the POLY level, the MD level, the MDLI level, the BMD level and the BM0 level. In some embodiments, the VG level is below the M0 level. In some embodiments, the VG level is between the POLY level and the M0 level. In some embodiments, the VG level is between the second layout level and the sixth layout level. Other layout levels are within the scope of the present disclosure.

Other configurations, arrangements on other layout levels or quantities of patterns in at least set of via patterns 324 are within the scope of the present disclosure.

Layout design 300 further includes one or more via patterns 326a, 326b, 326c (collectively referred to as a “set of via patterns 326”).

The set of via patterns 326 is usable to manufacture a corresponding set of vias 426 of integrated circuit 100, 200, 400, 500, 600, 800, 900 or 1100. In some embodiments, via patterns 326a, 326b, 326c of the set of via patterns 326 are usable to manufacture corresponding vias 426a, 426b, 426c of the set of vias 426 of integrated circuit 100, 200, 400, 500, 600, 800, 900 or 1100.

In some embodiments, the set of via patterns 326 is between the set of gate patterns 308 and the set of conductive feature patterns 332.

Via pattern 326a is between gate pattern 308b and conductive feature pattern 332a.

Via pattern 326b is between gate pattern 308a and conductive feature pattern 332e.

Via pattern 326c is between gate pattern 308b and conductive feature pattern 332c.

The set of via patterns 326 is positioned at a back-side via over gate (BVG) level of one or more of layout design 300 or integrated circuits 100, 200, 400, 500, 600, 800, 900 or 1100. In some embodiments, the BVG level is below the OD level, the POLY level, the MD level, the MDLI level, the BMD level and the M0 level. In some embodiments, the BVG level is above the BM0 level. In some embodiments, the BVG level is between the POLY level and the BM0 level. In some embodiments, the BVG level is between the second layout level and the seventh layout level. Other layout levels are within the scope of the present disclosure.

Other configurations, arrangements on other layout levels or quantities of patterns in at least set of via patterns 326 are within the scope of the present disclosure.

In some embodiments, cut feature pattern 340b is usable to separate gate 406b2 and gate 406b1 from each other, and is usable to separate gate 408b2 and gate 408b1 from each other. In some embodiments, cut feature pattern 340c is usable to separate gate 406a2 and gate 406a1 from each other, and is usable to separate gate 408a2 and gate 408a1 from each other.

In some embodiments, by including the set of cut feature patterns 340 in layout design 300, causes cut feature pattern 340b to be offset from cut feature pattern 340c in the second direction Y thereby causes gates 406b2/408b2 and 406b1/408b1 to be separated from each other at a different position than where gates 406a2/408a2 and 406a1/408a1 are separated from each other in the second direction Y.

In some embodiments, by separating gates 406b2/408b2 and 406b1/408b1 at a different position from where gates 406a2/408a2 and 406a1/408a1 are separated, conductive feature pattern 330c is usable as a first butt-side contact pattern on the front-side of the layout design 300, and conductive feature pattern 332c is usable as a second butt-side contact pattern on the back-side of the layout design 300, thus improving routing resources of layout design 300 and reducing the area of layout design 300 compared to other approaches.

In some embodiments, by using conductive feature pattern 330c as a first butt-side contact pattern on the front-side of the layout design 300, and by using conductive feature pattern 332c as a second butt-side contact pattern on the back-side of the layout design 300, at least one of conductive feature pattern 330c or 332c have a simpler design than other approaches that have a more complex L-shape and use at least one more extra masks.

Other configurations, arrangements on other layout levels or quantities of patterns in layout design 300 are within the scope of the present disclosure.

FIGS. 4A-4F are diagrams of an integrated circuit 400, in accordance with some embodiments.

FIGS. 4A-4F are corresponding diagrams of corresponding portions 400A-400F of an integrated circuit 400, simplified for ease of illustration.

Portion 400A includes one or more features of integrated circuit 400 of the OD level, the POLY level, the CPO level, the MD level, the MDLI level, the VG level, the VD level and the M0 level. Portion 400A is manufactured by portion 300A.

Portion 400B includes one or more features of integrated circuit 400 of the OD level, the POLY level, the CPO level, the BMD level, the MDLI level, the BVG level, the BVD level and the BM0 level. Portion 400B is manufactured by portion 300B.

Portion 400C includes one or more features of integrated circuit 400 of the VG level, the VD level and the M0 level. Portion 400C is manufactured by portion 300C.

Portion 400D includes one or more features of integrated circuit 400 of the BVG level, the BVD level and the BM0 level. Portion 400D is manufactured by portion 300D.

FIGS. 4E-4F are corresponding cross-sectional views of integrated circuit 400, in accordance with some embodiments. FIG. 4E is a cross-sectional view of integrated circuit 400 as intersected by plane A-A′, in accordance with some embodiments. FIG. 4F is a cross-sectional view of integrated circuit 400 as intersected by plane B-B′, in accordance with some embodiments.

Components that are the same or similar to those in one or more of FIGS. 1, 2, 3A-3D, 4A-4F, 5A-5F, 6A-6D, 7A-7D, 8A-8D, 9A-9G or 11A-11I are given the same reference numbers, and detailed description thereof is thus omitted.

Integrated circuit 400 is manufactured by layout design 300. Integrated circuit 400 is cell 401. Structural relationships including alignment, lengths and widths, as well as configurations and layers of integrated circuit 400, 500, 600, 800, 900 or 1100 are similar to the structural relationships and configurations and layers of layout design 300 of FIGS. 3A-3D, and similar detailed description will not be described in at least FIGS. 4A-4F, for brevity. For example, in some embodiments, at least one or more widths, lengths or pitches of layout design 300 or 700 is similar to corresponding widths, lengths or pitches of integrated circuit 400, 500, 600, 800, 900 or 1100, and similar detailed description is omitted for brevity. For example, in some embodiments, at least cell boundary 301a or 301b is similar to at least corresponding cell boundary 401a or 401b of integrated circuit 400, and similar detailed description is omitted for brevity.

Integrated circuit 400 includes at least one or more of the set of active regions 402 and 404, the set of gates 406 and 408, the set of removed gate portions 440, the set of contacts 410, the set of contacts 412, the set of contacts 414, the set of conductors 430, the set of conductors 432, the set of vias 420, the set of vias 422, the set of vias 424, the set of vias 426, a substrate 490 or an insulating region 492.

The set of active regions 402 includes at least one or more active regions 402a, 402b.

The set of active regions 404 includes at least one or more active regions 404a, 404b.

The set of active regions 402 and 404 are embedded in a substrate 490. Substrate 490 has a front-side 403a and a back-side 403b opposite from the front-side 403a. In some embodiments, at least the set of active regions 402 and 404, the set of gates 406 and 408 or the set of contacts 410, 412 or 414 are formed in the front-side 403a of substrate 490.

In some embodiments, at least the set of vias 422 or the set of vias 426 are formed in the back-side 403b of substrate 490.

In some embodiments, the set of active regions 402 and 404 correspond to active regions of CFET transistors. In some embodiments, the set of active regions 402 include drain regions and source regions grown by an epitaxial growth process. In some embodiments, the set of active regions 402 include drain regions and source regions that are grown with an epitaxial material at the corresponding drain regions and source regions. In some embodiments, the set of active regions 402 and 404 correspond to nanosheet structures (not labelled) of nanosheet transistors.

Other transistor types are within the scope of the present disclosure. For example, in some embodiments, the set of active regions 402 corresponds to nanowire structures (not shown) of nanowire transistors. In some embodiments, the set of active regions 402 corresponds to planar structures (not shown) of planar transistors. In some embodiments, the set of active regions 402 corresponds to fin structures (not shown) of finFETs.

In some embodiments, active regions 402a and 402b correspond to source and drain regions of NFET transistors of integrated circuit 100, 200, 400, 500, 600, 800, 900 or 1100, and active regions 404a and 404b correspond to source and drain regions of PFET transistors of integrated circuit 100, 200, 400, 500, 600, 800, 900 or 1100.

In some embodiments, active regions 402a and 402b correspond to source and drain regions of PFET transistors of integrated circuit 100, 200, 400, 500, 600, 800, 900 or 1100, and active regions 404a and 404b correspond to source and drain regions of NFET transistors of integrated circuit 100, 200, 400, 500, 600, 800, 900 or 1100.

In some embodiments, at least active region 402a or 402b is an N-type doped S/D region, and at least active region 404a or 404b is a P-type doped S/D region embedded in a dielectric material of substrate 490. In some embodiments, at least active region 402a or 402b is a P-type doped S/D region, and at least active region 404a or 404b is an N-type doped S/D region embedded in a dielectric material of substrate 490.

In some embodiments, active region 404a includes at least one of active regions 404a1, 404a2 or 404a3.

In some embodiments, active region 404a3 is the source/drain of PFET transistor PU1.

In some embodiments, active region 404a2 is the drain/source of PFET transistor PU1.

In some embodiments, active region 404a1 is the drain/source of PFET transistor X1. In some embodiments, active region 404a1 includes an insulating region 480a (shown in FIG. 6C-6D). In some embodiments, active region 404a1 is a dummy active region that has been removed and is filled with insulating region 480a.

In some embodiments, active region 404b includes at least one of active regions 404b1, 404b2 or 404b3.

In some embodiments, active region 404b3 is the source/drain of PFET transistor PU2.

In some embodiments, active region 404b2 is the drain/source of PFET transistor PU2.

In some embodiments, active region 404b1 is the drain/source of PFET transistor X2. In some embodiments, active region 404b1 includes an insulating region 480b (shown in FIG. 6C-6D). In some embodiments, active region 404b1 is a dummy active region that has been removed and is filled with insulating region 480b.

In some embodiments, at least one of insulating region 480a or 480b is a dielectric material. In some embodiments, the dielectric material includes silicon dioxide, silicon oxy-nitride, silicon nitride or the like.

Other configurations, arrangements on other layout levels or quantities of structures in the set of active regions 402 or 404 are within the scope of the present disclosure.

Insulating region 492 is configured to electrically isolate one or more elements of the set of active regions 402 and 404, the set of gates 406 and 408, the set of contacts 410, the set of contacts 412, the set of contacts 414, the set of conductors 430, the set of conductors 432, the set of vias 420, the set of vias 422, the set of vias 424 or the set of vias 426 from one another. In some embodiments, insulating region 492 includes multiple insulating regions deposited at different times from each other during method 1000A-1000B (FIGS. 10A-10B). In some embodiments, insulating region 492 is a dielectric material. In some embodiments, the dielectric material includes silicon dioxide, silicon oxy-nitride, silicon nitride, or the like.

Other configurations, arrangements on other layout levels or other numbers of portions in insulating region 492 are within the scope of the present disclosure.

The set of gates 406 include one or more gates 406a or 406b.

The set of gates 408 include one or more gates 408a or 408b.

The set of gates 406 and 408 correspond to one or more gates of transistors PD1, PU1, PD2, PU2, PG1, PG2, X1, X2 of integrated circuits 100, 200, 400, 500, 600, 800, 900 or 1100. In some embodiments, each of the gates in the set of gates 406 and 408 are shown in FIGS. 4A-4F with labels “PD1, PU1, PD2, PU2, PG1, PG2, X1, X2” that identify corresponding transistors of FIG. 2 having corresponding gates in FIGS. 4A-4F, 5A-5F, 6A-6D, 7A-7D, 8A-8D, 9A-9G or 11A-11I, and are omitted for brevity.

Gate 406a includes one or more gates 406a1 or 406a2.

Gate 406b includes one or more gates 406b1 or 406b2.

Gate 408a includes one or more gates 408a1 or 408a2.

Gate 408b includes one or more gates 408b1 or 408b2.

In some embodiments, gate 406a1 is a gate of NFET transistor PD1, gate 406a2 is a gate of NFET transistor PG2, gate 406b1 is a gate of NFET transistor PG1, and gate 406b2 is a gate of NFET transistor PD2.

In some embodiments, gate 408a1 is a gate of PFET transistor PU1, gate 408a2 is a gate of PFET transistor X2, gate 408b1 is a gate of PFET transistor X2, and gate 408b2 is a gate of PFET transistor PU2.

In some embodiments, gate 406a1 and gate 406a2 are separated from each other in the first direction X by removed gate portion 440c.

In some embodiments, gate 406b1 and gate 406b2 are separated from each other in the first direction X by removed gate portion 440b.

In some embodiments, gate 408a1 and gate 408a2 are separated from each other in the first direction X by removed gate portion 440c.

In some embodiments, gate 408b1 and gate 408b2 are separated from each other in the first direction X by removed gate portion 440b.

In some embodiments, a first side of the insulating region 440c contacts a first side of the gate 406a1/408a1. In some embodiments, a first side of the insulating region 440b contacts a first side of the gate 406b1/408b1. In some embodiments, the first side of the insulating region 440c is offset in the first direction X from the first side of the insulating region 440b.

In some embodiments, a second side of the insulating region 440c contacts a first side of the gate 406a2/408a2. In some embodiments, a second side of the insulating region 440b contacts a first side of the gate 406b2/408a2. In some embodiments, the second side of the insulating region 440c is offset in the first direction X from the second side of the insulating region 440b.

In some embodiments, an offset pair of elements in the first direction X are a pair of elements having a corresponding side along the second direction Y that are not aligned in the second direction Y.

In some embodiments, the first side of the gate 406a1/408a1 is offset in the first direction X from the first side of the gate 406b1/408b1.

In some embodiments, the first side of the gate 406a2/408a2 is offset in the first direction X from the first side of the gate 406b2/408b2.

In some embodiments, gates 406a1 and 406a2 are the same continuous structure. In some embodiments, gates 408a1, 408a2 are the same continuous structure. In some embodiments, gates 406b1 and 406b2 are the same continuous structure. In some embodiments, gates 408b1 and 408b2 are the same continuous structure.

In some embodiments, gate 406a1 and gate 408a1 are coupled together. In some embodiments, gate 406a1 and gate 408a1 are part of the same continuous structure.

In some embodiments, gate 406a2 and gate 408a2 are coupled together. In some embodiments, gate 406a2 and gate 408a2 are part of the same continuous structure.

In some embodiments, gate 406b1 and gate 408b1 are coupled together. In some embodiments, gate 406b1 and gate 408b1 are part of the same continuous structure.

In some embodiments, gate 406b2 and gate 408b2 are coupled together. In some embodiments, gate 406b2 and gate 408b2 are part of the same continuous structure.

In some embodiments, gate 406a1, 406a2, 406b1 or 406b2 and corresponding gate 408a1, 408a2, 408b1 or 408b2 are separated from each other in the third direction Z by an insulating region (not shown).

In some embodiments, the set of gates 406 or 408 encapsulates the set of active regions 402 or 404.

Other configurations, arrangements on other layout levels or quantities of gates in the set of gates 406 and 408 are within the scope of the present disclosure.

The set of removed gate portions 440 include one or more removed gate portion 440a, 440b, 440c or 440d.

In some embodiments, one or more removed gate portions 440a, 440b, 440c or 440d is a corresponding insulating region (not labelled) similar to the set of insulating regions 492, and similar detailed description is therefore omitted.

In some embodiments, the removed gate portion 440a separates gate 406a1 from a gate in an adjacent cell along cell boundary 401c.

In some embodiments, the removed gate portion 440d separates gate 406b2 from a gate in an adjacent cell along cell boundary 401d.

In some embodiments, the removed gate portion 440a separates gate 408a1 from a gate in an adjacent cell along cell boundary 401c.

In some embodiments, the removed gate portion 440d separates gate 408b2 from a gate in an adjacent cell along cell boundary 401d.

In some embodiments, the removed gate portion 440c separates gate 406a1 from gate 406a2 in the first direction X.

In some embodiments, the removed gate portion 440c separates gate 408a1 from gate 408a2 in the first direction X.

In some embodiments, the removed gate portion 440b separates gate 406b1 from gate 406b2 in the first direction X.

In some embodiments, the removed gate portion 440b separates gate 408b1 from gate 408b2 in the first direction X.

In some embodiments, the one or more removed gate portions 440a, 440b, 440c or 440d is configured to electrically isolate the gates that are adjacent to the corresponding the one or more removed gate portions 440a, 440b, 440c or 440d.

Other configurations, arrangements on other layout levels or quantities of removed gate portions in the set of removed gate portions 440 are within the scope of the present disclosure.

The set of contacts 410 includes one or more contacts 410a, 410b, 410c or 410d.

The set of contacts 412 includes one or more contacts 412a, 412b, 412c or 412d.

Each contact of the set of contacts 410 or 412 corresponds to one or more drain or source terminals of transistors PD1, PU1, PD2, PU2, PG1, PG2, X1, X2 of integrated circuits 100, 200, 400, 500, 600, 800, 900 or 1100.

In some embodiments, one or more contacts of the set of contacts 410 overlaps a pair of active regions of the set of active regions 402, thereby electrically coupling the pair of active regions of the set of active regions 402, and the source or drain of the corresponding transistors.

In some embodiments, one or more contacts of the set of contacts 412 is overlapped by a pair of active regions of the set of active regions 404, thereby electrically coupling the pair of active regions of the set of active regions 404, and the source or drain of the corresponding transistors.

In some embodiments, the set of contacts 410 or 412 encapsulates the set of active regions 402 or 404.

In some embodiments, contact 410a is a source/drain terminal of NFET transistor PD1.

In some embodiments, contact 410b is a source/drain terminal of NFET transistor PG1.

In some embodiments, contact 410c is a source/drain terminal of NFET transistor PG2.

In some embodiments, contact 410d is a source/drain terminal of NFET transistor PD2.

In some embodiments, contact 412a is a source/drain terminal of PFET transistor PU1.

In some embodiments, contact 412b is a source/drain terminal of PFET transistor X1.

In some embodiments, contact 412c is a source/drain terminal of PFET transistor X2.

In some embodiments, contact 412d is a source/drain terminal of PFET transistor PU2.

The set of contacts 414 includes one or more contacts 414a or 414b.

In some embodiments, contact 414a is a drain/source terminal of NFET transistor PD1, a drain/source terminal of NFET PG1, a drain/source terminal of PFET transistor PU1 and a drain/source terminal of PFET X1.

In some embodiments, contact 414a corresponds to node NDB of FIG. 2, and similar detailed description is omitted for brevity.

In some embodiments, contact 414b is a drain/source terminal of NFET transistor PG2, a drain/source terminal of NFET transistor PD2, a drain/source terminal of PFET transistor X2 and a drain/source terminal of PFET transistor PU2.

In some embodiments, contact 414b corresponds to node ND of FIG. 2, and similar detailed description is omitted for brevity.

Other configurations, arrangements on other layout levels or quantities of contacts in the set of contacts 410, 412 and 414 are within the scope of the present disclosure.

The set of conductors 430 includes one or more conductors 430a, 430b, 430c, 430d or 430e.

The set of conductors 432 includes one or more conductors 432a, 432b, 432c, 432d or 432e.

The set of conductors 430 is M0 routing tracks. The set of conductors 432 is BM0 routing tracks. In some embodiments, the set of conductors 430 and 432 are routing tracks in other layers. In some embodiments, the set of conductors 430 corresponds to 5 M0 routing tracks. In some embodiments, the set of conductors 432 corresponds to 3 BM0 routing tracks.

In some embodiments, conductor 430a is configured to supply the reference supply voltage VSS, conductor 430b is the bit line bar BLB, conductor 430c is a butt-side contact, conductor 430d is the bit line BL, and conductor 430e is configured to supply the reference supply voltage VSS.

In some embodiments, conductor 432a is the word line WL, conductor 432b is configured to supply the supply voltage VDD, conductor 432c is a butt-side contact, conductor 432d is configured to supply the supply voltage VDD, and conductor 432e is the word line bar WL.

Other configurations, arrangements on other layout levels or quantities of conductors in the set of conductors 430 and 432 are within the scope of the present disclosure.

The set of vias 420 includes one or more vias 420a, 420b, 420c, 420d or 420e.

The set of vias 422 includes one or more vias 422a, 422b or 422c.

The set of vias 424 includes one or more vias 424a.

The set of vias 426 includes one or more vias 426a, 426b or 426c.

The set of vias 420 is configured to electrically couple a corresponding source or drain region of the set of active regions 402 to the set of conductors 430 by the set of contacts 410 or 414, and vice versa. The set of vias 420 is between the set of contacts 410 or 414 and the set of conductors 430.

The set of vias 422 is configured to electrically couple a corresponding source or drain region of the set of active regions 404 to the set of conductors 432 by the set of contacts 412 or 414, and vice versa. The set of vias 422 is between the set of contacts 412 or 414 and the set of conductors 432.

The set of vias 424 is configured to electrically couple one or more gates of the set of gates 406 to the set of conductors 430, and vice versa. The set of vias 424 is between the set of gates 406 and the set of conductors 430.

The set of vias 426 is configured to electrically couple one or more gates of the set of gates 408 to the set of conductors 432, and vice versa. The set of vias 426 is between the set of gates 408 and the set of conductors 432.

Via 420a electrically couples conductor 430a and contact 410a together. Via 420b electrically couples conductor 430b and contact 410b together. Via 420c electrically couples conductor 430d and contact 410c together. Via 420d electrically couples conductor 430e and contact 410d together. Via 420e electrically couples conductor 430c and contact 414b together.

Via 422a electrically couples conductor 432b and contact 412a together. Via 422b electrically couples conductor 432d and contact 412d together. Via 422c electrically couples conductor 432c and contact 414a together.

Via 424a electrically couples conductor 430c and gate 406a1 together.

Via 426a electrically couples conductor 432a and gate 408b1 together. Via 426b electrically couples conductor 432e and gate 408a2 together. Via 426c electrically couples conductor 432c and gate 408b2 together.

In some embodiments, at least one width in the first direction X of a via of the set of vias 420, 422, 424 or 426 is equal to at least one width in the first direction X of another via of the set of vias 420, 422, 424 or 426.

In some embodiments, at least one width in the first direction X of a via of the set of vias 420, 422, 424 or 426 is different from at least one width in the first direction X of another via of the set of vias 420, 422, 424 or 426.

Other configurations, arrangements on other layout levels or quantities of vias in the set of vias 420, 422, 424 and 426 are within the scope of the present disclosure.

In some embodiments, at least one gate of the set of gates 406 or 408 are formed using a doped or non-doped polycrystalline silicon (or polysilicon). In some embodiments, at least one gate of the set of gates 406 or 408 include a metal, such as Al, Cu, W, Ti, Ta, TiN, TaN, NiSi, CoSi, other suitable conductive materials, or combinations thereof.

In some embodiments, at least one contact of the set of contacts 410, 412 or 414, or at least one conductor of the set of conductors 430 or 432, or at least one via of the set of vias 420, 422, 424 or 426 includes one or more layers of a conductive material, a metal, a metal compound or a doped semiconductor. In some embodiments, the conductive material includes Tungsten, Cobalt, Ruthenium, Copper, or the like or combinations thereof. In some embodiments, a metal includes at least Cu (Copper), Co, W, Ru, Al, or the like. In some embodiments, a metal compound includes at least AlCu, W—TiN, TiSix, NiSix, TiN, TaN, or the like. In some embodiments, a doped semiconductor includes at least doped silicon, or the like.

In some embodiments, conductor 430c electrically couples node ND of memory cell 200 with the gate of NFET transistor PD1 and the gate of NFET transistor PU1 on the front-side 403a of integrated circuit 400. For example, in some embodiments, conductor 430c electrically couples gate 406a1 and contact 414b together on the front-side 403a of integrated circuit 400.

In some embodiments, conductor 432c electrically couples node NDB of memory cell 200 with the gate of NFET transistor PD2 and the gate of NFET transistor PU2 on the back-side 403b of integrated circuit 400. For example, in some embodiments, conductor 432c electrically couples gate 408b2 and contact 414a together on the back-side 403b of integrated circuit 400.

In some embodiments, gates 406b2/408b2 and 406b1/408b1 are separated from each other at a different position from where gates 406a2/408a2 and 406a1/408a1 are separated from each other in the second direction Y.

In some embodiments, by separating gates 406b2/408b2 and 406b1/408b1 at a different position from where gates 406a2/408a2 and 406a1/408a1 are separated, conductor 430c is usable as a first butt-side contact on the front-side 403a of integrated circuit 400, and conductor 432c is usable as a second butt-side contact on the back-side 403b of integrated circuit 400, thus improving routing resources of integrated circuit 400 and reducing the area of integrated circuit 400 compared to other approaches.

In some embodiments, by using conductor 430c as a first butt-side contact on the front-side 403a of integrated circuit 400, and by using conductor 432c as a second butt-side contact on the back-side 403b of integrated circuit 400, at least one of conductor 430c or 432c has a simpler design than other approaches that have a more complex L-shape and use at least one more extra masks.

Other configurations, arrangements on other levels or quantities of elements in integrated circuit 400 are within the scope of the present disclosure.

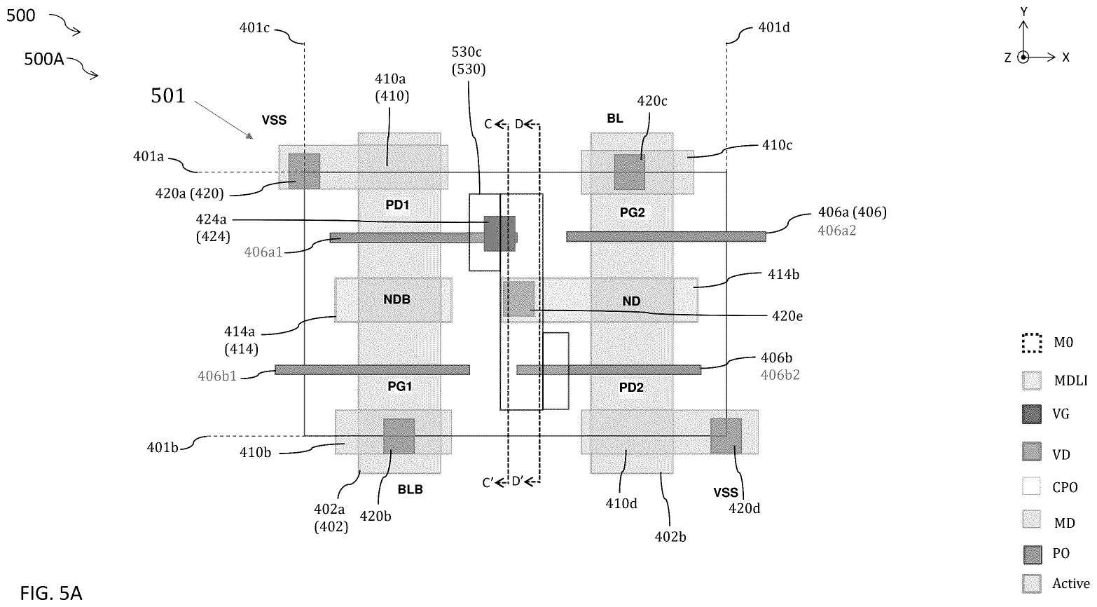

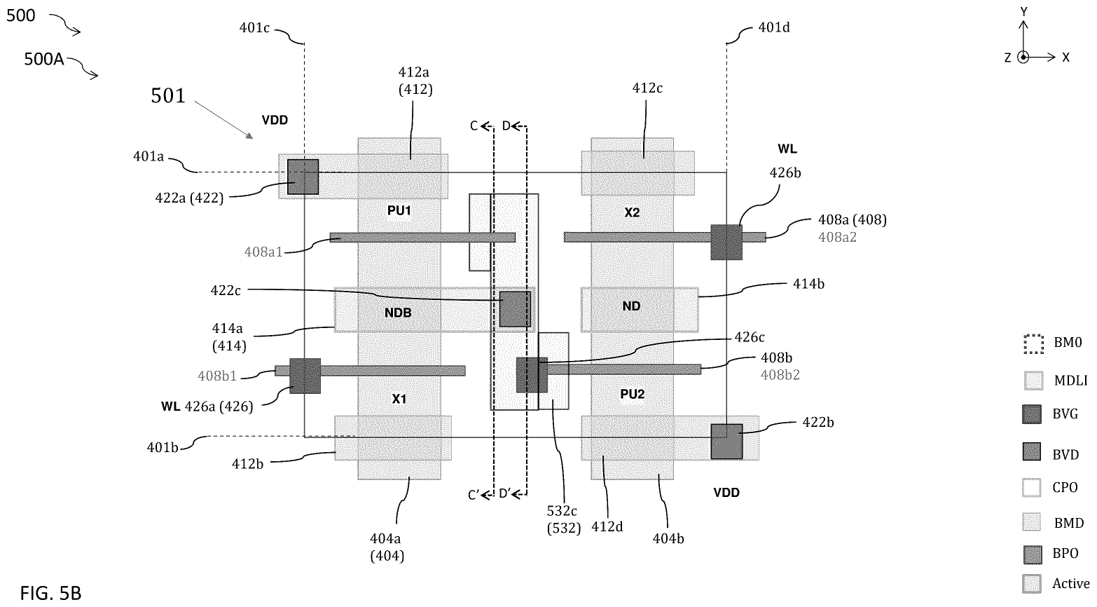

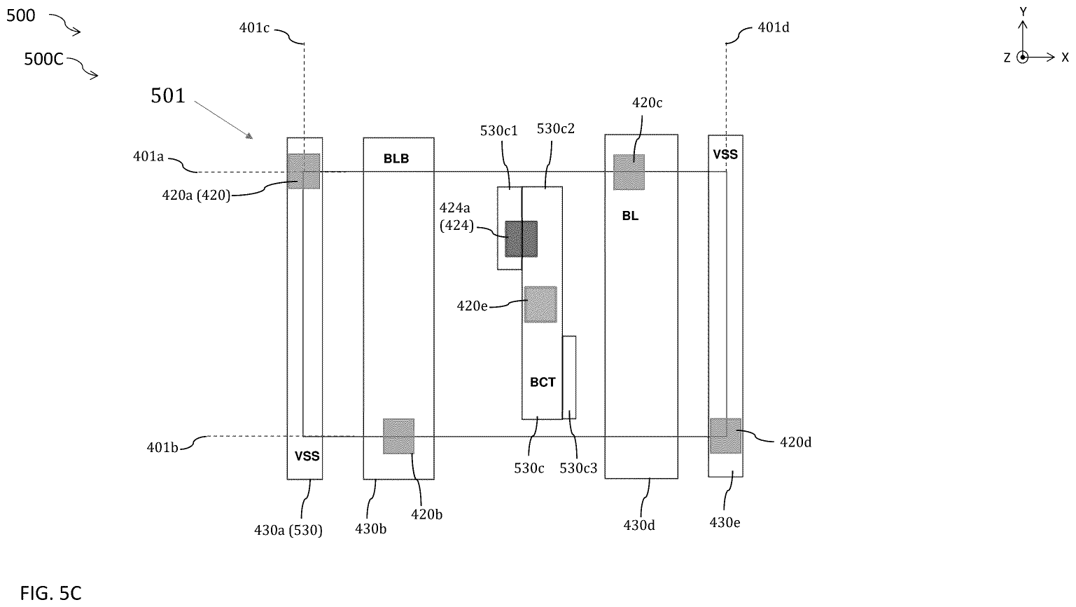

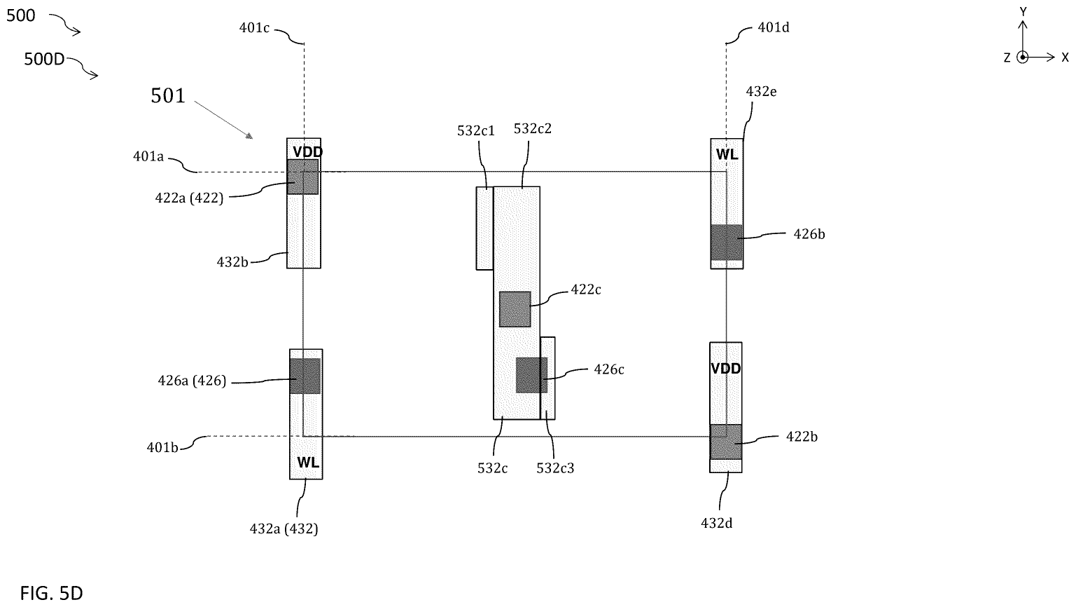

FIGS. 5A-5F are diagrams of an integrated circuit 500, in accordance with some embodiments.

FIGS. 5A-5D are corresponding diagrams of corresponding portions 500A-500D of an integrated circuit 500, simplified for ease of illustration.

Portion 500A includes one or more features of integrated circuit 500 of the OD level, the POLY level, the CPO level, the MD level, the MDLI level, the VG level, the VD level and the M0 level. Portion 500A is manufactured by a layout design similar to at least portion 300A, and similar detailed description is omitted for brevity.

Portion 500B includes one or more features of integrated circuit 500 of the OD level, the POLY level, the CPO level, the BMD level, the MDLI level, the BVG level, the BVD level and the BM0 level. Portion 500B is manufactured by a layout design similar to at least portion 300B, and similar detailed description is omitted for brevity.

Portion 500C includes one or more features of integrated circuit 400 of the VG level, the VD level and the M0 level. Portion 500C is manufactured by a layout design similar to at least portion 300C, and similar detailed description is omitted for brevity.

Portion 500D includes one or more features of integrated circuit 400 of the BVG level, the BVD level and the BM0 level. Portion 500D is manufactured by a layout design similar to at least portion 300D, and similar detailed description is omitted for brevity.

FIGS. 5E-5F are corresponding cross-sectional views of integrated circuit 500, in accordance with some embodiments. FIG. 5E is a cross-sectional view of integrated circuit 500 as intersected by plane C-C′, in accordance with some embodiments. FIG. 5F is a cross-sectional view of integrated circuit 500 as intersected by plane D-D′, in accordance with some embodiments.

In some embodiments, integrated circuit 500 is memory cell 200.

Integrated circuit 500 is manufactured by a corresponding layout design similar to integrated circuit 500.

In some embodiments, integrated circuit 500 is manufactured by a layout design similar to layout design 300, and similar detailed description is therefore omitted. Structural relationships including alignment, lengths and widths, as well as configurations and layers of integrated circuit 500 are similar to the structural relationships and configurations and layers of integrated circuit 400 of FIGS. 4A-4F, and similar detailed description will not be described in at least FIGS. 5A-5F, for brevity.

Integrated circuit 500 is cell 501.

Integrated circuit 500 is a variation of integrated circuit 400 of FIGS. 4A-4F, and similar detailed description is omitted for brevity.

In comparison with integrated circuit 400 of FIGS. 4A-4F, a set of conductors 530 replaces the set of conductors 430 of integrated circuit 400, and a set of conductors 532 replaces the set of conductors 432 of integrated circuit 400, and similar detailed description is omitted for brevity.

Integrated circuit 500 includes at least the set of active regions 402 and 404, the set of gates 406 and 408, the set of removed gate portions 440, the set of contacts 410, the set of contacts 412, the set of contacts 414, the set of conductors 530, the set of conductors 532, the set of vias 420, the set of vias 422, the set of vias 424, the set of vias 426, the substrate 490, and the insulating region 492.

The set of conductors 530 includes at least one of conductor 430a, 430b, 530c, 430d or 430e.

In comparison with integrated circuit 400, conductor 530c of the set of conductors 530 replaces conductor 430c of the set of conductors 430, and similar detailed description is omitted for brevity.

In comparison with conductor 430c of integrated circuit 400, conductor 530c of integrated circuit 500 has an increased area, and similar detailed description is omitted for brevity.

In some embodiments, conductor 530c includes a conductive portion 530c1, a conductive portion 530c2 and a conductive portion 530c3.

In some embodiments, conductive portion 530c2 is a central portion connected to each of conductive portion 530c1 and conductive portion 530c3. In some embodiments, conductive portion 530c1 is connected to a first side of conductive portion 530c2 at a first end. In some embodiments, conductive portion 530c3 is connected to a second side of conductive portion 530c2 at a second end.

In some embodiments, the first side of conductive portion 530c2 is opposite from the second side of conductive portion 530c2. In some embodiments, the first end of conductive portion 530c2 is opposite from the second end of conductive portion 530c2.

In some embodiments, conductor 530c has “a zig-zag shape.”

In comparison with conductor 430c of integrated circuit 400, conductor 530c of integrated circuit 500 has an increased length in the second direction Y and an increased width in the first direction X thereby resulting in conductor 530c having an increased area.

In some embodiments, by increasing the area of conductor 530c causes the capacitive coupling between conductor 430b and 430d to be reduced thereby improving the speed and performance of integrated circuit 500 compared to other approaches.

The set of conductors 530 is M0 routing tracks. In some embodiments, the set of conductors 530 is routing tracks in other layers. In some embodiments, the set of conductors 530 corresponds to 5 M0 routing tracks. Other M0 track assignments or numbers of M0 tracks are within the scope of the present disclosure.

Other configurations, arrangements on other layout levels or quantities of conductors in the set of conductors 530 are within the scope of the present disclosure.

The set of conductors 532 includes at least one of conductor 432a, 432b, 532c, 432d or 432e.

In comparison with integrated circuit 400, conductor 532c of the set of conductors 532 replaces conductor 432c of the set of conductors 432, and similar detailed description is omitted for brevity.

In comparison with conductor 432c of integrated circuit 400, conductor 532c of integrated circuit 500 has an increased area, and similar detailed description is omitted for brevity.

In some embodiments, conductor 532c includes a conductive portion 532c1, a conductive portion 532c2 and a conductive portion 532c3.

In some embodiments, conductive portion 532c2 is a central portion connected to each of conductive portion 532c1 and conductive portion 532c3. In some embodiments, conductive portion 532c1 is connected to a first side of conductive portion 532c2 at a first end. In some embodiments, conductive portion 532c3 is connected to a second side of conductive portion 532c2 at a second end.

In some embodiments, the first side of conductive portion 532c2 is opposite from the second side of conductive portion 532c2. In some embodiments, the first end of conductive portion 532c2 is opposite from the second end of conductive portion 532c2.

In some embodiments, conductor 532c has “a zig-zag shape.”

In comparison with conductor 432c of integrated circuit 400, conductor 532c of integrated circuit 500 has an increased length in the second direction Y and an increased width in the first direction X thereby resulting in conductor 532c having an increased area.

In some embodiments, by increasing the area of conductor 532c causes the capacitive coupling between conductor 432b and 432d to be reduced thereby improving the speed and performance of integrated circuit 500 compared to other approaches.

The set of conductors 532 is BM0 routing tracks. In some embodiments, the set of conductors 532 is routing tracks in other layers. In some embodiments, the set of conductors 532 corresponds to 3 BM0 routing tracks. Other BM0 track assignments or numbers of BM0 tracks are within the scope of the present disclosure.

Other configurations, arrangements on other layout levels or quantities of conductors in the set of conductors 532 are within the scope of the present disclosure.

In some embodiments, by including conductor 530c in integrated circuit 500, the capacitive coupling between the bit line BL and the bit line bar BLB is reduced thereby improving the speed and performance of integrated circuit 500 compared to other approaches.

In some embodiments, integrated circuit 500 achieves one or more of the benefits described herein.

Other configurations, arrangements on other levels or quantities of elements in integrated circuit 500 are within the scope of the present disclosure.

FIGS. 6A-6D are diagrams of an integrated circuit 600, in accordance with some embodiments.

FIGS. 6A-6D are corresponding diagrams of corresponding portions 600A-600D of an integrated circuit 600, simplified for ease of illustration.

Portion 600A includes one or more features of integrated circuit 600 of the OD level, the POLY level, the CPO level, the MD level, the MDLI level, the VG level, the VD level and the M0 level.

Portion 600B includes one or more features of integrated circuit 600 of the OD level, the POLY level, the CPO level, the BMD level, the MDLI level, the BVG level, the BVD level and the BM0 level.

FIGS. 6C-6D are corresponding cross-sectional views of integrated circuit 600, in accordance with some embodiments. FIG. 6C is a cross-sectional view of integrated circuit 600 as intersected by plane E-E′, in accordance with some embodiments. FIG. 6DF is a cross-sectional view of integrated circuit 600 as intersected by plane F-F′, in accordance with some embodiments.

Integrated circuit 600 is manufactured by a corresponding layout design similar to integrated circuit 600.

Integrated circuit 600 is a variation of integrated circuit 400 of FIGS. 4A-4D, and similar detailed description is omitted for brevity. In comparison with integrated circuit 400 of FIGS. 4A-4D, integrated circuit 600 includes two columns of memory cells (e.g., cell 601A and cell 601B), and similar detailed description is omitted for brevity.

Integrated circuit 600 includes a cell 601A and a cell 601B. In some embodiments, at least one of cell 601A or cell 601B is memory cell 200. In some embodiments, at least one of cell 601A or cell 601B is a variation of integrated circuit 400 of FIGS. 4A-4D, and similar detailed description is omitted for brevity.

Cell 601A is located in a column COL1.

Cell 601B is located in a column COL2. In some embodiments, column COL2 is adjacent or directly next to column COL1.

In comparison with integrated circuit 400 of FIGS. 4A-4D, each of the elements of cell 601A are located in a single column (e.g., column COL1) whereas integrated circuit 400 of FIGS. 4A-4D is located in 2 columns, and similar detailed description is omitted for brevity.

In comparison with integrated circuit 400 of FIGS. 4A-4D, each of the elements of cell 601B are located in a single column (e.g., column COL2) whereas integrated circuit 400 of FIGS. 4A-4D is located in 2 columns, and similar detailed description is omitted for brevity.

In comparison with integrated circuit 400 of FIGS. 4A-4D, a set of contacts 610 replaces the set of contacts 410 of integrated circuit 400, a set of contacts 612 replaces the set of contacts 412 of integrated circuit 400, a set of removed gate portions 640 replaces the set of removed gate portions 440 of integrated circuit 400, a set of conductors 630 replaces the set of conductors 430 of integrated circuit 400, a set of conductors 632 replaces the set of conductors 432 of integrated circuit 400, a set of vias 620 replaces the set of vias 420 of integrated circuit 400, a set of vias 622 replaces the set of vias 422 of integrated circuit 400, a set of vias 624 replaces the set of vias 424 of integrated circuit 400, a set of vias 626 replaces the set of vias 426 of integrated circuit 400, and similar detailed description is omitted for brevity.

Cell 601A includes at least one or more of the set of active regions 402 and 404, the set of gates 406 and 408, the set of removed gate portions 640, the set of contacts 610, the set of contacts 612, the set of contacts 414, the set of conductors 630, the set of conductors 632, the set of vias 620, the set of vias 622, the set of vias 624, the set of vias 626, the substrate 490 and the insulating region 492.

The set of contacts 610 includes at least one of contact 410a, 410b or 410c.

In comparison with integrated circuit 400, each of contacts 410b and 410c of integrated circuit 600 are located in a single column (e.g., column COL1), and similar detailed description is omitted for brevity.

In comparison with integrated circuit 400, contact 410a of integrated circuit 600 is located in two columns (e.g., columns COL1 and COL2), and similar detailed description is omitted for brevity.

In some embodiments, by rearranging cell 601A as shown in FIGS. 6A-6D, the reference voltage supply VSS is supplied by a single contact (e.g., contact 410a).

Other configurations, arrangements on other layout levels or quantities of contacts in the set of contacts 610 are within the scope of the present disclosure.

The set of contacts 612 includes at least one of contact 412a, 412b or 412c.

In comparison with integrated circuit 400, each of contacts 412b and 412c of integrated circuit 600 are located in a single column (e.g., column COL1), and similar detailed description is omitted for brevity.

In comparison with integrated circuit 400, contact 412a of integrated circuit 600 is located in two columns (e.g., columns COL1 and COL2), and similar detailed description is omitted for brevity.

In some embodiments, by rearranging cell 601A as shown in FIGS. 6A-6D, the voltage supply VDD is supplied by a single contact (e.g., contact 412a).

Other configurations, arrangements on other layout levels or quantities of contacts in the set of contacts 612 are within the scope of the present disclosure.

In comparison with integrated circuit 400, each of contacts 414a and 414b of integrated circuit 600 are located in a single column (e.g., column COL1), and similar detailed description is omitted for brevity.

The set of conductors 630 includes at least one of conductor 430b, 630c or 430d. For ease of illustration, conductor 430b (e.g., bit line bar BLB) and conductor 430b (e.g., bit line BL) are not shown in FIG. 6A-6D, and similar detailed description is omitted for brevity.

In comparison with integrated circuit 400, conductor 630c of the set of conductors 630 replaces conductor 430c of the set of conductors 430, and similar detailed description is omitted for brevity.

The set of conductors 630 is M0 routing tracks. In some embodiments, the set of conductors 630 is routing tracks in other layers. Other M0 track assignments or numbers of M0 tracks are within the scope of the present disclosure.

Other configurations, arrangements on other layout levels or quantities of conductors in the set of conductors 630 are within the scope of the present disclosure.

The set of conductors 632 includes at least one of conductor 432a, 432b or 632c.

For ease of illustration, conductors 432a (e.g., word line WL) and conductor 432b (e.g., word line WL) are not shown in FIG. 6A-6D, and similar detailed description is omitted for brevity. In some embodiments, conductors 432a and 432b are a single continuous structure configured as the word line WL.

In comparison with integrated circuit 400, conductor 632c of the set of conductors 632 replaces conductor 432c of the set of conductors 432, and similar detailed description is omitted for brevity.

The set of conductors 632 is BM0 routing tracks. In some embodiments, the set of conductors 632 is routing tracks in other layers. Other BM0 track assignments or numbers of BM0 tracks are within the scope of the present disclosure.

Other configurations, arrangements on other layout levels or quantities of conductors in the set of conductors 632 are within the scope of the present disclosure.

The set of removed gate portions 640 includes at least one of removed gate portion 640a, 640b or 640c.

In some embodiments, one or more removed gate portions 640a, 640b or 640c is a corresponding insulating region (not labelled) similar to the set of insulating regions 492, and similar detailed description is therefore omitted.

In some embodiments, the insulating region of removed gate portion 640a is configured to electrically insulate gate 406a2 from adjacent gates. In some embodiments, the insulating region of removed gate portion 640a is configured to electrically insulate gate 408a2 from adjacent gates.

In some embodiments, the insulating region of removed gate portion 640a is configured to electrically insulate gate 406b2 from adjacent gates. In some embodiments, the insulating region of removed gate portion 640a is configured to electrically insulate gate 408b2 from adjacent gates.

In some embodiments, the insulating region of removed gate portion 640a is configured to electrically insulate gate 406a1 from adjacent gates. In some embodiments, the insulating region of removed gate portion 640a is configured to electrically insulate gate 408a1 from adjacent gates.

In some embodiments, the insulating region of removed gate portion 640a is configured to electrically insulate gate 406b1 from adjacent gates. In some embodiments, the insulating region of removed gate portion 640a is configured to electrically insulate gate 408b1 from adjacent gates.

In some embodiments, the insulating region of removed gate portion 640b is configured to electrically insulate gates 406a2, 406a1, 406b2, 406b1, 408a2, 408a1, 408b2 and 408b1 in column COL1 of cell 601B from gates in column COL2 of cell 601B.

In some embodiments, the insulating region of removed gate portion 640c is configured to electrically insulate gates in column COL2 of cell 601B from adjacent gates located in another column.

In comparison with integrated circuit 400, each of gates 406a2, 406a1, 406b2, 406b1, 408a2, 408a1, 408b2 and 408b1 of integrated circuit 600 is located in a single column (e.g., columns COL1), and similar detailed description is omitted for brevity.

In comparison with removed gate portions 440b and 440c of integrated circuit 400, removed gate portions 640a, 640b and 640c of integrated circuit 600 have a rectangular shape in the first direction X and the second direction Y.

Other configurations, arrangements on other layout levels or quantities of removed gate portions in the set of removed gate portions 640 are within the scope of the present disclosure.

The set of vias 620 includes at least one of via 420a, 420b, 420c or 620e.

In comparison with integrated circuit 400, via 620e of the set of vias 620 replaces via 420e of the set of vias 420, and similar detailed description is omitted for brevity.

In comparison with integrated circuit 400, via 620e of the set of vias 620 is electrically connected to conductor 630c and contact 414a, and similar detailed description is omitted for brevity.

Other configurations, arrangements on other layout levels or quantities of vias in the set of vias 620 are within the scope of the present disclosure.

The set of vias 622 includes at least one of via 422a or 622c.

In comparison with integrated circuit 400, via 622c of the set of vias 622 replaces via 422c of the set of vias 422, and similar detailed description is omitted for brevity.

In comparison with integrated circuit 400, via 622c of the set of vias 622 is electrically connected to conductor 632c and contact 414b, and similar detailed description is omitted for brevity.

Other configurations, arrangements on other layout levels or quantities of vias in the set of vias 622 are within the scope of the present disclosure.

The set of vias 624 includes at least one of via 624a.

In comparison with integrated circuit 400, via 624a of the set of vias 622 replaces via 424a of the set of vias 424, and similar detailed description is omitted for brevity.

In comparison with integrated circuit 400, via 624a of the set of vias 624 is electrically connected to conductor 630c and gate 406b2, and similar detailed description is omitted for brevity.

Other configurations, arrangements on other layout levels or quantities of vias in the set of vias 624 are within the scope of the present disclosure.

The set of vias 626 includes at least one of via 426a, 426b or 626c.

In comparison with integrated circuit 400, via 626c of the set of vias 626 replaces via 426c of the set of vias 426, and similar detailed description is omitted for brevity.

In comparison with integrated circuit 400, via 626c of the set of vias 626c is electrically connected to conductor 632c and gate 408a1, and similar detailed description is omitted for brevity.

Other configurations, arrangements on other layout levels or quantities of vias in the set of vias 626 are within the scope of the present disclosure.

In some embodiments, cell 601B includes the same elements as cell 601A, the labels of the same elements in cell 601B are changed by adding “−2” to the end of corresponding element in cell 601B, and similar detailed description is omitted for brevity. For example, bit line BL in cell 601A is labeled as “bit line BL-2” in cell 601B, and similar detailed description is omitted for brevity

Cell 601B includes at least one or more of the set of active regions 402 and 404, the set of gates 406 and 408, the set of removed gate portions 640, the set of contacts 610, the set of contacts 612, the set of contacts 414, the set of conductors 630, the set of conductors 632, the set of vias 620, the set of vias 622, the set of vias 624, the set of vias 626, the substrate 490 and the insulating region 492.

In some embodiments, conductor 630c electrically couples node NDB of memory cell 200 with the gate of NFET transistor PD2 and the gate of NFET transistor PU2 on the front-side 403a of integrated circuit 600. For example, in some embodiments, conductor 630c electrically couples gate 406b2 and contact 414a together on the front-side 403a of integrated circuit 600.

In some embodiments, conductor 632c electrically couples node ND of memory cell 200 with the gate of NFET transistor PU1 and the gate of NFET transistor PD1 on the back-side 403b of integrated circuit 600. For example, in some embodiments, conductor 632c electrically couples gate 408a1 and contact 414b together on the back-side 403b of integrated circuit 600.

In some embodiments, conductor 630c is usable as a first butt-side contact on the front-side 403a of integrated circuit 600, and conductor 632c is usable as a second butt-side contact on the back-side 403b of integrated circuit 600, thus improving routing resources of integrated circuit 600 and reducing the area of integrated circuit 600 compared to other approaches.

In some embodiments, by using conductor 630c as a first butt-side contact on the front-side 403a of integrated circuit 600, and by using conductor 632c as a second butt-side contact on the back-side 403b of integrated circuit 600, at least one of conductor 630c or 632c has a simpler design than other approaches that have a more complex L-shape and use at least one more extra masks.

In some embodiments, integrated circuit 600 achieves one or more of the benefits described herein.

Other configurations, arrangements on other levels or quantities of elements in integrated circuit 600 are within the scope of the present disclosure.

FIGS. 7A-7D are diagrams of a layout design 700, in accordance with some embodiments.

FIGS. 7A-7D are corresponding diagrams of corresponding portions 700A-700D of a layout design 700, simplified for ease of illustration.

Portion 700A includes one or more features of layout design 700 of the OD level, the POLY level, the CPO level, the MD level, the MDLI level, the VG level, the VD level and the M0 level.

Portion 700B includes one or more features of layout design 700 of the OD level, the POLY level, the CPO level, the BMD level, the MDLI level, the BVG level, the BVD level and the BM0 level.

Portion 700C includes one or more features of layout design 700 of the VG level, the VD level and the M0 level.

Portion 700D includes one or more features of layout design 700 of the BVG level, the BVD level and the BM0 level.

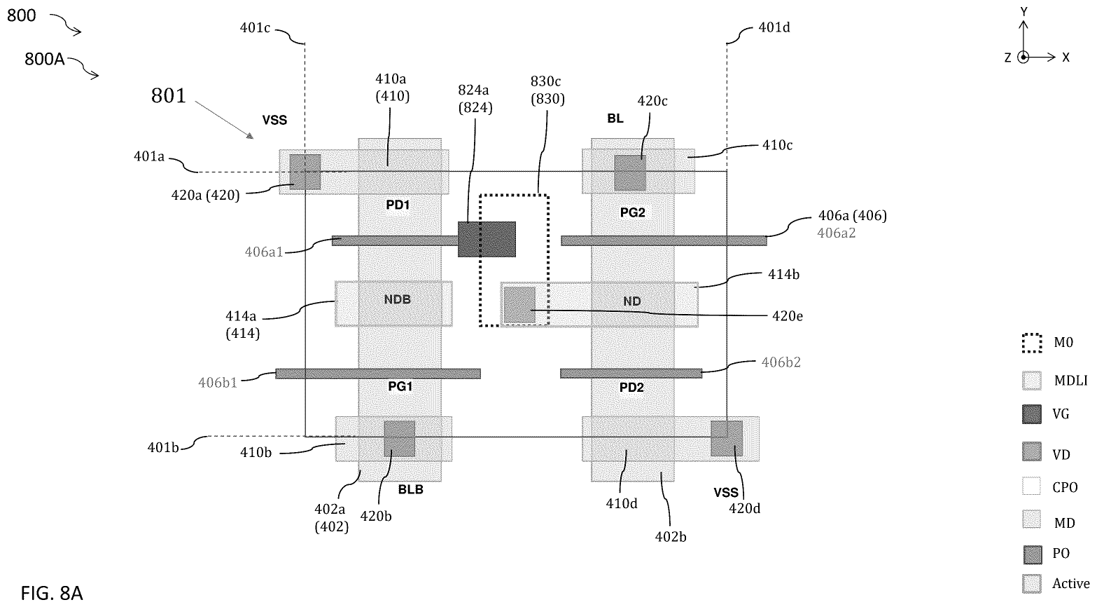

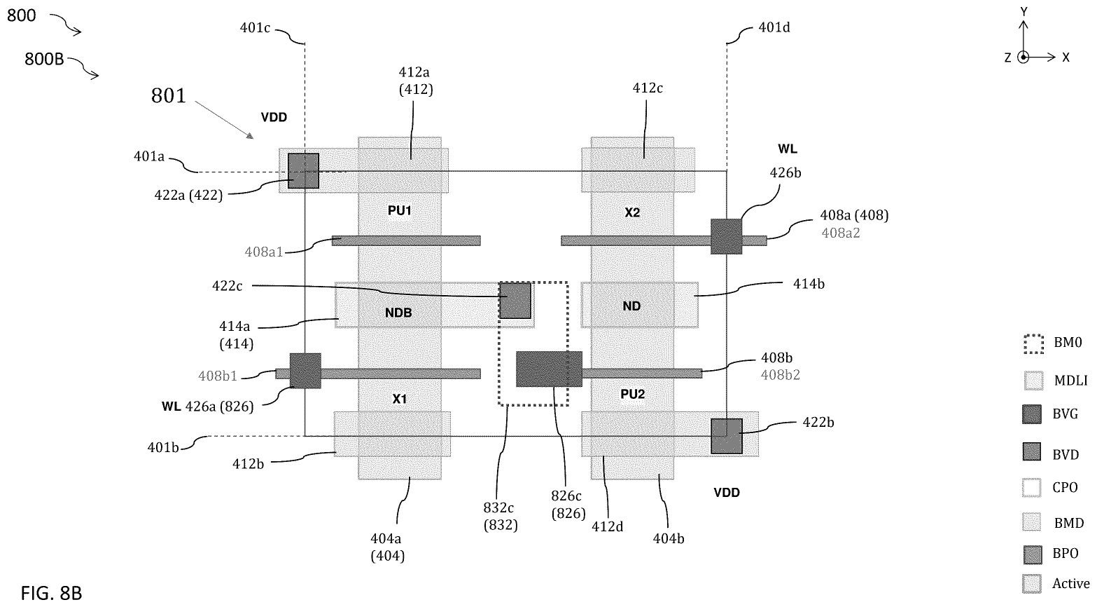

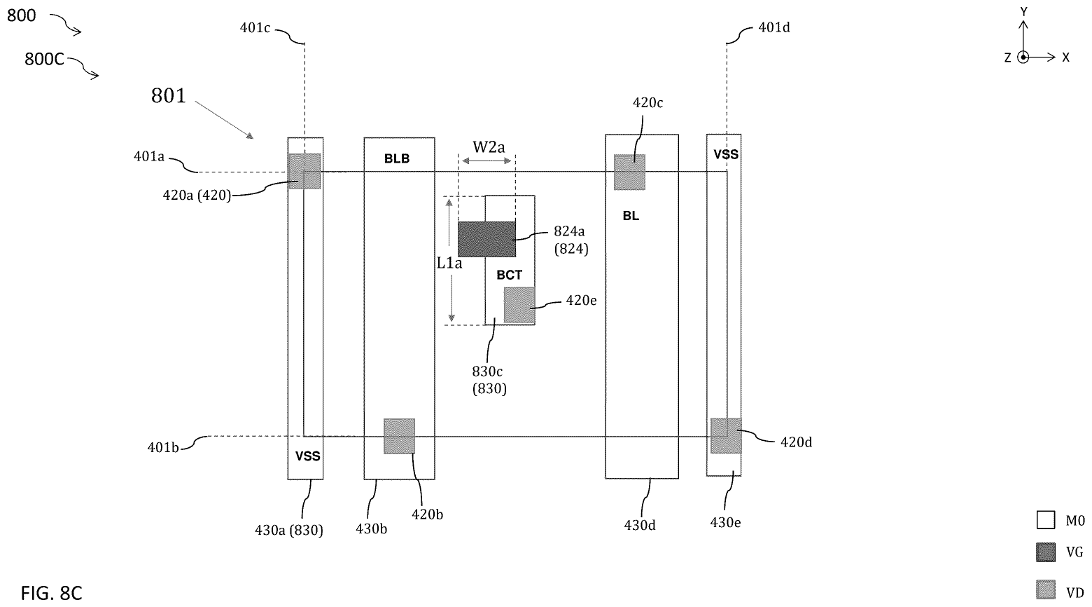

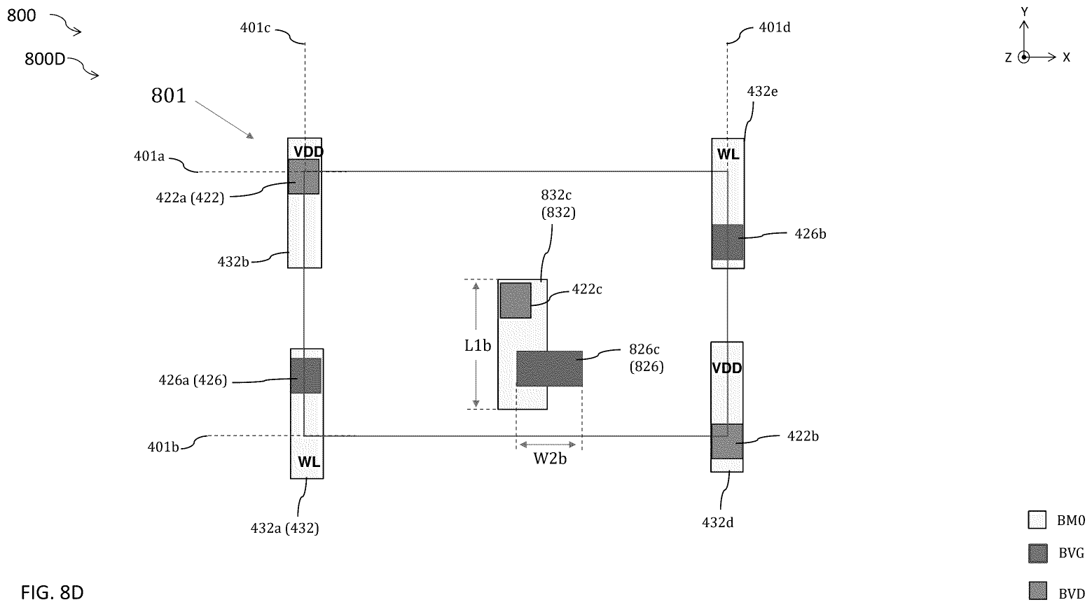

Layout design 700 is usable to manufacture integrated circuit 800 of FIGS. 8A-8D.

In some embodiments, layout design 700 is memory cell 200.

Layout design 700 is cell 701.

Layout design 700 is a variation of layout design 300 of FIGS. 3A-3D, and similar detailed description is omitted for brevity.

In comparison with layout design 300 of FIGS. 3A-3D, a set of cut feature patterns 740 replaces the set of cut feature patterns 340 of layout design 300, a set of conductive feature patterns 730 replaces the set of conductive feature patterns 330 of layout design 300, a set of conductive feature patterns 732 replaces the set of conductive feature patterns 332 of layout design 300, a set of via patterns 724 replaces the set of via patterns 324 of layout design 300, a set of via patterns 726 replaces the set of via patterns 326 of layout design 300, and similar detailed description is omitted for brevity.

Layout design 700 includes at least one or more of the set of active region patterns 302 and 304, the set of gate patterns 306 and 308, the set of cut feature patterns 740, the set of contact patterns 310, the set of contact patterns 312, the set of contact patterns 314, the set of conductive feature patterns 730, the set of conductive feature patterns 732, the set of via patterns 320, the set of via patterns 322, the set of via patterns 724 or the set of via patterns 726.

The set of conductive feature patterns 730 includes at least one of conductive feature pattern 330a, 330b, 730c, 330d or 330e.

In comparison with layout design 300, conductive feature pattern 730c of the set of conductive feature patterns 730 replaces conductive feature pattern 330c of the set of conductive feature patterns 330, and similar detailed description is omitted for brevity.

The set of conductive feature patterns 730 is M0 routing tracks. In some embodiments, the set of conductive feature patterns 730 is routing tracks in other layers. In some embodiments, the set of conductive feature patterns 730 corresponds to 5 M0 routing tracks. Other M0 track assignments or numbers of M0 tracks are within the scope of the present disclosure.

Other configurations, arrangements on other layout levels or quantities of conductive feature patterns in the set of conductive feature patterns 730 are within the scope of the present disclosure.

The set of conductive feature patterns 732 includes at least one of conductive feature pattern 332a, 332b, 732c, 332d or 332e.

In comparison with layout design 300, conductive feature pattern 732c of the set of conductive feature patterns 732 replaces conductive feature pattern 332c of the set of conductive feature patterns 332, and similar detailed description is omitted for brevity.

The set of conductive feature patterns 732 is BM0 routing tracks. In some embodiments, the set of conductive feature patterns 732 is routing tracks in other layers. In some embodiments, the set of conductive feature patterns 732 corresponds to 3 BM0 routing tracks. Other BM0 track assignments or numbers of BM0 tracks are within the scope of the present disclosure.

Other configurations, arrangements on other layout levels or quantities of conductive feature patterns in the set of conductive feature patterns 732 are within the scope of the present disclosure.

The set of cut feature patterns 740 includes at least one of cut feature pattern 340a, 740b, 340d.

In comparison with layout design 300, cut feature pattern 740b of the set of cut feature patterns 740 replaces cut feature patterns 340b and 340c of the set of cut feature patterns 340, and similar detailed description is omitted for brevity.

In comparison with cut feature patterns 340b and 340c of layout design 300, cut feature pattern 740b of layout design 700 does not have “a zig zag shape,” and thus has “a rectangular shape” in the first direction X and the second direction Y, and similar detailed description is omitted for brevity.

In comparison with cut feature patterns 340b and 340c of layout design 300, cut feature pattern 740b of layout design 700 has a uniform shape in the second direction Y.

In comparison with cut feature patterns 340b and 340c of layout design 300, cut feature pattern 740b of layout design 700 has an increased width in the first direction X, and similar detailed description is omitted for brevity.

In some embodiments, by increasing the width of cut feature pattern 740b in the first direction X results in cut feature pattern 740b having an increased area compared to cut feature patterns 340b and 340c.

In some embodiments, by increasing the width of cut feature pattern 740b causes the area of cut feature pattern 740b to be increased thereby increasing the distance gates 406a1/408a1 and 406a2/408a2 are separated by, and thereby increasing the distance gates 406b1/408b1 and 406b2/408b2 re separated by.

Other configurations, arrangements on other layout levels or quantities of cut feature patterns in the set of cut feature patterns 740 are within the scope of the present disclosure.

The set of via patterns 724 includes at least one of via pattern 724a.

In comparison with layout design 300, via pattern 724a of the set of via patterns 724 replaces via pattern 324a of the set of via patterns 324, and similar detailed description is omitted for brevity.

In comparison with via pattern 324a of layout design 300, via pattern 724a of layout design 700 has an increased width W1a in the first direction X, and similar detailed description is omitted for brevity.

In some embodiments, by increasing the width W1a in the first direction X of via pattern 724a of layout design 700 thereby causes an increase in the area of via pattern 724a.

In some embodiments, since the width of the cut feature pattern 740b is increased in the first direction X, then the width W1a of via pattern 724c is also increased in the first direction X.

Other configurations, arrangements on other layout levels or quantities of via patterns in the set of via patterns 724 are within the scope of the present disclosure.

The set of via patterns 726 includes at least one of via pattern 326a, 326b or 726c.

In comparison with layout design 300, via pattern 726c of the set of via patterns 726 replaces via pattern 326c of the set of via patterns 326, and similar detailed description is omitted for brevity.

In comparison with via pattern 326c of layout design 300, via pattern 726c of layout design 700 has an increased width W1b in the first direction X, and similar detailed description is omitted for brevity.

In some embodiments, by increasing the width W1b in the first direction X of via pattern 726c of layout design 700 thereby causes an increase in the area of via pattern 726c.

In some embodiments, since the width of the cut feature pattern 740b is increased in the first direction X, then the width W1b of via pattern 726c is also increased in the first direction X.

Other configurations, arrangements on other layout levels or quantities of via patterns in the set of via patterns 726 are within the scope of the present disclosure.

In some embodiments, at least one of via pattern 724a or 726c is referred to as “a slotted via pattern.”

In some embodiments, layout design 700 achieves one or more of the benefits described herein.

Other configurations, arrangements on other levels or quantities of elements in layout design 700 are within the scope of the present disclosure.

FIGS. 8A-8D are diagrams of an integrated circuit 800, in accordance with some embodiments.

FIGS. 8A-8D are corresponding diagrams of corresponding portions 800A-800D of an integrated circuit 800, simplified for ease of illustration.

Portion 800A includes one or more features of integrated circuit 800 of the OD level, the POLY level, the CPO level, the MD level, the MDLI level, the VG level, the VD level and the M0 level.

Portion 800B includes one or more features of integrated circuit 800 of the OD level, the POLY level, the CPO level, the BMD level, the MDLI level, the BVG level, the BVD level and the BM0 level.

Portion 800C includes one or more features of integrated circuit 800 of the VG level, the VD level and the M0 level.

Portion 800D includes one or more features of integrated circuit 800 of the BVG level, the BVD level and the BM0 level.

Integrated circuit 800 is manufactured by layout design 700 of FIGS. 7A-7D.

In some embodiments, integrated circuit 800 is memory cell 200.

Integrated circuit 800 is cell 801.

Integrated circuit 800 is a variation of integrated circuit 400 of FIGS. 4A-4D, and similar detailed description is omitted for brevity.

In comparison with integrated circuit 400 of FIGS. 4A-4D, a set of removed gate portions 840 replaces the set of removed gate portions 440 of integrated circuit 400, a set of conductors 830 replaces the set of conductors 430 of integrated circuit 400, a set of conductors 832 replaces the set of conductors 432 of integrated circuit 400, a set of vias 824 replaces the set of vias 424 of integrated circuit 400, a set of vias 826 replaces the set of vias 426 of integrated circuit 400, and similar detailed description is omitted for brevity.

Integrated circuit 800 includes at least one or more of the set of active regions 402 and 404, the set of gates 406 and 408, the set of removed gate portions 840, the set of contacts 410, the set of contacts 412, the set of contacts 414, the set of conductors 830, the set of conductors 832, the set of vias 420, the set of vias 422, the set of vias 824, the set of vias 826, the substrate 490 and the insulating region 492.

The set of conductors 830 includes at least one of conductor 430a, 430b, 830c, 430d or 430e.

In comparison with integrated circuit 400, conductor 830c of the set of conductors 830 replaces conductor 430c of the set of conductors 430, and similar detailed description is omitted for brevity.

The set of conductors 830 is M0 routing tracks. In some embodiments, the set of conductors 830 is routing tracks in other layers. In some embodiments, the set of conductors 830 corresponds to 5 M0 routing tracks. Other M0 track assignments or numbers of M0 tracks are within the scope of the present disclosure.

Other configurations, arrangements on other layout levels or quantities of conductors in the set of conductors 830 are within the scope of the present disclosure.

The set of conductors 832 includes at least one of conductor 432a, 432b, 832c, 432d or 432e.

In comparison with integrated circuit 400, conductor 832c of the set of conductors 832 replaces conductor 432c of the set of conductors 432, and similar detailed description is omitted for brevity.

The set of conductors 832 is BM0 routing tracks. In some embodiments, the set of conductors 832 is routing tracks in other layers. In some embodiments, the set of conductors 832 corresponds to 3 BM0 routing tracks. Other BM0 track assignments or numbers of BM0 tracks are within the scope of the present disclosure.

Other configurations, arrangements on other layout levels or quantities of conductors in the set of conductors 832 are within the scope of the present disclosure.

The set of removed gate portions 840 includes at least one of removed gate portion 440a, 840b or 440d.

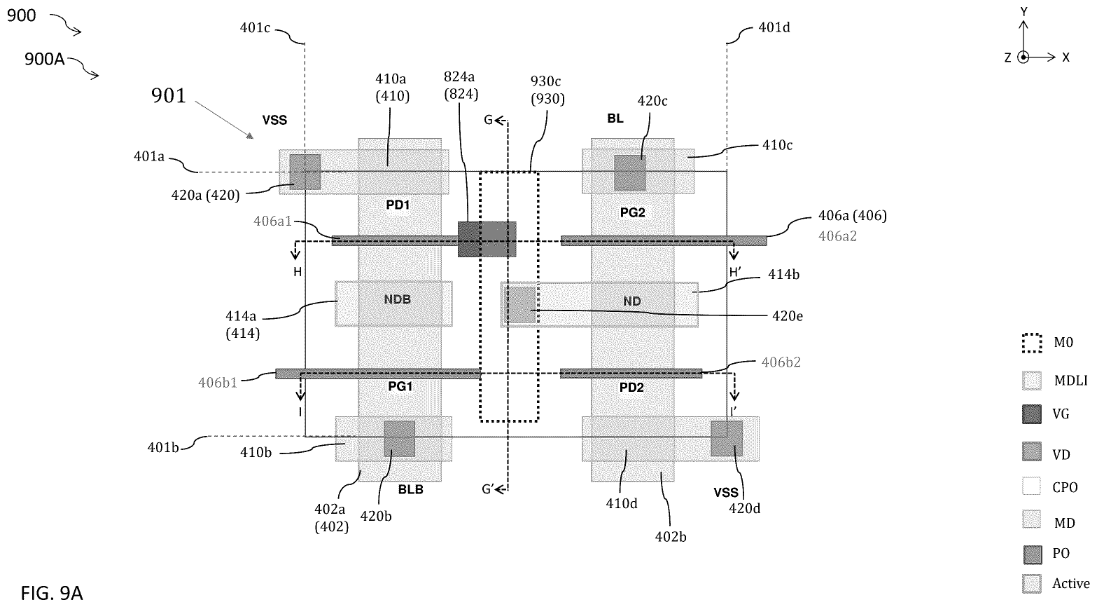

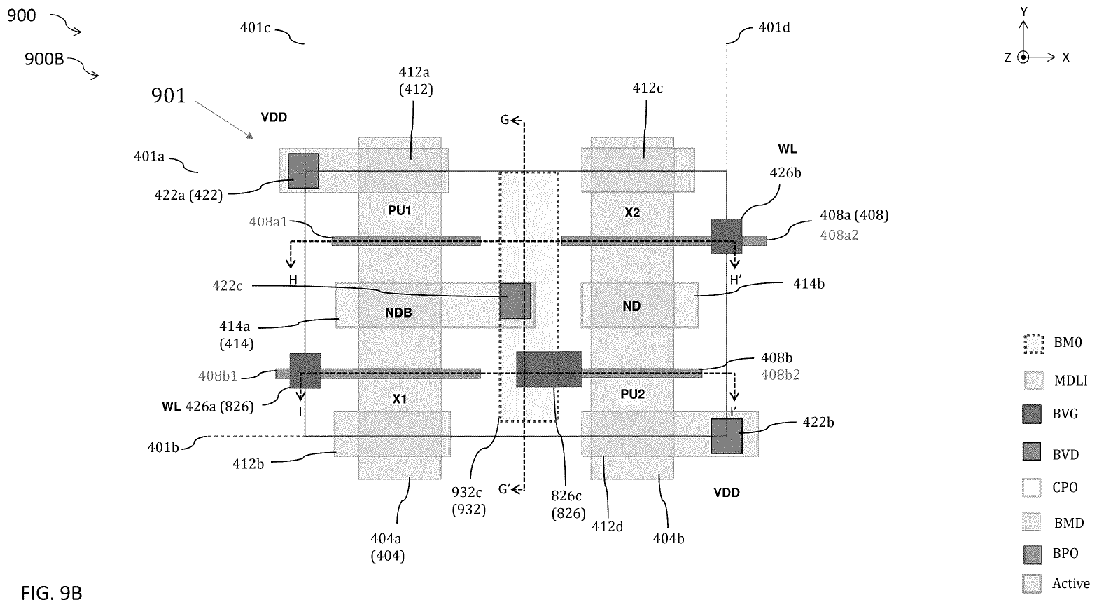

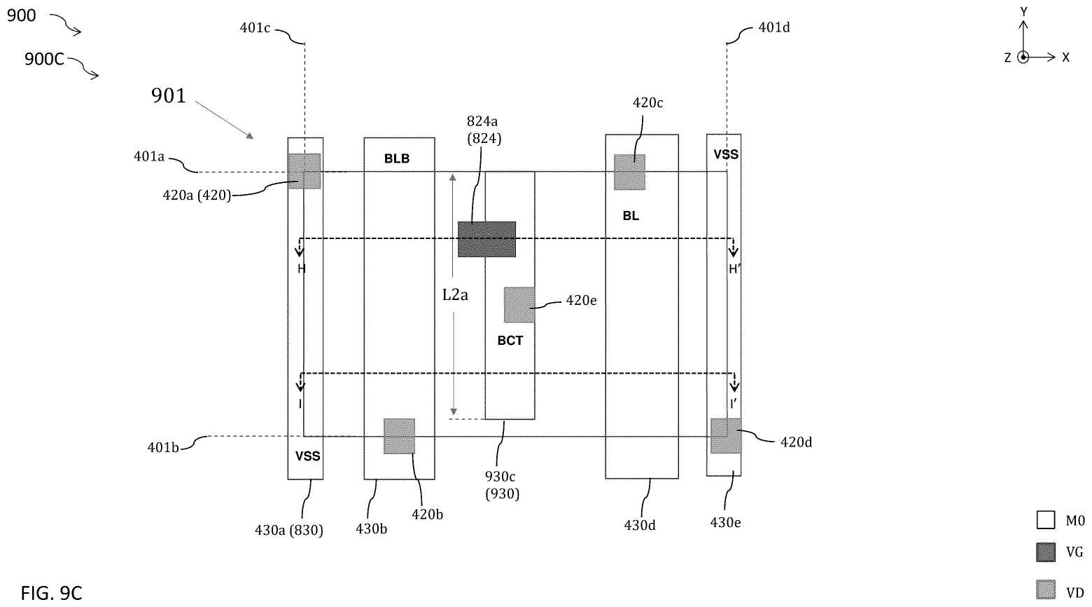

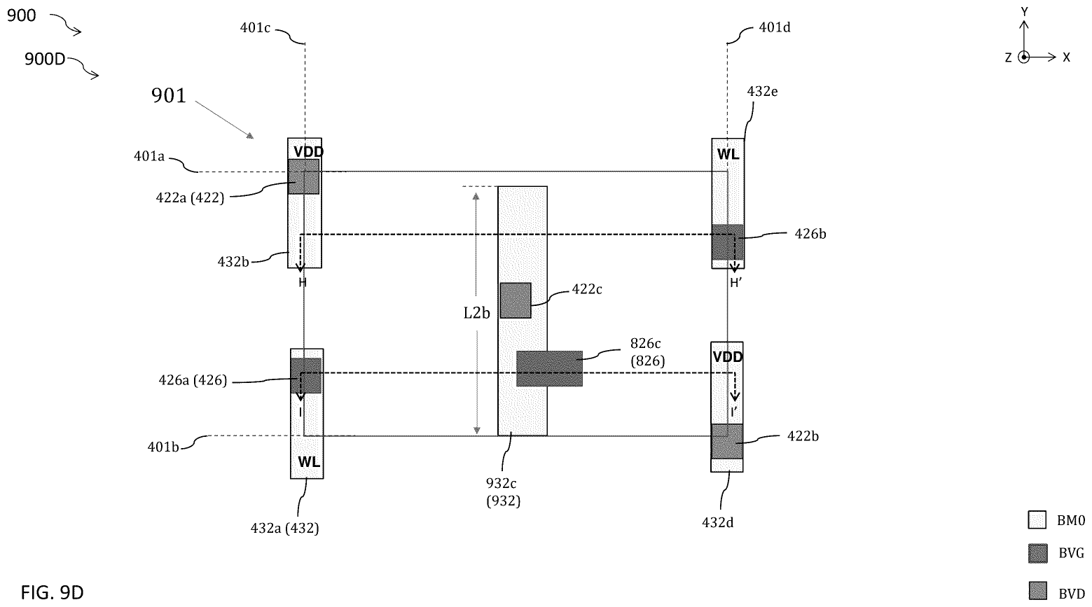

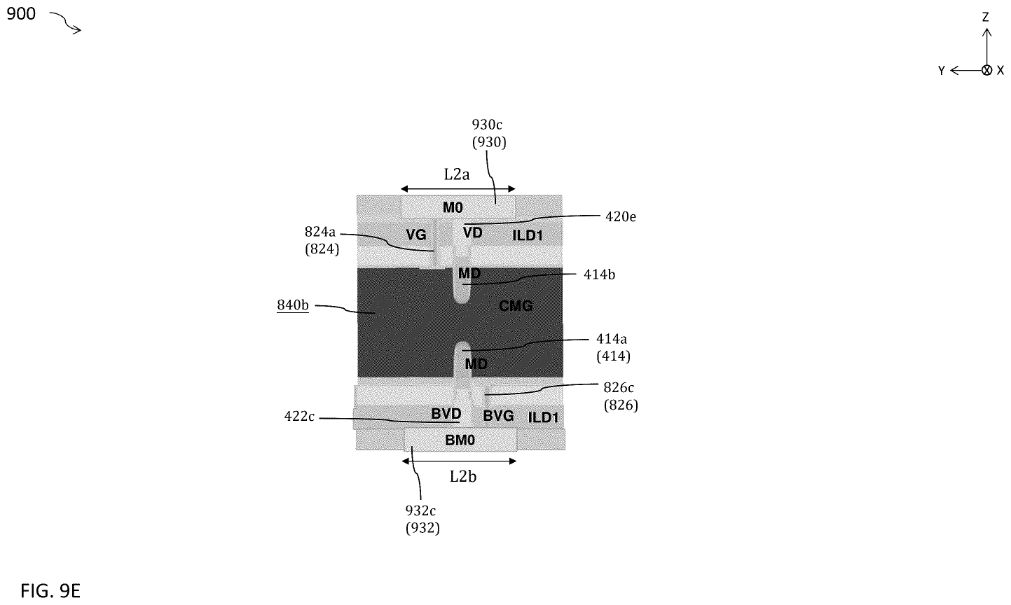

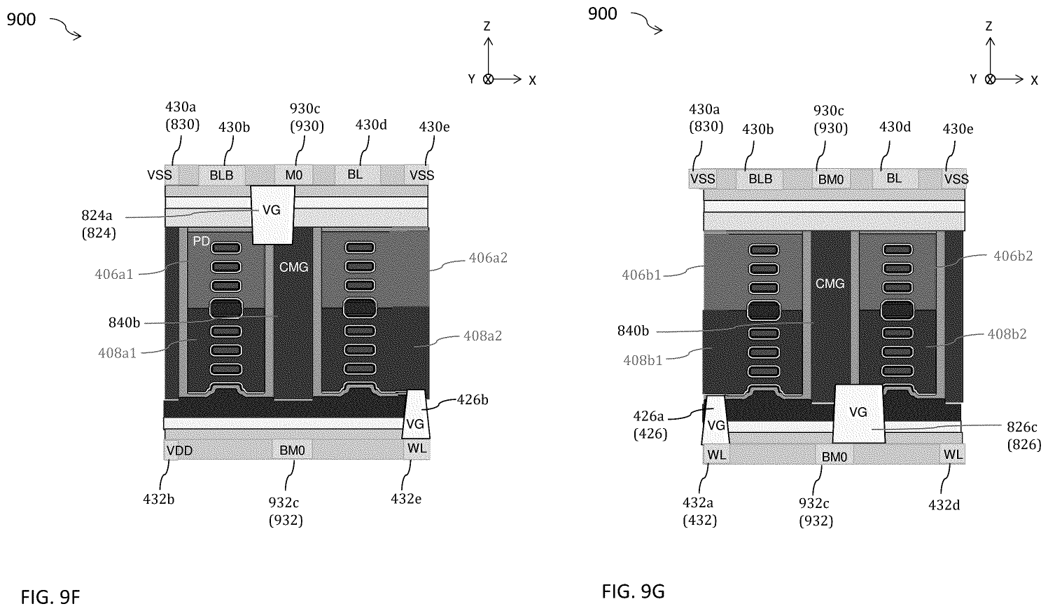

In some embodiments, one or more removed gate portions 440a, 840b (shown in FIG. 9E) or 440d is a corresponding insulating region (not labelled) similar to the set of insulating regions 492, and similar detailed description is therefore omitted.

In some embodiments, the insulating region of removed gate portion 840b is configured to electrically insulate gate 406a1 from gate 406a2 from each other. In some embodiments, the insulating region of removed gate portion 840b is configured to electrically insulate gate 408a1 from gate 408a2 from each other.

In some embodiments, the insulating region of removed gate portion 840b is configured to electrically insulate gate 406b1 from gate 406b2 from each other. In some embodiments, the insulating region of removed gate portion 840b is configured to electrically insulate gate 408b1 from gate 408b2 from each other.

In comparison with integrated circuit 400, removed gate portion 840b (shown in FIG. 9E) of the set of removed gate portions 840 replaces removed gate portions 440b and 440c of the set of removed gate portions 440, and similar detailed description is omitted for brevity.

In comparison with removed gate portions 440b and 440c of integrated circuit 400, removed gate portion 840b of integrated circuit 800 does not have “a zig zag shape,” and thus has “a rectangular shape” in the first direction X and the second direction Y, and similar detailed description is omitted for brevity.

In comparison with removed gate portions 440b and 440c of integrated circuit 400, removed gate portion 840b of integrated circuit 800 has a uniform shape in the second direction Y.

In some embodiments, a first side of the insulating region 840b contacts a first side of the gate 406a1/408a1 and a first side of the gate 406b1/408b1.

In some embodiments, a second side of the insulating region 440c contacts a first side of the gate 406a2/408a2 and a first side of the gate 406b2/408a2.

In some embodiments, the first side of the gate 406a1/408a1 is aligned in the second direction Y with the first side of the gate 406b1/408b1.

In some embodiments, the first side of the gate 406a2/408a2 is aligned in the second direction Y with the first side of the gate 406b2/408b2.

In comparison with removed gate portions 440b and 440c of integrated circuit 400, removed gate portion 840b of integrated circuit 800 has an increased width in the first direction X, and similar detailed description is omitted for brevity.

In some embodiments, by increasing the width of removed gate portion 840b in the first direction X results in removed gate portion 840b having an increased area compared to removed gate portions 440b and 440c.

In some embodiments, by increasing the width of removed gate portion 840b causes the area of removed gate portion 840b to be increased thereby increasing the distance gates 406a1/408a1 and 406a2/408a2 are separated by in the first direction X, and thereby increasing the distance gates 406b1/408b1 and 406b2/408b2 are separated by in the first direction X.

Other configurations, arrangements on other layout levels or quantities of removed gate portions in the set of removed gate portions 840 are within the scope of the present disclosure.

The set of vias 824 includes at least one of via 824a.

In comparison with integrated circuit 400, via 824a of the set of vias 824 replaces via 424a of the set of vias 424, and similar detailed description is omitted for brevity.

In comparison with via 424a of integrated circuit 400, via 824a of integrated circuit 800 has an increased width W2a in the first direction X, and similar detailed description is omitted for brevity.

In some embodiments, by increasing the width W2a in the first direction X of via 824a of integrated circuit 800 thereby causes an increase in the area of via 824a.

In some embodiments, since the width of the removed gate portion 840b is increased in the first direction X, then the width W2a of via 824c is also increased in the first direction X in order to be electrically connected to gate 406a1.

Other configurations, arrangements on other layout levels or quantities of vias in the set of vias 824 are within the scope of the present disclosure.

The set of vias 826 includes at least one of via 426a, 426b or 826c.

In comparison with integrated circuit 400, via 826c of the set of vias 826 replaces via 426c of the set of vias 426, and similar detailed description is omitted for brevity.

In comparison with via 426c of integrated circuit 400, via 826c of integrated circuit 800 has an increased width W2b in the first direction X, and similar detailed description is omitted for brevity.

In some embodiments, by increasing the width W2b in the first direction X of via 826c of integrated circuit 800 thereby causes an increase in the area of via 826c.

In some embodiments, since the width of the removed gate portion 840b is increased in the first direction X, then the width W2b of via 826c is also increased in the first direction X in order to be electrically connected to gate 408b2.

In some embodiments, at least one width in the first direction X of a via of the set of vias 420, 422, 824 or 826 is equal to at least one width in the first direction X of another via of the set of vias 420, 422, 824 or 826.

In some embodiments, at least one width in the first direction X of a via of the set of vias 420, 422, 824 or 826 is different from at least one width in the first direction X of another via of the set of vias 420, 422, 824 or 826.

Other configurations, arrangements on other layout levels or quantities of vias in the set of vias 826 are within the scope of the present disclosure.

In some embodiments, at least one of via 824a or 826c is referred to as “a slotted via.”

In some embodiments, integrated circuit 800 achieves one or more of the benefits described herein.

Other configurations, arrangements on other levels or quantities of elements in integrated circuit 800 are within the scope of the present disclosure.

FIGS. 9A-9G are diagrams of an integrated circuit 900, in accordance with some embodiments.

FIGS. 9A-9D are corresponding diagrams of corresponding portions 900A-900D of an integrated circuit 900, simplified for ease of illustration.

Portion 900A includes one or more features of integrated circuit 900 of the OD level, the POLY level, the CPO level, the MD level, the MDLI level, the VG level, the VD level and the M0 level. Portion 900A is manufactured by a layout design similar to at least portion 700A, and similar detailed description is omitted for brevity.

Portion 900B includes one or more features of integrated circuit 900 of the OD level, the POLY level, the CPO level, the BMD level, the MDLI level, the BVG level, the BVD level and the BM0 level. Portion 900B is manufactured by a layout design similar to at least portion 700B, and similar detailed description is omitted for brevity.

Portion 900C includes one or more features of integrated circuit 800 of the VG level, the VD level and the M0 level. Portion 900C is manufactured by a layout design similar to at least portion 700C, and similar detailed description is omitted for brevity.

Portion 900D includes one or more features of integrated circuit 800 of the BVG level, the BVD level and the BM0 level. Portion 900D is manufactured by a layout design similar to at least portion 700D, and similar detailed description is omitted for brevity.

FIGS. 9E-9G are corresponding cross-sectional views of integrated circuit 900, in accordance with some embodiments. FIG. 9E is a cross-sectional view of integrated circuit 900 as intersected by plane G-G′, in accordance with some embodiments. FIG. 9F is a cross-sectional view of integrated circuit 900 as intersected by plane H-H′, in accordance with some embodiments. FIG. 9G is a cross-sectional view of integrated circuit 900 as intersected by plane I-I′, in accordance with some embodiments.

In some embodiments, integrated circuit 900 is memory cell 200.

Integrated circuit 900 is manufactured by a corresponding layout design similar to integrated circuit 900.

In some embodiments, integrated circuit 900 is manufactured by a layout design similar to layout design 700, and similar detailed description is therefore omitted. Structural relationships including alignment, lengths and widths, as well as configurations and layers of integrated circuit 900 are similar to the structural relationships and configurations and layers of integrated circuit 800 of FIGS. 8A-8D, and similar detailed description will not be described in at least FIGS. 9A-9G, for brevity.

Integrated circuit 900 is cell 901.

Integrated circuit 900 is a variation of integrated circuit 800 of FIGS. 8A-8D, and similar detailed description is omitted for brevity.

In comparison with integrated circuit 800 of FIGS. 8A-8D, a set of conductors 930 replaces the set of conductors 430 of integrated circuit 800, and a set of conductors 932 replaces the set of conductors 432 of integrated circuit 800, and similar detailed description is omitted for brevity.

Integrated circuit 900 includes at least the set of active regions 402 and 404, the set of gates 406 and 408, the set of removed gate portions 440, the set of contacts 410, the set of contacts 412, the set of contacts 414, the set of conductors 930, the set of conductors 932, the set of vias 420, the set of vias 422, the set of vias 424, the set of vias 426, the substrate 490, and the insulating region 492.

The set of conductors 930 includes at least one of conductor 430a, 430b, 930c, 430d or 430e.

In comparison with integrated circuit 800, conductor 930c of the set of conductors 930 replaces conductor 830c of the set of conductors 830, and similar detailed description is omitted for brevity.

In comparison with conductor 830c of integrated circuit 800, conductor 930c of integrated circuit 900 has an increased length L2a in the second direction Y, and similar detailed description is omitted for brevity.

In comparison with conductor 830c of integrated circuit 800, by increasing the length L2a of conductor 930c in the second direction Y causes conductor 930c to have an increased area.

In some embodiments, by increasing the area of conductor 930c causes the capacitive coupling between conductor 430b and 430d to be reduced thereby improving the speed and performance of integrated circuit 900 compared to other approaches.

The set of conductors 930 is M0 routing tracks. In some embodiments, the set of conductors 930 is routing tracks in other layers. In some embodiments, the set of conductors 930 corresponds to 5 M0 routing tracks. Other M0 track assignments or numbers of M0 tracks are within the scope of the present disclosure.

Other configurations, arrangements on other layout levels or quantities of conductors in the set of conductors 930 are within the scope of the present disclosure.

The set of conductors 932 includes at least one of conductor 432a, 432b, 932c, 432d or 432e.

In comparison with integrated circuit 800, conductor 932c of the set of conductors 932 replaces conductor 832c of the set of conductors 832, and similar detailed description is omitted for brevity.

In comparison with conductor 832c of integrated circuit 800, conductor 932c of integrated circuit 900 has an increased length L2b in the second direction Y, and similar detailed description is omitted for brevity.

In comparison with conductor 832c of integrated circuit 800, by increasing the length L2b of conductor 932c in the second direction Y causes conductor 930c to have an increased area.

In some embodiments, by increasing the area of conductor 932c causes the capacitive coupling between conductor 432b and 432d to be reduced thereby improving the speed and performance of integrated circuit 900 compared to other approaches.

The set of conductors 932 is BM0 routing tracks. In some embodiments, the set of conductors 932 is routing tracks in other layers. In some embodiments, the set of conductors 932 corresponds to 3 BM0 routing tracks. Other BM0 track assignments or numbers of BM0 tracks are within the scope of the present disclosure.

Other configurations, arrangements on other layout levels or quantities of conductors in the set of conductors 932 are within the scope of the present disclosure.

In some embodiments, by including conductor 930c in integrated circuit 900, the capacitive coupling between the bit line BL and the bit line bar BLB is reduced thereby improving the speed and performance of integrated circuit 900 compared to other approaches.

In some embodiments, integrated circuit 900 achieves one or more of the benefits described herein.

Other configurations, arrangements on other levels or quantities of elements in integrated circuit 900 are within the scope of the present disclosure.

FIG. 10A-10B are corresponding functional flow charts of a corresponding method 1000A-1000B of manufacturing an IC device, in accordance with some embodiments. It is understood that additional operations may be performed before, during, and/or after the method 1000A depicted in FIG. 10A, and that some other processes may only be briefly described herein.

It is understood that additional operations may be performed before, during, and/or after the method 1000B depicted in FIG. 10B, and that some other processes may only be briefly described herein.

In some embodiments, other order of operations of method 1000A, 1000B, 1200 or 1300 is within the scope of the present disclosure. Method 1000A, 1000B, 1200 or 1300 includes exemplary operations, but the operations are not necessarily performed in the order shown. Operations may be added, replaced, changed order, and/or eliminated as appropriate, in accordance with the spirit and scope of disclosed embodiments. In some embodiments, one or more of the operations of at least method 1000A, 1000B, 1200 or 1300 is not performed.

In some embodiments, method 1000A is an embodiment of operation 1204 of method 1200. In some embodiments, the methods 1000A, 1000B or 1200 and 1300 are usable to manufacture or fabricate at least integrated circuit 100, 200, 400, 500, 600, 1000A, 900 or 1100, or an integrated circuit with similar features as at least layout design 300 or 700.

In operation 1002 of method 1000A, a first set of transistors and a second set of transistors are fabricated on a front-side 403a of a semiconductor wafer 490 or substrate. In some embodiments, the first set of transistors or the second set of transistors of method 1000A includes one or more transistors in at least the set of active regions 402 or 404. In some embodiments, the first set of transistors or the second set of transistors of method 1000A includes one or more transistors described herein.

In some embodiments, operation 1002 includes fabricating source and drain regions of the set of transistors in a first well as further described in method 1000B. In some embodiments, the first well comprises p-type dopants. In some embodiments, the p-dopants include boron, aluminum or other suitable p-type dopants. In some embodiments, the first well comprises an epi-layer grown over a substrate. In some embodiments, the epi-layer is doped by adding dopants during the epitaxial process. In some embodiments, the epi-layer is doped by ion implantation after the epi-layer is formed. In some embodiments, the first well is formed by doping the substrate. In some embodiments, the doping is performed by ion implantation. In some embodiments, the first well has a dopant concentration ranging from 1×10¹² atoms/cm³ to 1×10¹⁴ atoms/cm³.

In some embodiments, the first well comprises n-type dopants. In some embodiments, the n-type dopants include phosphorus, arsenic or other suitable n-type dopants. In some embodiments, the n-type dopant concentration ranges from about 1×10¹² atoms/cm³ to about 1×10¹⁴ atoms/cm³.

In some embodiments, the formation of the source/drain features includes, a portion of the substrate is removed to form recesses at an edge of spacers, and a filling process is then performed by filling the recesses in the substrate. In some embodiments, the recesses are etched, for example, a wet etching or a dry etching, after removal of a pad oxide layer or a sacrificial oxide layer. In some embodiments, the etch process is performed to remove a top surface portion of the active region adjacent to an isolation region, such as an STI region. In some embodiments, the filling process is performed by an epitaxy or epitaxial (epi) process. In some embodiments, the recesses are filled using a growth process which is concurrent with an etch process where a growth rate of the growth process is greater than an etch rate of the etch process. In some embodiments, the recesses are filled using a combination of growth process and etch process. For example, a layer of material is grown in the recess and then the grown material is subjected to an etch process to remove a portion of the material. Then a subsequent growth process is performed on the etched material until a desired thickness of the material in the recess is achieved. In some embodiments, the growth process continues until a top surface of the material is above the top surface of the substrate. In some embodiments, the growth process is continued until the top surface of the material is co-planar with the top surface of the substrate. In some embodiments, a portion of the first well is removed by an isotropic or an anisotropic etch process. The etch process selectively etches the first well without etching a gate structure and any spacers. In some embodiments, the etch process is performed using a reactive ion etch (RIE), wet etching, or other suitable techniques. In some embodiments, a semiconductor material is deposited in the recesses to form the source/drain features. In some embodiments, an epi process is performed to deposit the semiconductor material in the recesses. In some embodiments, the epi process includes a selective epitaxy growth (SEG) process, CVD process, molecular beam epitaxy (MBE), other suitable processes, and/or combination thereof. The epi process uses gaseous and/or liquid precursors, which interacts with a composition of substrate. In some embodiments, the source/drain features include epitaxially grown silicon (epi Si), silicon carbide, or silicon germanium. Source/drain features of the IC device associated with the gate structure are in-situ doped or undoped during the epi process in some instances. When source/drain features are undoped during the epi process, source/drain features are doped during a subsequent process in some instances. The subsequent doping process is achieved by an ion implantation, plasma immersion ion implantation, gas and/or solid source diffusion, other suitable processes, and/or combination thereof. In some embodiments, source/drain features are further exposed to annealing processes after forming source/drain features and/or after the subsequent doping process.

In some embodiments, operation 1002 further includes operation 1002a. In some embodiments, operation 1002a includes forming a first gate region of the second set of transistors. In some embodiments, the first gate region of the second set of transistors of method 1000A includes the set of gates 408.

In some embodiments, operation 1002 further includes operation 1002b. In some embodiments, operation 1002b includes forming a first insulating material on a first gate structure of the second set of transistors. In some embodiments, operation 1002b includes forming a first insulating material over at least the first gate structure of the first gate regions of the second set of transistors. In some embodiments, the first insulating material includes an insulating region similar to insulating region 492. In some embodiments, operation 1002b is not performed.

In some embodiments, operation 1002 further includes operation 1002c. In some embodiments, operation 1002c includes forming a second gate region of the first set of transistors. In some embodiments, the second gate regions of the first set of transistors of method 1000A include the set of gates 406. In some embodiments, operations 1002a and 1002c are performed at the same time.

In some embodiments, the first and second gate region is between the drain region and the source region. In some embodiments, the first and second gate region is over the first well and the substrate. In some embodiments, fabricating the first and second gate regions of operations 1002a and 1002c include performing one or more deposition processes to form one or more dielectric material layers. In some embodiments, a deposition process includes a chemical vapor deposition (CVD), a plasma enhanced CVD (PECVD), an atomic layer deposition (ALD), or other process suitable for depositing one or more material layers. In some embodiments, fabricating the first and second gate regions includes performing one or more deposition processes to form one or more conductive material layers. In some embodiments, fabricating the first and second gate regions includes forming gate electrodes or dummy gate electrodes. In some embodiments, fabricating the gate regions includes depositing or growing at least one dielectric layer, e.g., gate dielectric. In some embodiments, gate regions are formed using a doped or non-doped polycrystalline silicon (or polysilicon). In some embodiments, the first and second gate regions include a metal, such as Al, Cu, W, Ti, Ta, TiN, TaN, NiSi, CoSi, other suitable conductive materials, or combinations thereof.

In some embodiments, forming the first insulating material on the first gate structure of the second set of transistors of operation 1002b includes performing one or more deposition processes to form one or more dielectric material layers and/or insulating material layers. In some embodiments, the one or more deposition processes to form one or more dielectric material layers and/or insulating material layers includes CVD, a PECVD, ALD, or other process suitable for depositing one or more material layers. In some embodiments, forming the first insulating material on the first gate structure of the second set of transistors includes performing one or more deposition processes to form one or more insulating material layers. In some embodiments, the first insulating material is a dielectric material. In some embodiments, the dielectric material includes silicon dioxide, silicon oxy-nitride, or the like.

In some embodiments, operation 1002a, 1002b and 1002c are replaced by forming the first gate regions of the second set of transistors and the second gate regions of the first set of transistors, removing a portion of the first gate regions of the second set of transistors and the second gate regions of the first set of transistors, and forming the first insulating material between the first gate structure of the second set of transistors and the second gate structure of the first set of transistors. In some embodiments, the gate removal process is a POLY cut process that includes one or more etching processes. In some embodiments, the gate removal process includes one or more etching processes suitable to remove a portion of the gate structure. In some embodiments, a mask is used to specify portions of the gate structure that are to be cut or removed. In some embodiments the mask is a hard mask. In some embodiments, the mask is a soft mask. In some embodiments, etching corresponds to plasma etching, reactive ion etching, chemical etching, dry etching, wet etching, other suitable processes, any combination thereof, or the like.

In some embodiments, the gate removal process of operations 1002a, 1002b or 1002c also include the formation of the set of gates 406 or 408, and the cut regions are identified by the set of cut feature patterns 340 of FIGS. 3A-3D.

In some embodiments, operation 1002 further includes operation 1002d. In some embodiments, operation 1002d includes depositing a first conductive material on at least one of a first level, a second level or a third level thereby forming at least one of a corresponding first set of contacts, a second set of contacts or a third set of contacts.

In some embodiments, the first set of contacts, the second set of contacts and the third set of contacts are part of the first set of transistors and the second set of transistors.

In some embodiments, the first set of contacts includes the set of contacts 410 or 610.

In some embodiments, the second set of contacts includes the set of contacts 412 or 612.

In some embodiments, the third set of contacts includes the set of contacts 414.

In operation 1004 of method 1000A, a first set of vias are formed on the front-side 403a of the a wafer or substrate on a VD level or a VG level (e.g., VD or VG). In some embodiments, the first set of vias of method 1000A includes one or more portions at least the set of vias 420, 424, 620, 624 or 824.

In some embodiments, operation 1004 includes forming a first set of self-aligned contacts (SACs) in the insulating layer over the front-side 403a of the wafer. In some embodiments, the first set of vias is electrically coupled to at least the first set of transistors or the second set of transistors.

In operation 1006 of method 1000A, a second conductive material is deposited on the front-side 403a of the substrate on a first metal level thereby forming a first set of conductors on the front-side 403a of the wafer or substrate on a first metal level (e.g., M0).

In some embodiments, operation 1006 includes at least depositing a first set of conductive regions over the front-side 403a of the integrated circuit. In some embodiments, the first set of conductors of method 1000A includes one or more portions of at least the set of conductors 430, 530, 630, 830 or 930.

In some embodiments, the first set of conductors includes a first butt-side contact, a bit line BL and a bit line bar BLB.

In operation 1008 of method 1000A, thinning is performed on the back-side 403b of the wafer or substrate. In some embodiments, operation 1010 includes a thinning process performed on the back-side 403b of the semiconductor wafer or substrate. In some embodiments, the thinning process includes a grinding operation and a polishing operation (such as chemical mechanical polishing (CMP)) or other suitable processes. In some embodiments, after the thinning process, a wet etching operation is performed to remove defects formed on the back-side 403b of the semiconductor wafer or substrate.

In operation 1010 of method 1000A, a second set of vias are formed on the back-side 403b of the thinned wafer or substrate on a BVD level or a BVG level (e.g., BVD or BVG). In some embodiments, the second set of vias of method 1000A includes one or more portions at least the set of vias 422, 426, 622, 626 or 826.

In some embodiments, operation 1010 includes forming a second set of self-aligned contacts (SACs) in the insulating layer over the back-side 403b of the wafer. In some embodiments, the second set of vias is electrically coupled to at least the first set of transistors or the second set of transistors.

In operation 1012 of method 1000A, a second conductive material is deposited on the back-side 403b of the substrate on a second metal level thereby forming a second set of conductors on the back-side 403b of the wafer or substrate on the second metal level (e.g., BM0).

In some embodiments, operation 1012 includes at least depositing a second set of conductive regions over the back-side 403b of the integrated circuit. In some embodiments, the second set of conductors of method 1000A includes one or more portions of at least the set of conductors 432, 532, 632, 832 or 932.

In some embodiments, the second set of conductors is electrically coupled to at least the second set of transistors by the second set of vias.

In some embodiments, the second set of conductors includes a second butt-side contact and a word line WL. In some embodiments, the second set of transistors is configured to receive a word line signal on the word line from the back-side.

In some embodiments, one or more of operations 1002, 1004, 1006, 1010 or 1012 of method 1000A include using a combination of photolithography and material removal processes to form openings in an insulating layer (not shown) over the substrate. In some embodiments, the photolithography process includes patterning a photoresist, such as a positive photoresist or a negative photoresist. In some embodiments, the photolithography process includes forming a hard mask, an antireflective structure, or another suitable photolithography structure. In some embodiments, the material removal process includes a wet etching process, a dry etching process, an RIE process, laser drilling or another suitable etching process. The openings are then filled with conductive material, e.g., copper, aluminum, titanium, nickel, tungsten, or other suitable conductive material. In some embodiments, the openings are filled using CVD, PVD, sputtering, ALD or other suitable formation process.

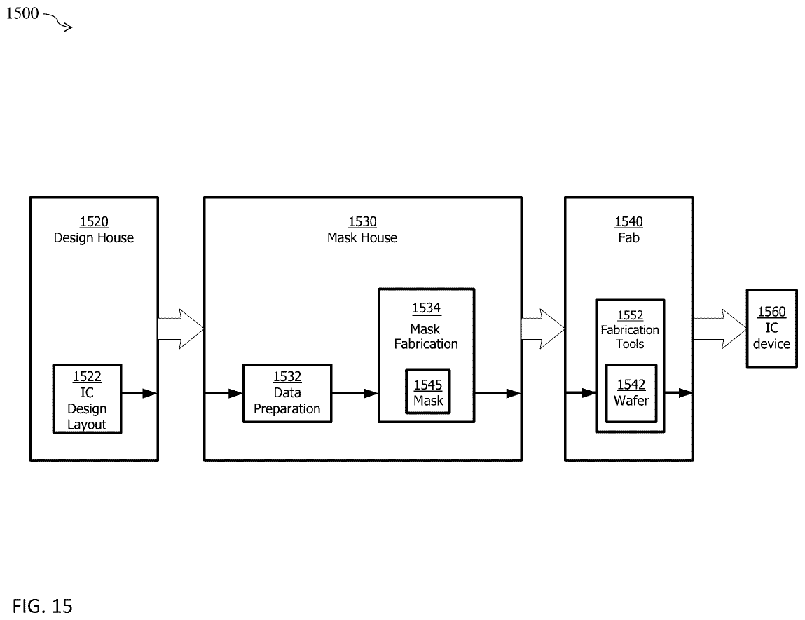

In some embodiments, at least one or more operations of method 1000A or 1000B is performed by system 1500 of FIG. 15. In some embodiments, at least one method(s), such as method 1000A (discussed above) or 1000B (discussed below), is performed in whole or in part by at least one manufacturing system, including system 1500. One or more of the operations of method 1000A or 1000B is performed by IC fab 1540 (FIG. 15) to fabricate IC device 1560. In some embodiments, one or more of the operations of method 1000A or 1000B is performed by fabrication tools 1552 to fabricate wafer 1542.

In some embodiments, the conductive material includes copper, aluminum, titanium, nickel, tungsten, or other suitable conductive material. In some embodiments, the openings and trench are filled using CVD, PVD, sputtering, ALD or other suitable formation process. In some embodiments, after conductive material is deposited in one or more of operations 1002d, 1006, 1008 or 1012, the conductive material is planarized to provide a level surface for subsequent steps.

FIG. 10B is a functional flow chart of method 1000B of manufacturing an IC device, in accordance with some embodiments.

It is understood that additional operations may be performed before, during, and/or after the method 1000B depicted in FIG. 10B, and that some other processes may only be briefly described herein.

In some embodiments, method 1000B is an embodiment of operation 1204 of method 1200.

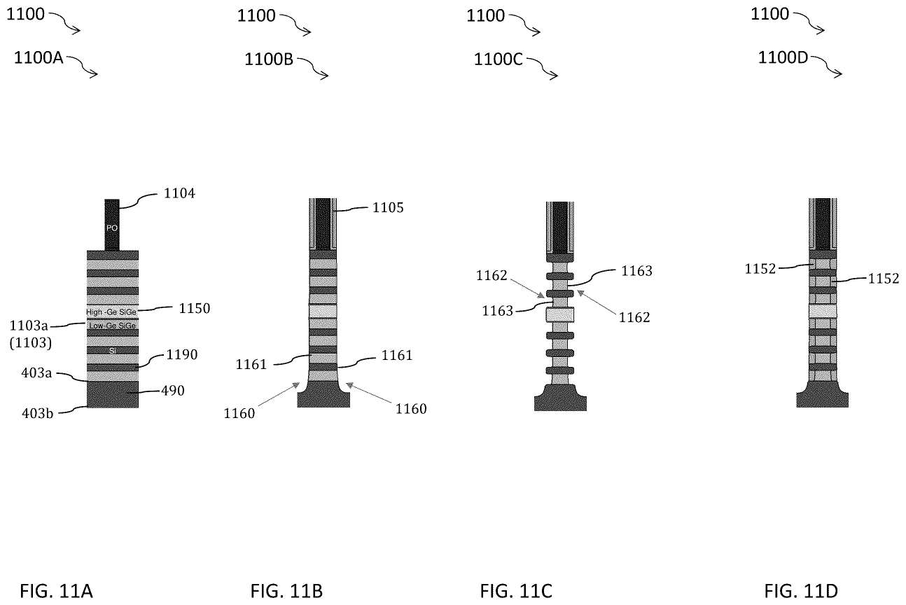

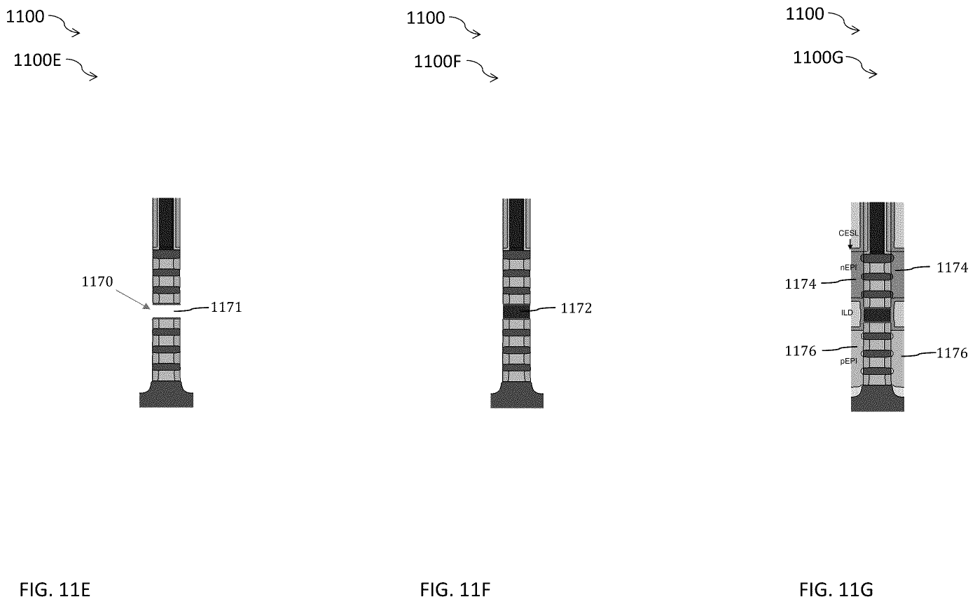

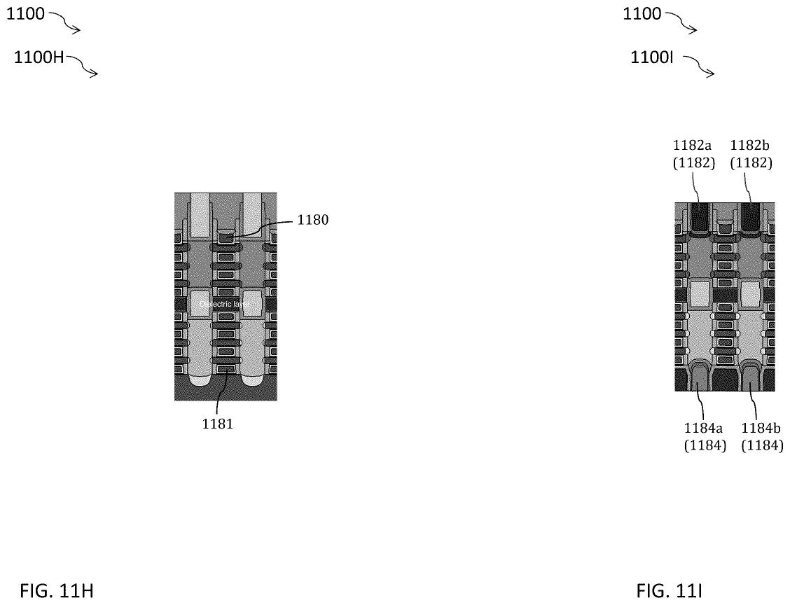

FIGS. 11A-11I are cross-sectional views of intermediate device structures obtained when fabricating the first butt-side contact on the front-side of the integrated circuit, and the second butt-side contact on the back-side of the integrated circuit, in accordance with some embodiments. In some embodiments, FIGS. 11A-11I are cross-sectional views of intermediate device structures of integrated circuit 600.

The device structures in FIGS. 11A-11I correspond to intermediate versions of integrated circuit 600 along line E-E′ of FIGS. 6A-6B.

In operation 1020 of method 1000B, a first set of dummy gates of a first set of transistors and a second set of transistors are fabricated on a front-side 403a of a semiconductor wafer or substrate.

In some embodiments, the device structures prepared at operation 1020 includes the device structure 1100A of FIG. 11A.

In the cross-sectional view of FIG. 11A, the source region 1102a and the drain region 1102b are part of an active region 1102 of the n-type or p-type transistor, and are formed on the front-side 203a of substrate 490.

Substrate 490 includes a front-side 403a and a back-side 403b.

Substrate 490 further includes alternating layers of a first set of semiconductor layers 1103 and a second set of semiconductor layers 1190.

In some embodiments, the first set of semiconductor layers 1103 includes a plurality of low-Ge SiGe layers. In some embodiments, the second set of semiconductor layers 1190 includes one or more layers of Si.

In some embodiments, substrate 490 further includes a layer 1150 between the first set of semiconductor layers 1103 and the second set of semiconductor layers 1190.

In some embodiments, the layer 1150 includes at least one high-Ge SiGe layer.

Dummy gate 1104 is formed on a top surface of the substrate 490. In some embodiments, the dummy gate 1104 includes a polysilicon material.

In operation 1022 of method 1000B, a first set of recess regions is formed in a first region of the front-side 403a of the semiconductor wafer or substrate. In some embodiments, operation 1022 includes performing a first etch process in the first region of the front-side 403a of the semiconductor wafer or substrate.

In some embodiments, the first set of recess regions is also referred to as a first set of source/drain recess regions.

In some embodiments, the device structures prepared at operation 1022 include the device structure 1100B of FIG. 11B.

In the cross-sectional view of FIG. 11B, the first set of recess regions 1161 are formed in the first region 1160 of the front-side 403a of substrate 490.

In operation 1024 of method 1000B, a second set of recess regions is formed in a second region of the front-side 403a of the semiconductor wafer or substrate. In some embodiments, operation 1024 includes performing a second etch process in the second region of the front-side 403a of the semiconductor wafer or substrate.

In some embodiments, the second set of recess regions is also referred to as a second set of source/drain recess regions.

In some embodiments, the second etch process includes one or more etch processes with high etch selectivity in order to remove portions of the first set of semiconductor layers 1103 and not removing portions of the second set of semiconductor layers 1190.

In some embodiments, the device structures prepared at operation 1024 include the device structure 1100C of FIG. 11C.

In the cross-sectional view of FIG. 11C, the second set of recess regions 1163 are formed in the second region 1162 of the front-side 403a of substrate 490.

In operation 1026 of method 1000B, inner spacer regions 1152 are formed in the second set of recess regions. In some embodiments, operation 1028 includes depositing a first set of insulating regions in the second set of recess regions. In some embodiments, operation 1026 includes performing a first deposition process to form the inner spacer regions.

In some embodiments, the device structures prepared at operation 1026 include the device structure 1100D of FIG. 11D.

In the cross-sectional view of FIG. 11D, the inner spacer regions 1152 are formed in the second set of recess regions 1163 of the front-side 403a of substrate 490.

In operation 1028 of method 1000B, a third set of recess regions is formed in a third region of the front-side 403a of the semiconductor wafer or substrate. In some embodiments, operation 1028 includes performing a third etch process in the third region of the front-side 403a of the semiconductor wafer or substrate.

In some embodiments, the device structures prepared at operation 1028 include the device structure 1100E of FIG. 11E.

In the cross-sectional view of FIG. 11E, the third set of recess regions 1171 are formed in a third region 1170 of the front-side 403a of substrate 490. In some embodiments, operation 1028 include removing the layer 1150 by the third etch process.

In some embodiments, the third etch process includes one or more etch processes with high etch selectivity in order to remove portions of the layer 1150 and not removing portions of the inner spacer regions 1152, the first set of semiconductor layers 1103 and the second set of semiconductor layers 1190.

In operation 1030 of method 1000B, an insulating layer is formed in the third set of recess regions. In some embodiments, operation 1030 includes depositing a second set of insulating regions in the third set of recess regions.

In some embodiments, operation 1030 includes performing a second deposition process to form the insulating layer between the first set of transistors and the second set of transistors. In some embodiments, operation 1030 includes performing a second deposition process to form a dielectric layer between the first set of transistors and the second set of transistors.

In some embodiments, the device structures prepared at operation 1030 include the device structure 1100F of FIG. 11F.

In the cross-sectional view of FIG. 11F, the insulating layer 1172 is formed in the third set of recess regions 1171.

In operation 1032 of method 1000B, a first set of source/drain regions of the first set of transistors and a second set of source/drain regions of the second set of transistors is formed in the first set of recess regions.

In some embodiments, operation 1032 includes performing one or more epitaxial growth processes to form one or more epi-layers in the first set of recess regions.

In some embodiments, the one or more epi-layers are doped by adding dopants during the epitaxial process. In some embodiments, the one or more epi-layers are doped by ion implantation after the epi-layer is formed.

In some embodiments, the device structures prepared at operation 1032 include the device structure 1100G of FIG. 11G.

In the cross-sectional view of FIG. 11G, the first set of source/drain regions 1174 of the first set of transistors and a second set of source/drain regions 1176 of the second set of transistors is formed in the first set of recess regions 1161.

In operation 1034 of method 1000B, a first set of gates of the first set of transistors and a second set of gates of the second set of transistors are formed.

In some embodiments, operation 1034 includes performing a replacement polysilicon gate (RPG) loop to form the first set of gates of the first set of transistors and the second set of gates of the second set of transistors.

In some embodiments, the gate material of the first set of gates and the second set of gates have a work function that is matched to the corresponding channel material.

In some embodiments, operation 1034 corresponds to one or more of operations 1002a, 1002b or 1002c.

In some embodiments, the device structures prepared at operation 1034 include the device structure 1100H of FIG. 11H.

In the cross-sectional view of FIG. 11H, the first set of gates 1180 of the first set of transistors and a second set of gates 1181 of the second set of transistors are formed.

In some embodiments, the first set of gates 1180 corresponds to the set of gates 406, and similar detailed description is therefore omitted. In some embodiments, the second set of gates 1181 corresponds to the set of gates 408, and similar detailed description is therefore omitted.

In operation 1036 of method 1000B, one or more end of line (BEOL) processes are performed to fabricate a first and a second set of vias and a first and a second set of conductors.

In some embodiments, operation 1036 includes fabricating the first set of vias and the first set of conductors on the front side of the substrate, and the second set of vias and the second set of conductors on the backside of the substrate.

In some embodiments, operation 1036 further includes fabricating the first set of contacts, the second set of contacts and the third set of contacts.

In some embodiments, operation 1036 corresponds to one or more of operations 1002d, 1004, 1006, 1010 or 1012.

In some embodiments, the device structures prepared at operation 1036 include the device structure 1100I of FIG. 11I.

In the cross-sectional view of FIG. 11I, the first set of vias 1182 of the first set of transistors and the second set of vias 1184 of the second set of transistors are formed.

In some embodiments, the first set of vias 1182 corresponds to the set of vias 420 and 424, and similar detailed description is therefore omitted. In some embodiments, the second set of vias 1184 corresponds to the set of vias 422 and 426, and similar detailed description is therefore omitted.

In some embodiments, one or more of the operations of method 1000A-1000B, 1200 or 1300 is not performed.

One or more of the operations of methods 1200-1300 is performed by a processing device configured to execute instructions for manufacturing an integrated circuit, such as at least integrated circuit 100, 200, 400, 500, 600, 800, 900 or 1100. In some embodiments, one or more operations of methods 1200-1300 are performed using a same processing device as that used in a different one or more operations of methods 1200-1300. In some embodiments, a different processing device is used to perform one or more operations of methods 1200-1300 from that used to perform a different one or more operations of methods 1200-1300. In some embodiments, other order of operations of method 1000A-1000B, 1200 or 1300 is within the scope of the present disclosure. Method 1000A-1000B, 1200 or 1300 includes exemplary operations, but the operations are not necessarily performed in the order shown. Operations in method 1000A-1000B, 1200 or 1300 may be added, replaced, changed order, and/or eliminated as appropriate, in accordance with the spirit and scope of disclosed embodiments.

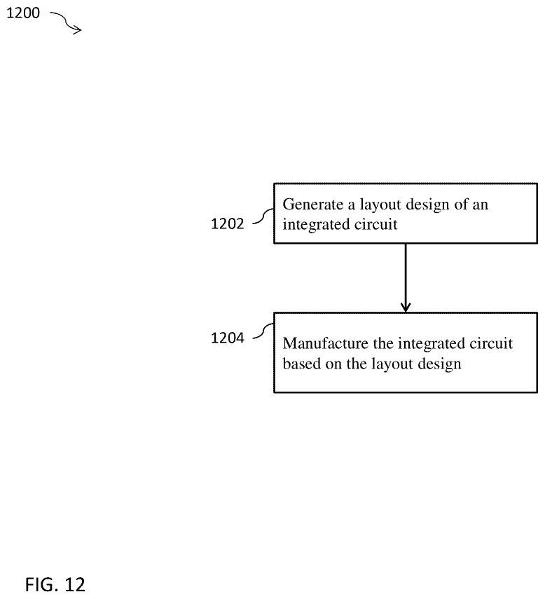

FIG. 12 is a flowchart of a method 1200 of forming or manufacturing an integrated circuit in accordance with some embodiments. It is understood that additional operations may be performed before, during, and/or after the method 1200 depicted in FIG. 12, and that some other operations may only be briefly described herein. In some embodiments, the method 1200 is usable to form integrated circuits, such as at least integrated circuit 100, 200, 400, 500, 600, 800, 900 or 1100. In some embodiments, the method 1200 is usable to form integrated circuits having similar features and similar structural relationships as one or more of layout design 300 or 700.

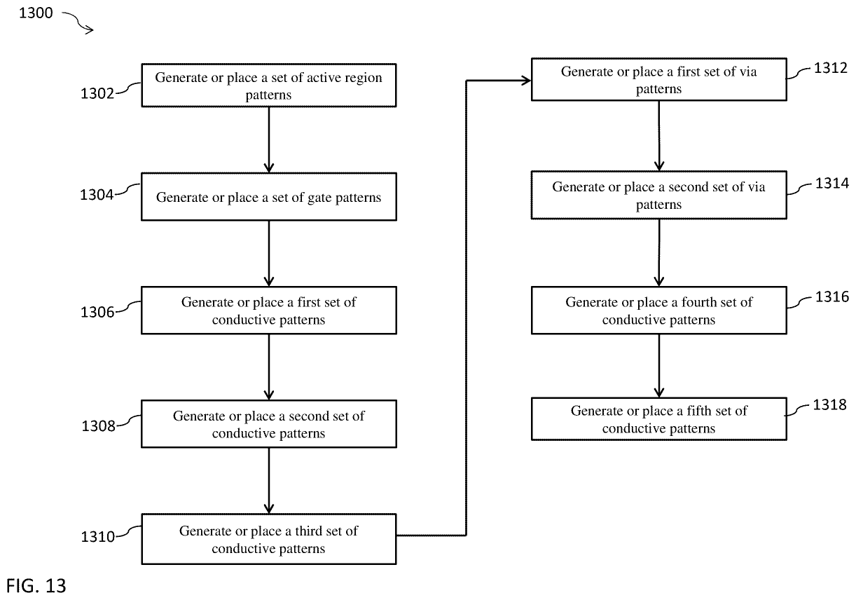

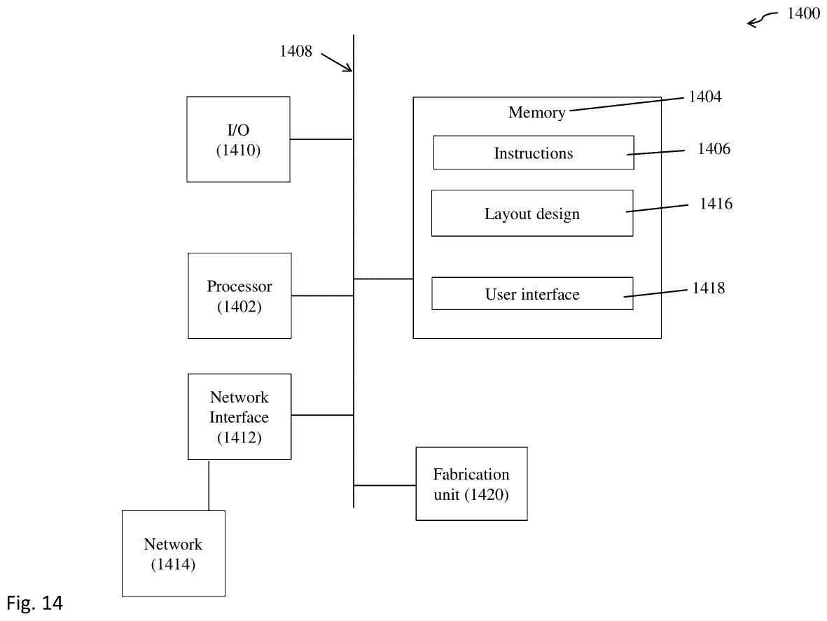

In operation 1202 of method 1200, a layout design of an integrated circuit is generated. Operation 1202 is performed by a processing device (e.g., processor 1402 (FIG. 14)) configured to execute instructions for generating a layout design. In some embodiments, the layout design of method 1200 includes one or more patterns of at least layout design 300 or 700, or one or more features similar to at least integrated circuit 100, 200, 400, 500, 600, 800, 900 or 1100. In some embodiments, the layout design of the present application is in a graphic database system (GDSII) file format. In some embodiments, operation 1202 corresponds to method 1300 of FIG. 13.

In operation 1204 of method 1200, the integrated circuit is manufactured based on the layout design. In some embodiments, operation 1204 of method 1200 comprises manufacturing at least one mask based on the layout design, and manufacturing the integrated circuit based on the at least one mask. In some embodiments, operation 1204 corresponds to method 1000A-1000B of FIGS. 10A-10B.

FIG. 13 is a flowchart of a method 1300 of generating a layout design of an integrated circuit, in accordance with some embodiments. It is understood that additional operations may be performed before, during, and/or after the method 1300 depicted in FIG. 13, and that some other processes may only be briefly described herein. In some embodiments, method 1300 is an embodiment of operation 1202 of method 1200. In some embodiments, method 1300 is usable to generate one or more layout patterns of at least layout design 300 or 700, or one or more features similar to at least integrated circuit 100, 200, 400, 500, 600, 800, 900 or 1100.

In some embodiments, method 1300 is usable to generate one or more layout patterns having structural relationships including alignment, lengths and widths, as well as configurations and layers of at least layout design 300 or 700, or one or more features similar to at least integrated circuit 100, 200, 400, 500, 600, 800, 900 or 1100, and similar detailed description will not be described in FIG. 13, for brevity.

In operation 1302 of method 1300, a set of active region patterns is generated or placed on the layout design. In some embodiments, the set of active region patterns of method 1300 includes at least portions of one or more patterns of the set of active region patterns 302 or 304. In some embodiments, the set of active region patterns of method 1300 includes one or more regions similar to the set of active regions 402 or 404. In some embodiments, the set of active region patterns of method 1300 includes one or more patterns or similar patterns in the OD layer.

In operation 1304 of method 1300, a set of gate patterns is generated or placed on the layout design. In some embodiments, the set of gate patterns of method 1300 includes at least portions of one or more patterns of the set of gate patterns 306 or 308 or the set of cut feature patterns 340 or 740. In some embodiments, the set of active gate patterns of method 1300 includes one or more regions similar to the set of gates 406 or 408 or the set of removed gate portions 440. In some embodiments, the set of gate patterns of method 1300 includes one or more patterns or similar patterns in the POLY layer.

In operation 1306 of method 1300, a first set of conductive patterns is generated or placed on the layout design. In some embodiments, the first set of conductive patterns of method 1300 includes at least portions of one or more patterns of the set of contact patterns 310. In some embodiments, the first set of conductive patterns of method 1300 includes one or more patterns similar to the set of contacts 410 or 610. In some embodiments, the first set of conductive patterns of method 1300 includes one or more patterns or similar patterns in the MD layer.

In operation 1308 of method 1300, a second set of conductive patterns is generated or placed on the layout design. In some embodiments, the second set of conductive patterns of method 1300 includes at least portions of one or more patterns of the set of contact patterns 312. In some embodiments, the second set of conductive patterns of method 1300 includes one or more patterns similar to the set of contacts 412 or 612. In some embodiments, the second set of conductive patterns of method 1300 includes one or more patterns or similar patterns in the BMD layer.

In operation 1310 of method 1300, a third set of conductive patterns is generated or placed on the layout design. In some embodiments, the third set of conductive patterns of method 1300 includes at least portions of one or more patterns of the set of contact patterns 314. In some embodiments, the third set of conductive patterns of method 1300 includes one or more patterns similar to the set of contacts 414. In some embodiments, the third set of conductive patterns of method 1300 includes one or more patterns or similar patterns in the MDLI layer.

In operation 1312 of method 1300, a first set of via patterns is generated or placed on the layout design. In some embodiments, the first set of via patterns of method 1300 includes at least portions of one or more patterns of the set of via patterns 320, 324 or 724. In some embodiments, the first set of via patterns of method 1300 includes one or more via patterns similar to at least the set of vias 420, 424, 620, 624 or 824. In some embodiments, the first set of via patterns of method 1300 includes one or more patterns or similar vias in the VG or VD layer.

In operation 1314 of method 1300, a second set of via patterns is generated or placed on the layout design. In some embodiments, the second set of via patterns of method 1300 includes at least portions of one or more patterns of the set of via patterns 322, 326 or 726. In some embodiments, the second set of via patterns of method 1300 includes one or more via patterns similar to at least the set of vias 422, 426, 622, 626 or 826. In some embodiments, the second set of via patterns of method 1300 includes one or more patterns or similar vias in the BVG or BVD layer.

In operation 1316 of method 1300, a fourth set of conductive patterns is generated or placed on the layout design. In some embodiments, the fourth set of conductive patterns of method 1300 includes at least portions of one or more patterns of at least the set of conductive patterns 330 or 730. In some embodiments, the fourth set of conductive patterns of method 1300 includes one or more conductive patterns similar to at least the set of conductors 430, 530, 630, 830 or 930. In some embodiments, the fourth set of conductive patterns of method 1300 includes one or more patterns or similar conductors in the M0 layer.

In operation 1318 of method 1300, a fifth set of conductive patterns is generated or placed on the layout design. In some embodiments, the fifth set of conductive patterns of method 1300 includes at least portions of one or more patterns of at least the set of conductive patterns 332 or 732. In some embodiments, the fifth set of conductive patterns of method 1300 includes one or more conductive patterns similar to at least the set of conductors 432, 532, 632, 832 or 932. In some embodiments, the fifth set of conductive patterns of method 1300 includes one or more patterns or similar conductors in the BM0 layer.

FIG. 14 is a schematic view of a system 1400 for designing an IC layout design and manufacturing an IC circuit in accordance with some embodiments.

In some embodiments, system 1400 generates or places one or more IC layout designs described herein. System 1400 includes a hardware processor 1402 and a non-transitory, computer readable storage medium 1404 (e.g., memory 1404) encoded with, i.e., storing, the computer program code 1406, i.e., a set of executable instructions 1406. Computer readable storage medium 1404 is configured for interfacing with manufacturing machines for producing the integrated circuit. The processor 1402 is electrically coupled to the computer readable storage medium 1404 via a bus 1408. The processor 1402 is also electrically coupled to an I/O interface 1410 by bus 1408. A network interface 1412 is also electrically connected to the processor 1402 via bus 1408. Network interface 1412 is connected to a network 1414, so that processor 1402 and computer readable storage medium 1404 are capable of connecting to external elements via network 1414. The processor 1402 is configured to execute the computer program code 1406 encoded in the computer readable storage medium 1404 in order to cause system 1400 to be usable for performing a portion or all of the operations as described in method 1200-1300.

In some embodiments, the processor 1402 is a central processing unit (CPU), a multi-processor, a distributed processing system, an application specific integrated circuit (ASIC), and/or a suitable processing unit.

In some embodiments, the computer readable storage medium 1404 is an electronic, magnetic, optical, electromagnetic, infrared, and/or a semiconductor system (or apparatus or device). For example, the computer readable storage medium 1404 includes a semiconductor or solid-state memory, a magnetic tape, a removable computer diskette, a random access memory (RAM), a read-only memory (ROM), a rigid magnetic disk, and/or an optical disk. In some embodiments using optical disks, the computer readable storage medium 1404 includes a compact disk-read only memory (CD-ROM), a compact disk-read/write (CD-R/W), and/or a digital video disc (DVD).

In some embodiments, the storage medium 1404 stores the computer program code 1406 configured to cause system 1400 to perform method 1200-1300. In some embodiments, the storage medium 1404 also stores information needed for performing method 1200-1300 as well as information generated during performing method 1200-1300, such as layout design 1416, user interface 1418 and fabrication unit 1420, and/or a set of executable instructions to perform the operation of method 1200-1300. In some embodiments, layout design 1416 comprises one or more of layout patterns of at least layout design 300 or 700, or features similar to at least integrated circuit 100, 200, 400, 500, 600, 800, 900 or 1100.

In some embodiments, the storage medium 1404 stores instructions (e.g., computer program code 1406) for interfacing with manufacturing machines. The instructions (e.g., computer program code 1406) enable processor 1402 to generate manufacturing instructions readable by the manufacturing machines to effectively implement method 1200-1300 during a manufacturing process.

System 1400 includes I/O interface 1410. I/O interface 1410 is coupled to external circuitry. In some embodiments, I/O interface 1410 includes a keyboard, keypad, mouse, trackball, trackpad, and/or cursor direction keys for communicating information and commands to processor 1402.

System 1400 also includes network interface 1412 coupled to the processor 1402. Network interface 1412 allows system 1400 to communicate with network 1414, to which one or more other computer systems are connected. Network interface 1412 includes wireless network interfaces such as BLUETOOTH, WIFI, WIMAX, GPRS, or WCDMA; or wired network interface such as ETHERNET, USB, or IEEE-2094. In some embodiments, method 1200-1300 is implemented in two or more systems 1400, and information such as layout design, and user interface are exchanged between different systems 1400 by network 1414.

System 1400 is configured to receive information related to a layout design through I/O interface 1410 or network interface 1412. The information is transferred to processor 1402 by bus 1408 to determine a layout design for producing at least integrated circuit 100, 200, 400, 500, 600, 800, 900 or 1100. The layout design is then stored in computer readable medium 1404 as layout design 1416. System 1400 is configured to receive information related to a user interface through I/O interface 1410 or network interface 1412. The information is stored in computer readable medium 1404 as user interface 1418. System 1400 is configured to receive information related to a fabrication unit 1420 through I/O interface 1410 or network interface 1412. The information is stored in computer readable medium 1404 as fabrication unit 1420. In some embodiments, the fabrication unit 1420 includes fabrication information utilized by system 1400. In some embodiments, the fabrication unit 1420 corresponds to mask fabrication 1534 of FIG. 15.

In some embodiments, method 1200-1300 is implemented as a standalone software application for execution by a processor. In some embodiments, method 1200-1300 is implemented as a software application that is a part of an additional software application. In some embodiments, method 1200-1300 is implemented as a plug-in to a software application. In some embodiments, method 1200-1300 is implemented as a software application that is a portion of an EDA tool. In some embodiments, method 1200-1300 is implemented as a software application that is used by an EDA tool. In some embodiments, the EDA tool is used to generate a layout of the integrated circuit device. In some embodiments, the layout is stored on a non-transitory computer readable medium. In some embodiments, the layout is generated using a tool such as VIRTUOSO® available from CADENCE DESIGN SYSTEMS, Inc., or another suitable layout generating tool. In some embodiments, the layout is generated based on a netlist which is created based on the schematic design. In some embodiments, method 1200-1300 is implemented by a manufacturing device to manufacture an integrated circuit using a set of masks manufactured based on one or more layout designs generated by system 1400. In some embodiments, system 1400 is a manufacturing device configured to manufacture an integrated circuit using a set of masks manufactured based on one or more layout designs of the present disclosure. In some embodiments, system 1400 of FIG. 14 generates layout designs of an integrated circuit that are smaller than other approaches. In some embodiments, system 1400 of FIG. 14 generates layout designs of integrated circuit structure that occupy less area and provide better routing resources than other approaches.

FIG. 15 is a block diagram of an integrated circuit (IC) manufacturing system 1500, and an IC manufacturing flow associated therewith, in accordance with at least one embodiment of the present disclosure. In some embodiments, based on a layout diagram, at least one of (A) one or more semiconductor masks or (B) at least one component in a layer of a semiconductor integrated circuit is fabricated using manufacturing system 1500.

In FIG. 15, IC manufacturing system 1500 (hereinafter “system 1500”) includes entities, such as a design house 1520, a mask house 1530, and an IC manufacturer/fabricator (“fab”) 1540, that interact with one another in the design, development, and manufacturing cycles and/or services related to manufacturing an IC device 1560. The entities in system 1500 are connected by a communications network. In some embodiments, the communications network is a single network. In some embodiments, the communications network is a variety of different networks, such as an intranet and the Internet. The communications network includes wired and/or wireless communication channels. Each entity interacts with one or more of the other entities and provides services to and/or receives services from one or more of the other entities. In some embodiments, one or more of design house 1520, mask house 1530, and IC fab 1540 is owned by a single larger company. In some embodiments, one or more of design house 1520, mask house 1530, and IC fab 1540 coexist in a common facility and use common resources.

Design house (or design team) 1520 generates an IC design layout 1522. IC design layout 1522 includes various geometrical patterns designed for an IC device 1560. The geometrical patterns correspond to patterns of metal, oxide, or semiconductor layers that make up the various components of IC device 1560 to be fabricated. The various layers combine to form various IC features. For example, a portion of IC design layout 1522 includes various IC features, such as an active region, gate electrode, source electrode and drain electrode, metal lines or vias of an interlayer interconnection, and openings for bonding pads, to be formed in a semiconductor substrate (such as a silicon wafer) and various material layers disposed on the semiconductor substrate. Design house 1520 implements a proper design procedure to form IC design layout 1522. The design procedure includes one or more of logic design, physical design or place and route. IC design layout 1522 is presented in one or more data files having information of the geometrical patterns. For example, IC design layout 1522 can be expressed in a GDSII file format or DFII file format.

Mask house 1530 includes data preparation 1532 and mask fabrication 1534. Mask house 1530 uses IC design layout 1522 to manufacture one or more masks 1545 to be used for fabricating the various layers of IC device 1560 according to IC design layout 1522. Mask house 1530 performs mask data preparation 1532, where IC design layout 1522 is translated into a representative data file (RDF). Mask data preparation 1532 provides the RDF to mask fabrication 1534. Mask fabrication 1534 includes a mask writer. A mask writer converts the RDF to an image on a substrate, such as a mask (reticle) 1545 or a semiconductor wafer 1542. The IC design layout 1522 is manipulated by mask data preparation 1532 to comply with particular characteristics of the mask writer and/or requirements of IC fab 1540. In FIG. 15, mask data preparation 1532 and mask fabrication 1534 are illustrated as separate elements. In some embodiments, mask data preparation 1532 and mask fabrication 1534 can be collectively referred to as mask data preparation.

In some embodiments, mask data preparation 1532 includes optical proximity correction (OPC) which uses lithography enhancement techniques to compensate for image errors, such as those that can arise from diffraction, interference, other process effects and the like. OPC adjusts IC design layout 1522. In some embodiments, mask data preparation 1532 includes further resolution enhancement techniques (RET), such as off-axis illumination, sub-resolution assist features, phase-shifting masks, other suitable techniques, and the like or combinations thereof. In some embodiments, inverse lithography technology (ILT) is also used, which treats OPC as an inverse imaging problem.

In some embodiments, mask data preparation 1532 includes a mask rule checker (MRC) that checks the IC design layout that has undergone processes in OPC with a set of mask creation rules which contain certain geometric and/or connectivity restrictions to ensure sufficient margins, to account for variability in semiconductor manufacturing processes, and the like. In some embodiments, the MRC modifies the IC design layout to compensate for limitations during mask fabrication 1534, which may undo part of the modifications performed by OPC in order to meet mask creation rules.

In some embodiments, mask data preparation 1532 includes lithography process checking (LPC) that simulates processing that will be implemented by IC fab 1540 to fabricate IC device 1560. LPC simulates this processing based on IC design layout 1522 to create a simulated manufactured device, such as IC device 1560. The processing parameters in LPC simulation can include parameters associated with various processes of the IC manufacturing cycle, parameters associated with tools used for manufacturing the IC, and/or other aspects of the manufacturing process. LPC takes into account various factors, such as aerial image contrast, depth of focus (DOF), mask error enhancement factor (MEEF), other suitable factors, and the like or combinations thereof. In some embodiments, after a simulated manufactured device has been created by LPC, if the simulated device is not close enough in shape to satisfy design rules, OPC and/or MRC are be repeated to further refine IC design layout 1522.

It should be understood that the above description of mask data preparation 1532 has been simplified for the purposes of clarity. In some embodiments, data preparation 1532 includes additional features such as a logic operation (LOP) to modify the IC design layout according to manufacturing rules. Additionally, the processes applied to IC design layout 1522 during data preparation 1532 may be executed in a variety of different orders.

After mask data preparation 1532 and during mask fabrication 1534, a mask 1545 or a group of masks 1545 are fabricated based on the modified IC design layout 1522. In some embodiments, mask fabrication 1534 includes performing one or more lithographic exposures based on IC design layout 1522. In some embodiments, an electron-beam (e-beam) or a mechanism of multiple e-beams is used to form a pattern on a mask (photomask or reticle) 1545 based on the modified IC design layout 1522. The mask 1545 can be formed in various technologies. In some embodiments, the mask 1545 is formed using binary technology. In some embodiments, a mask pattern includes opaque regions and transparent regions. A radiation beam, such as an ultraviolet (UV) beam, used to expose the image sensitive material layer (e.g., photoresist) which has been coated on a wafer, is blocked by the opaque region and transmits through the transparent regions. In one example, a binary version of mask 1545 includes a transparent substrate (e.g., fused quartz) and an opaque material (e.g., chromium) coated in the opaque regions of the binary mask. In another example, the mask 1545 is formed using a phase shift technology. In the phase shift mask (PSM) version of mask 1545, various features in the pattern formed on the mask are configured to have proper phase difference to enhance the resolution and imaging quality. In various examples, the phase shift mask can be attenuated PSM or alternating PSM. The mask(s) generated by mask fabrication 1534 is used in a variety of processes. For example, such a mask(s) is used in an ion implantation process to form various doped regions in the semiconductor wafer, in an etching process to form various etching regions in the semiconductor wafer, and/or in other suitable processes.

IC fab 1540 is an IC fabrication entity that includes one or more manufacturing facilities for the fabrication of a variety of different IC products. In some embodiments, IC Fab 1540 is a semiconductor foundry. For example, there may be a manufacturing facility for the front end fabrication of a plurality of IC products (front-end-of-line (FEOL) fabrication), while a second manufacturing facility may provide the back end fabrication for the interconnection and packaging of the IC products (back-end-of-line (BEOL) fabrication), and a third manufacturing facility may provide other services for the foundry entity.

IC fab 1540 includes wafer fabrication tools 1552 (hereinafter “fabrication tools 1552”) configured to execute various manufacturing operations on semiconductor wafer 1542 such that IC device 1560 is fabricated in accordance with the mask(s), e.g., mask 1545. In various embodiments, fabrication tools 1552 include one or more of a wafer stepper, an ion implanter, a photoresist coater, a process chamber, e.g., a CVD chamber or LPCVD furnace, a CMP system, a plasma etch system, a wafer cleaning system, or other manufacturing equipment capable of performing one or more suitable manufacturing processes as discussed herein.

IC fab 1540 uses mask(s) 1545 fabricated by mask house 1530 to fabricate IC device 1560. Thus, IC fab 1540 at least indirectly uses IC design layout 1522 to fabricate IC device 1560. In some embodiments, a semiconductor wafer 1542 is fabricated by IC fab 1540 using mask(s) 1545 to form IC device 1560. In some embodiments, the IC fabrication includes performing one or more lithographic exposures based at least indirectly on IC design 1522. Semiconductor wafer 1542 includes a silicon substrate or other proper substrate having material layers formed thereon. Semiconductor wafer 1542 further includes one or more of various doped regions, dielectric features, multilevel interconnects, and the like (formed at subsequent manufacturing steps).

System 1500 is shown as having design house 1520, mask house 1530 or IC fab 1540 as separate components or entities. However, it is understood that one or more of design house 1520, mask house 1530 or IC fab 1540 are part of the same component or entity.

In some embodiments, one or more of the operations of method 1300 is not performed. Furthermore, various PFET or NFET transistors shown in the present disclosure are of a particular dopant type (e.g., N-type or P-type) are for illustration purposes. Embodiments of the disclosure are not limited to a particular transistor type, and one or more of the PFET or NFET transistors shown in the present disclosure can be substituted with a corresponding transistor of a different transistor/dopant type. Similarly, the low or high logical value of various signals used in the above description is also for illustration. Embodiments of the disclosure are not limited to a particular logical value when a signal is activated and/or deactivated. Selecting different logical values is within the scope of various embodiments. Selecting different numbers of transistors in the present disclosure is within the scope of various embodiments.

One aspect of this description relates to a memory cell. In some embodiments, the memory cell includes a first transistor of a first type, and being coupled to a first storage node, the first transistor including a first gate on a first level. In some embodiments, the memory cell further includes a second transistor of a second type different from the first type, and being coupled to the first storage node, the second transistor including a second gate on a second level below the first level. In some embodiments, the memory cell further includes a third transistor of the first type, and being coupled to a second storage node, the third transistor including a third gate on the first level, the third gate being separated from the first gate in at least a first direction. In some embodiments, the memory cell further includes a fourth transistor of the second type, and being coupled to the second storage node, the fourth transistor including a fourth gate on the second level. In some embodiments, the memory cell further includes a first conductor extending in a second direction different from the first direction, the first conductor being on a first metal layer above a front-side of a substrate, and being coupled to the first gate and the second storage node. In some embodiments, the memory cell further includes a second conductor extending in the second direction, the second conductor being on a second metal layer below a back-side of the substrate, and being coupled to the fourth gate and the first storage node, and the second metal layer being different from the first metal layer.

Another aspect of this description relates to a memory cell. In some embodiments, the memory cell includes a first transistor of a first type, the first transistor including a first drain/source, and a first gate on a first level. In some embodiments, the memory cell further includes a second transistor of a second type different from the first type, the second transistor including a second drain/source, and a second gate on a second level below the first level. In some embodiments, the memory cell further includes a third transistor of the first type, the third transistor including a third drain/source, and a third gate on the first level. In some embodiments, the memory cell further includes a fourth transistor of the second type, the fourth transistor including a fourth drain/source, and a fourth gate on the second level, the fourth gate being separated from the second gate in at least a first direction. In some embodiments, the memory cell further includes a first conductor extending in a second direction different from the first direction, the first conductor being on a first metal layer above a front-side of a substrate, overlapping the first gate, and being coupled to the first gate, the third drain/source and the fourth drain/source. In some embodiments, the memory cell further includes a second conductor extending in the second direction, the second conductor being on a second metal layer below a back-side of the substrate, being overlapped by the fourth gate, and being coupled to the fourth gate, the first drain/source and the second drain/source, and the second metal layer being below from the first metal layer.

Still another aspect of this description relates to a method of fabricating a memory cell. In some embodiments, the method includes fabricating a first set of transistors and a second set of transistors in a front-side of a substrate, the first set of transistors being stacked above the second set of transistors. In some embodiments, the method further includes fabricating a first set of vias on the front-side of the substrate, the first set of vias being electrically coupled to at least the first set of transistors. In some embodiments, the method further includes depositing a first conductive material on the front-side of the substrate on a first metal level thereby forming a first set of conductors, the first set of conductors being electrically coupled to at least the first set of transistors by the first set of vias, the first set of conductors comprising a first conductor electrically coupling a first gate of the first set of transistors and a first storage node of the memory cell together. In some embodiments, the method further includes performing thinning on a back-side of the substrate opposite from the front-side. In some embodiments, the method further includes fabricating a second set of vias on the back-side of the thinned substrate, the second set of vias being electrically coupled to at least the second set of transistors. In some embodiments, the method further includes depositing a second conductive material on the back-side of the thinned substrate on a second metal level thereby forming a second set of conductors, the second set of conductors being electrically coupled to at least the second set of transistors by the second set of vias, the second set of conductors comprising a second conductor electrically coupling a second gate of the second set of transistors and a second storage node of the memory cell together.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A device, comprising:
a first transistor of a first type, and being coupled to a first node, the first transistor including a first gate on a first level;
a second transistor of a second type different from the first type, and being coupled to the first node, the second transistor including a second gate on a second level below the first level;
a third transistor of the first type, and being coupled to a second node, the third transistor including a third gate on the first level, the third gate being separated from the first gate in at least a first direction;
a fourth transistor of the second type, and being coupled to the second node, the fourth transistor including a fourth gate on the second level;
a first conductor extending in a second direction different from the first direction, the first conductor being on a first metal layer above a front-side of a substrate, and being coupled to the first gate and the second node; and
a second conductor extending in the second direction, the second conductor being on a second metal layer below a back-side of the substrate, and being coupled to the fourth gate and the first node, and the second metal layer being different from the first metal layer.

2. The device of claim 1, wherein
each of the first gate, the second gate, the third gate, and the fourth gate extend in the first direction,
the first gate and the third gate are further separated from each other in the second direction, and
the second gate and the fourth gate are separated from each other in the first direction and the second direction.

3. The device of claim 2, further comprising:
a first pass-gate transistor of the first type and being coupled to the first node, the first pass-gate transistor including a fifth gate on the first level; and
a second pass-gate transistor of the second type, and being coupled to the second node, and the second pass-gate transistor including a sixth gate on the first level,
wherein the fifth gate and the sixth gate extend in the first direction,
the third gate and the fifth gate are separated from each other in the first direction, and
the first gate and the sixth gate are separated from each other in the first direction.

4. The device of claim 3, further comprising:
a first contact extending in the first direction, being on a third level, and being electrically coupled to a source/drain of the first pass-gate transistor;
a second contact extending in the second direction, being on the third level, and being electrically coupled to a source/drain of the second pass-gate transistor; and
a third contact extending in the second direction, being on the third level and a fourth level different from the third level, and being electrically coupled to a source/drain of the first transistor, a source/drain of the second transistor and the source/drain of the first pass-gate transistor; and
a fourth contact extending in the second direction, being on the third level and the fourth level, and being electrically coupled to a source/drain of the third transistor, a source/drain of the fourth transistor and the source/drain of the second pass-gate transistor.

5. The device of claim 4, further comprising:
a first via electrically coupling the first conductor and the fourth contact together, the first via being between the first conductor and the fourth contact; and
a second via electrically coupling the first conductor and the first gate together, the second via being between the first conductor and the first gate.

6. The device of claim 5, further comprising:
a third conductor extending in the second direction, being on the first metal layer, being coupled to the first contact, and being configured as a bit line bar;
a fourth conductor extending in the second direction, being on the first metal layer, being coupled to the second contact, and being configured as a bit line;
a third via electrically coupling the third conductor and the first contact together, the third via being between the third conductor and the first contact; and
a fourth via electrically coupling the fourth conductor and the second contact together, the fourth via being between the fourth conductor and the second contact;
wherein the first conductor, the second conductor, the third conductor and the fourth conductor are separated from each other in the first direction.

7. The device of claim 5, further comprising:
a first insulating region between the first gate and the sixth gate, the first insulating region configured to electrically insulate the first gate and the sixth gate from each other; and
a second insulating region between the fifth gate and the third gate, the first insulating region configured to electrically insulate the fifth gate and the third gate from each other;
wherein a first side of the first insulating region contacts a first side of the first gate,
a first side of the second insulating region contacts a first side of the fifth gate, and
the first side of the first insulating region is offset in the first direction from the first side of the second insulating region.

8. The device of claim 7, wherein
the first via has a first width in the first direction,
the second via has a second width in the first direction, and
the first width is equal to the second width.

9. The device of claim 7, further comprising:
a third via electrically coupling the second conductor and the third contact together, the third via being between the second conductor and the third contact; and
a fourth via electrically coupling the second conductor and the fourth gate together, the fourth via being between the second conductor and the fourth gate.

10. The device of claim 9, wherein
the third via has a first width in the first direction,
the fourth via has a second width in the first direction, and
the first width is equal to the second width.

11. The device of claim 9, wherein the first conductor or the second conductor comprises:
a first conductive portion extending in the second direction;
a second conductive portion extending in the second direction; and
a third conductive portion extending in the second direction, and is a central portion connected to each of the first conductive portion and the second conductive portion on corresponding opposite sides.

12. A device, comprising:
a first transistor of a first type, the first transistor including a first drain/source, and a first gate on a first level;
a second transistor of a second type different from the first type, the second transistor including a second drain/source, and a second gate on a second level below the first level;
a third transistor of the first type, the third transistor including a third drain/source, and a third gate on the first level;
a fourth transistor of the second type, the fourth transistor including a fourth drain/source, and a fourth gate on the second level, the fourth gate being separated from the second gate in at least a first direction;
a first conductor extending in a second direction different from the first direction, the first conductor being on a first metal layer above a front-side of a substrate, overlapping the first gate, and being coupled to the first gate, the third drain/source and the fourth drain/source; and
a second conductor extending in the second direction, the second conductor being on a second metal layer below a back-side of the substrate, being overlapped by the fourth gate, and being coupled to the fourth gate, the first drain/source and the second drain/source, and the second metal layer being below from the first metal layer.

13. The device of claim 12, further comprising:
a first pass-gate transistor of the first type and being coupled to the first transistor and the second transistor, the first pass-gate transistor including a fifth drain/source, and a fifth gate on the first level; and
a second pass-gate transistor of the second type, and being coupled to the third transistor and the fourth transistor, and the second pass-gate transistor including a sixth drain/source, and a sixth gate on the first level.

14. The device of claim 13, wherein
each of the first gate, the second gate, the third gate, the fourth gate, the fifth gate and the sixth gate extend in the first direction;
the first gate and the third gate are separated from each other in the first direction and the second direction;
the second gate and the fourth gate are further separated from each other in the second direction;
the third gate and the fifth gate are separated from each other in the first direction, and
the first gate and the sixth gate are separated from each other in the first direction.

15. The device of claim 14, further comprising:
a first contact extending in the second direction, being on a third level and a fourth level different from the third level, and being electrically coupled to the first drain/source of the first transistor, the second drain/source of the second transistor and the fifth drain/source of the first pass-gate transistor; and
a second contact extending in the second direction, being on the third level and the fourth level, and being electrically coupled to the third drain/source of the third transistor, the fourth drain/source of the fourth transistor and the sixth drain/source of the second pass-gate transistor.

16. The device of claim 15, further comprising:
a first via electrically coupling the first conductor and the second contact together, the first via being between the first conductor and the second contact; and
a second via electrically coupling the first conductor and the first gate together, the second via being between the first conductor and the first gate.

17. The device of claim 16, further comprising:
a first insulating region between the first gate and the sixth gate, the first insulating region configured to electrically insulate the first gate and the sixth gate from each other; and
a second insulating region between the fifth gate and the third gate, the first insulating region configured to electrically insulate the fifth gate and the third gate from each other;
wherein a first side of the first insulating region contacts a first side of the first gate,
a first side of the second insulating region contacts a first side of the fifth gate, and
the first side of the first insulating region is aligned in the second direction with the first side of the second insulating region.

18. The device of claim 17, further comprising:
a third via electrically coupling the second conductor and the first contact together, the third via being between the second conductor and the first contact; and
a fourth via electrically coupling the second conductor and the fourth gate together, the fourth via being between the second conductor and the fourth gate.

19. The device of claim 18, wherein
the first via has a first width in the first direction,
the second via has a second width in the first direction,
the third via has a third width in the first direction,
the fourth via has a fourth width in the first direction,
the first width is less than the second width, and
the third width is less than the fourth width.

20. A method, comprising:
fabricating a first set of transistors and a second set of transistors in a front-side of a substrate, the first set of transistors being stacked above the second set of transistors;
fabricating a first set of vias on the front-side of the substrate, the first set of vias being electrically coupled to at least the first set of transistors;
depositing a first conductive material on the front-side of the substrate on a first metal level thereby forming a first set of conductors, the first set of conductors being electrically coupled to at least the first set of transistors by the first set of vias, the first set of conductors comprising a first conductor electrically coupling a first gate of the first set of transistors and a first node of the device together;
performing thinning on a back-side of the substrate opposite from the front-side;
fabricating a second set of vias on the back-side of the thinned substrate, the second set of vias being electrically coupled to at least the second set of transistors; and
depositing a second conductive material on the back-side of the thinned substrate on a second metal level thereby forming a second set of conductors, the second set of conductors being electrically coupled to at least the second set of transistors by the second set of vias, the second set of conductors comprising a second conductor electrically coupling a second gate of the second set of transistors and a second node of the device together.
